(19) United States
(12) Patent Application Publication
(10) Pub. No.: US 2024/0172554 A1
(43) Pub. Date: May 23, 2024

(54) ORGANIC LIGHT EMITTING DIODE AND ORGANIC LIGHT EMITTING DEVICE INCLUDING THE SAME

(71) Applicants: LG DISPLAY CO., LTD., Seoul (KR); Research & Business Foundation SUNGKYUNKWAN UNIVERSITY, Suwon-si (KR)

(72) Inventors: Suk-Young BAE, Paju-si (KR); Dong-Ryun LEE, Paju-si (KR); Jong-Uk KIM, Paju-si (KR); Han-Jin AHN, Paju-si (KR); Jun-Yun KIM, Paju-si (KR); Jun-Yeob LEE, Suwon-si (KR); Sook-Hee JEONG, Suwon-si (KR); Jin-Ho PARK, Suwon-si (KR)

(73) Assignees: LG DISPLAY CO., LTD., Seoul (KR); Research & Business Foundation SUNGKYUNKWAN UNIVERSITY, Suwon-si (KR)

(21) Appl. No.: 18/237,725

(22) Filed: Aug. 24, 2023

(30) Foreign Application Priority Data
Oct. 27, 2022 (KR) 10-2022-0140316

(51) Int. Cl. H10K 85/40; C09K 11/06

(52) U.S. Cl. CPC H10K 85/40; C09K 11/06; H10K 50/12

(57) ABSTRACT

The present invention relates to an organic light emitting diode and an organic light emitting device including the organic light emitting diode. The organic light emitting diode includes a first electrode; a second electrode facing the first electrode; and a first blue emitting material layer including a first compound, a second compound and a third compound and positioned between the first and second electrodes, wherein the first compound is represented by Formula 1, the second compound is represented by Formula 3, and the third compound is represented by Formula 5, and wherein in the first blue emitting material layer, a summation of a weight % of the first compound, a weight % of the second compound and a weight % of the third compound is 100%, and the weight % of each of the first and second compounds is greater than the weight % of the third compound.

### CROSS-REFERENCE TO RELATED APPLICATIONS

The present application claims the benefit of Korean Patent Application No. 10-2022-0140316 filed in the Republic of Korea on Oct. 27, 2022, which is hereby incorporated by reference in its entirety.

### BACKGROUND

### Technical Field

The present disclosure relates to an organic light emitting diode, and more particularly, to an organic light emitting diode having low driving voltage, high emitting efficiency, improved color purity and enhanced lifespan and an organic light emitting device including the organic light emitting diode.

### Description of the Related Art

Requirement for flat panel display devices having small occupied area is increased. Among the flat panel display devices, a technology of an organic light emitting display device, which includes an organic light emitting diode (OLED) and may be called to as an organic electroluminescent device, is rapidly developed.

The OLED emits light by injecting electrons from a cathode as an electron injection electrode and holes from an anode as a hole injection electrode into an emitting material layer, combining the electrons with the holes, generating an exciton, and transforming the exciton from an excited state to a ground state.

For example, the OLED uses red, green and blue emission. However, in the related art OLED, there is still limitation of emitting efficiency and lifespan in the blue emission.

### SUMMARY

Accordingly, embodiments of the present disclosure are directed to an OLED and an organic light emitting device that substantially obviate one or more of the problems associated with the limitations and disadvantages of the related art.

An aspect of the present disclosure is to provide an OLED and an organic light emitting device having low driving voltage, high emitting efficiency, improved color purity and enhanced lifespan.

Additional features and aspects will be set forth in the description that follows, and in part will be apparent from the description, or may be learned by practice of the present disclosure concepts provided herein. Other features and aspects of the present disclosure concepts may be realized and attained by the structure particularly pointed out in the written description, or derivable therefrom, and the claims hereof as well as the appended drawings.

To achieve these and other advantages and in accordance with the objects of the present disclosure, as embodied and broadly described herein, an aspect of the present disclosure is an organic light emitting diode comprising a first electrode; a second electrode facing the first electrode; and a first blue emitting material layer including a first compound, a second compound and a third compound and positioned between the first and second electrodes, wherein the first compound is represented by Formula 1:

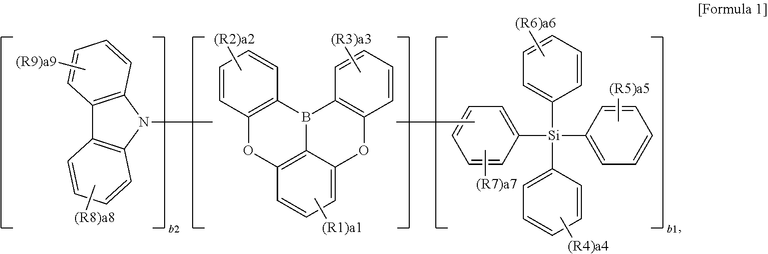

wherein in the Formula 1, a1 is an integer of 0 to 3, each of a2 and a3 is independently an integer of 0 to 4, and a summation of a1, a2 and a3 is 9 or less, each of a4, a5 and a6 is independently an integer of 0 to 5, and each of a7, a8 and a9 is independently an integer of 0 to 4, each of b1 and b2 is independently an integer of 1 to 10, and a summation of b1 and b2 is 11 or less, each of R1, R2, R3, R4, R5, R6 and R7 is independently selected from the group consisting of deuterium, halogen, cyano, a substituted or unsubstituted C1 to C20 alkyl group, a substituted or unsubstituted C6 to C30 aryl group, a substituted or unsubstituted C3 to C60 heteroaryl group, a substituted or unsubstituted C1 to C60 alkylamine group and a substituted or unsubstituted C6 to C30 arylamine group, and each of R8 and R9 is independently selected from the group consisting of deuterium, halogen, cyano, a substituted or unsubstituted C1 to C20 alkyl group, a substituted or unsubstituted C6 to C30 aryl group, a substituted or unsubstituted C3 to C60 heteroaryl group, a substituted or unsubstituted C1 to C60 alkylamine group and a substituted or unsubstituted C6 to C30 arylamine group, or adjacent two R8 and/or adjacent two R9 are connected to each other to form a substituted or unsubstituted aromatic ring or a substituted or unsubstituted heteroaromatic ring, wherein the second compound is represented by Formula 3:

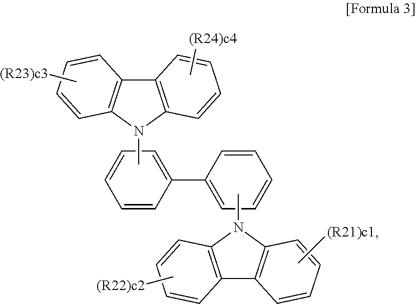

wherein in the Formula 3, each of c1, c2, c3 and c4 is independently an integer of 0 to 4, and each of R21, R22, R23 and R24 is independently selected from the group consisting of deuterium, halogen, cyano, a substituted or unsubstituted C1 to C20 alkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, wherein the third compound is represented by Formula 5:

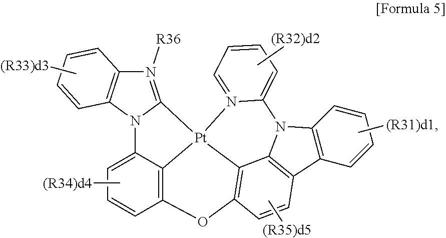

wherein in the Formula 5, each of R31, R32, R33, R34, R35 and R36 is independently selected from the group consisting of deuterium, halogen, cyano, a substituted or unsubstituted C1 to C20 alkyl group, a substituted or unsubstituted C3 to C30 cycloalkyl group, a substituted or unsubstituted C1 to C20 alkylsilyl group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group, each of d1, d2 and d3 is independently an integer of 0 to 4, d4 is an integer of 0 to 3, and d5 is an integer of 0 to 2, and wherein in the first blue emitting material layer, a summation of a weight % of the first compound, a weight % of the second compound and a weight % of the third compound is 100%, and the weight % of each of the first and second compounds is greater than the weight % of the third compound.

Another aspect of the present disclosure is an organic light emitting device comprising a substrate; the above organic light emitting diode disposed over the substrate; and an encapsulation layer covering the organic light emitting diode.

It is to be understood that both the foregoing general description and the following detailed description are merely by way of example, and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate embodiments of the present disclosure and together with the description serve to explain principles of the present disclosure.

FIG. 1 is a schematic circuit diagram of an organic light emitting display device of the present disclosure.

FIG. 2 is a schematic cross-sectional view of an organic light emitting display device according to a first embodiment of the present disclosure.

FIG. 3 is a schematic cross-sectional view of an OLED according to a second embodiment of the present disclosure.

FIG. 4 is a view illustrating a relation between compounds in an EML of an OLED of Comparative Example.

FIG. 5 is a view illustrating a relation between compounds in an EML of an OLED according to the second embodiment of the present disclosure.

FIG. 6 is a schematic cross-sectional view of an OLED according to a third embodiment of the present disclosure.

FIG. 7 is a schematic cross-sectional view of an OLED according to a fourth embodiment of the present disclosure.

FIG. 8 is a schematic cross-sectional view of an OLED according to a fifth embodiment of the present disclosure.

FIG. 9 is a schematic cross-sectional view of an organic light emitting display device according to a sixth embodiment of the present disclosure.

FIG. 10 is a schematic cross-sectional view of an organic light emitting display device according to a seventh embodiment of the present disclosure.

FIG. 11 is a schematic cross-sectional view of an OLED according to an eighth embodiment of the present disclosure.

FIG. 12 is a schematic cross-sectional view of an OLED according to a ninth embodiment of the present disclosure.

FIG. 13 is a schematic cross-sectional view of an OLED according to a tenth embodiment of the present disclosure.

### DETAILED DESCRIPTION

Reference will now be made in detail to aspects of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When ‘including’, ‘having’, ‘consisting’, and the like are used in this specification, other parts may be added unless ‘only’ is used. When a component is expressed in the singular, cases including the plural are included unless specific statement is described.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts may be disposed between the two parts unless a more limiting term, such as “just” or “direct(ly)” is used.

In describing a time relationship, for example, when the temporal order is described as, for example, “after,” “subsequent,” “next,” and “before,” a case that is not continuous may be included unless a more limiting term, such as “just,” “immediate(ly),” or “direct(ly)” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Moreover, the term “substituted or unsubstituted” means being unsubstituted or substituted with one or more substituents selected from the group consisting of deuterium; a halogen group; a nitrile group; a nitro group; a hydroxy group; a carbonyl group; an ester group; an imide group; an amino group; a phosphine oxide group; an alkoxy group; an aryloxy group; an alkylthioxy group; an arylthioxy group; an alkylsulfoxy group; an arylsulfoxy group; a silyl group; a boron group; an alkyl group; a cycloalkyl group; an alkenyl group; an aryl group; an aralkyl group; an aralkenyl group; an alkylaryl group; an alkylamine group; an aralkylamine group; a heteroarylamine group; an arylamine group; an arylphosphine group; a heterocyclic group; or a heteroaryl group, or being unsubstituted or substituted with a substituent to which two or more substituents are linked among the substituents exemplified above. These substituents exemplified above may contain 1 to 60 carbon atoms, in particular, from 1, 2, 3, 6, or 7 to 60, 30, 20, 10, or 6 carbon atoms. And the heterocyclic group or heteroaryl group may contain one or more of heteroatoms, e.g., N, O, S, P, or Si atoms. Moreover, “the substituent to which two or more substituents are linked” may be a biphenyl group. That is, the biphenyl group may also be an aryl group and may be interpreted as a substituent to which two phenyl groups are linked.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in co-dependent relationship.

Reference will now be made in detail to some of the examples and preferred embodiments, which are illustrated in the accompanying drawings.

The present disclosure relates to an OLED, in which an emitting material layer includes an n-type host, a p-type host and a phosphorescent dopant, and an organic light emitting device including the OLED. For example, an organic light emitting device may be an organic light emitting display device or an organic lightening device. As an example, an organic light emitting display device, which is a display device including the OLED of the present disclosure, will be mainly described.

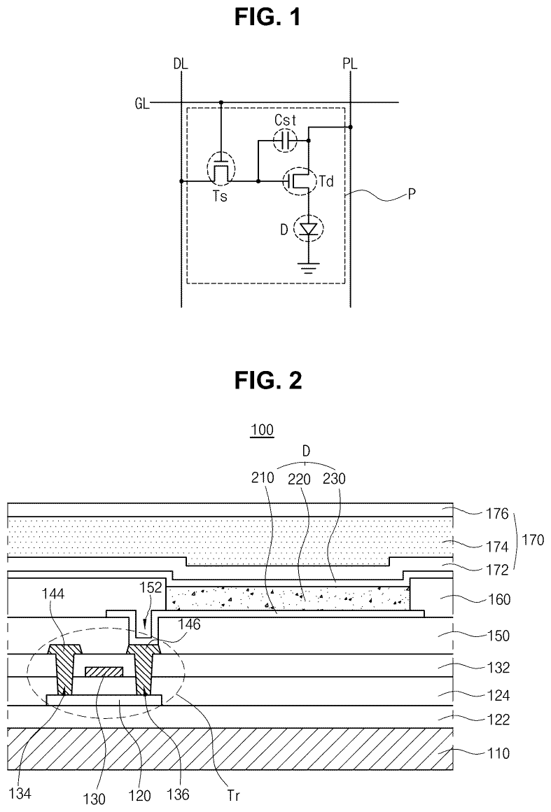

FIG. 1 is a schematic circuit diagram of an organic light emitting display device of the present disclosure.

As shown in FIG. 1, an organic light emitting display device includes a gate line GL, a data line DL, a power line PL, a switching thin film transistor TFT Ts, a driving TFT Td, a storage capacitor Cst, and an OLED D. The gate line GL and the data line DL cross each other to define a pixel region P. The pixel region may include a red pixel region, a green pixel region and a blue pixel region.

The switching TFT Ts is connected to the gate line GL and the data line DL, and the driving TFT Td and the storage capacitor Cst are connected to the switching TFT Ts and the power line PL. The OLED D is connected to the driving TFT Td.

In the organic light emitting display device, when the switching TFT Ts is turned on by a gate signal applied through the gate line GL, a data signal from the data line DL is applied to the gate electrode of the driving TFT Td and an electrode of the storage capacitor Cst.

When the driving TFT Td is turned on by the data signal, an electric current is supplied to the OLED D from the power line PL. As a result, the OLED D emits light. In this case, when the driving TFT Td is turned on, a level of an electric current applied from the power line PL to the OLED D is determined such that the OLED D can produce a gray scale.

The storage capacitor Cst serves to maintain the voltage of the gate electrode of the driving TFT Td when the switching TFT Ts is turned off. Accordingly, even if the switching TFT Ts is turned off, a level of an electric current applied from the power line PL to the OLED D is maintained to next frame.

As a result, the organic light emitting display device displays a desired image.

FIG. 2 is a schematic cross-sectional view of an organic light emitting display device according to a first embodiment of the present disclosure.

As shown in FIG. 2, the organic light emitting display device 100 includes a substrate 110, a TFT Tr on or over the substrate 110, a planarization layer 150 covering the TFT Tr and an OLED D on the planarization layer 150 and connected to the TFT Tr. A red pixel region, a green pixel region and a blue pixel region may be defined on the substrate 110.

The substrate 110 may be a glass substrate or a flexible substrate. For example, the flexible substrate may be one of a polyimide (PI) substrate, a polyethersulfone (PES) substrate, a polyethylenenaphthalate (PEN) substrate, a polyethylene terephthalate (PET) substrate and a polycarbonate (PC) substrate.

A buffer layer 122 is formed on the substrate, and the TFT Tr is formed on the buffer layer 122. The buffer layer 122 may be omitted. For example, the buffer layer 122 may be formed of an inorganic insulating material, e.g., silicon oxide or silicon nitride.

A semiconductor layer 120 is formed on the buffer layer 122. The semiconductor layer 120 may include an oxide semiconductor material or polycrystalline silicon.

When the semiconductor layer 120 includes the oxide semiconductor material, a light-shielding pattern (not shown) may be formed under the semiconductor layer 120. The light to the semiconductor layer 120 is shielded or blocked by the light-shielding pattern such that thermal degradation of the semiconductor layer 120 can be prevented. On the other hand, when the semiconductor layer 120 includes polycrystalline silicon, impurities may be doped into both sides of the semiconductor layer 120.

A gate insulating layer 124 is formed on the semiconductor layer 120. The gate insulating layer 124 may be formed of an inorganic insulating material such as silicon oxide or silicon nitride.

A gate electrode 130, which is formed of a conductive material, e.g., metal, is formed on the gate insulating layer 124 to correspond to a center of the semiconductor layer 120. In FIG. 2, the gate insulating layer 124 is formed on an entire surface of the substrate 110. Alternatively, the gate insulating layer 124 may be patterned to have the same shape as the gate electrode 130.

An interlayer insulating layer 132 is formed on the gate electrode 130 and over an entire surface of the substrate 110. The interlayer insulating layer 132 may be formed of an inorganic insulating material, e.g., silicon oxide or silicon nitride, or an organic insulating material, e.g., benzocyclobutene or photo-acryl.

The interlayer insulating layer 132 includes first and second contact holes 134 and 136 exposing both sides of the semiconductor layer 120. The first and second contact holes 134 and 136 are positioned at both sides of the gate electrode 130 to be spaced apart from the gate electrode 130.

The first and second contact holes 134 and 136 are formed through the gate insulating layer 124. Alternatively, when the gate insulating layer 124 is patterned to have the same shape as the gate electrode 130, the first and second contact holes 134 and 136 is formed only through the interlayer insulating layer 132.

A source electrode 144 and a drain electrode 146, which are formed of a conductive material, e.g., metal, are formed on the interlayer insulating layer 132.

The source electrode 144 and the drain electrode 146 are spaced apart from each other with respect to the gate electrode 130 and respectively contact both sides of the semiconductor layer 120 through the first and second contact holes 134 and 136.

The semiconductor layer 120, the gate electrode 130, the source electrode 144 and the drain electrode 146 constitute the TFT Tr. The TFT Tr serves as a driving element. Namely, the TFT Tr is the driving TFT Td (of FIG. 1).

In the TFT Tr, the gate electrode 130, the source electrode 144, and the drain electrode 146 are positioned over the semiconductor layer 120. Namely, the TFT Tr has a coplanar structure.

Alternatively, in the TFT Tr, the gate electrode may be positioned under the semiconductor layer, and the source and drain electrodes may be positioned over the semiconductor layer such that the TFT Tr may have an inverted staggered structure. In this instance, the semiconductor layer may include amorphous silicon.

Although not shown, the gate line and the data line cross each other to define the pixel region, and the switching TFT is formed to be connected to the gate and data lines. The switching TFT is connected to the TFT Tr as the driving element. In addition, the power line, which may be formed to be parallel to and spaced apart from one of the gate and data lines, and the storage capacitor for maintaining the voltage of the gate electrode of the TFT Tr in one frame may be further formed.

A planarization layer 150 is formed on an entire surface of the substrate 110 to cover the source and drain electrodes 144 and 146. The planarization layer 150 provides a flat top surface and has a drain contact hole 152 exposing the drain electrode 146 of the TFT Tr.

The OLED D is disposed on the planarization layer 150 and includes a first electrode 210, which is connected to the drain electrode 146 of the TFT Tr, an organic light emitting layer 220 and a second electrode 230. The organic light emitting layer 220 and the second electrode 230 are sequentially stacked on the first electrode 210. The OLED D is positioned in each of the red, green and blue pixel regions and respectively emits the red, green and blue light.

The first electrode 210 is separately formed in each pixel region. The first electrode 210 may be an anode and may include a transparent conductive oxide material layer, which may be formed of a conductive material, e.g., a transparent conductive oxide (TCO), having a relatively high work function.

For example, the transparent conductive oxide material layer may be formed of one of indium-tin-oxide (ITO), indium-zinc-oxide (IZO), indium-tin-zinc-oxide (ITZO), tin oxide (SnO), zinc oxide (ZnO), indium-copper-oxide (ICO) and aluminum-zinc-oxide (Al:ZnO, AZO).

The first electrode 210 may have a single-layered structure of the transparent conductive oxide material layer. Namely, the first electrode 210 may be a transparent electrode.

Alternatively, the first electrode 210 may further include a reflective layer to have a double-layered structure or a triple-layered structure. Namely, the first electrode 210 may be a reflective electrode.

For example, the reflective layer may be formed of one of silver (Ag), an alloy of Ag and one of palladium (Pd), copper (Cu), indium (In) and neodymium (Nd), and aluminum-palladium-copper (APC) alloy. For example, the first electrode 210 may have a double-layered structure of Ag/ITO or APC/ITO or a triple-layered structure of ITO/Ag/ITO or ITO/APC/ITO.

In addition, a bank layer 160 is formed on the planarization layer 150 to cover an edge of the first electrode 210. Namely, the bank layer 160 is positioned at a boundary of the pixel region and exposes a center of the first electrode 210 in the pixel region.

The organic light emitting layer 220 including an emitting material layer (EML) is formed on the first electrode 210. In the OLED D in the blue pixel region, the EML of the organic light emitting layer 220 includes a first host, e.g., an n-type host, represented by Formula 1, a second host, e.g., a p-type host, represented by Formula 3 and a phosphorescent dopant, e.g., an emitter or an emission dopant, represented by Formula 5. As a result, in the OLED D and the organic light emitting display device according to the present disclosure, the driving voltage is reduced, and the emitting efficiency, the color purity and the lifespan are improved.

The organic light emitting layer 220 may further include at least one of a hole injection layer (HIL), a hole transporting layer (HTL), an electron blocking layer (EBL), a hole blocking layer (HBL), an electron transporting layer (ETL) and an electron injection layer (EIL) to have a multi-layered structure.

In an aspect of the present disclosure, the organic light emitting layer 220 of the OLED D in the blue pixel region may include a first blue emitting part including a first blue EML and a second blue emitting part including a second blue EML to have a tandem structure, and at least one of the first and second blue EMLs includes a first host as an n-type host represented by Formula 1, a second host as a p-type host represented by Formula 3 and a phosphorescent dopant as an emitter represented by Formula 5. In this case, the organic light emitting layer 220 may further include a charge generation layer (CGL) between the first and second blue emitting parts. As a result, in the OLED D and the organic light emitting display device according to the present disclosure, the driving voltage is reduced, and the emitting efficiency, the color purity and the lifespan are improved.

The second electrode 230 is formed over the substrate 110 where the organic light emitting layer 220 is formed. The second electrode 230 covers an entire surface of the display area and may be formed of a conductive material having a relatively low work function to serve as a cathode. For example, the second electrode 230 may be formed of aluminum (Al), magnesium (Mg), calcium (Ca), silver (Ag) or their alloy, e.g., Mg—Ag alloy (MgAg).

In a top-emission type OLED D, the first electrode 210 serves as a reflective electrode, and the second electrode 220 has a thin profile to serve as a transparent (or a semitransparent) electrode. Alternatively, in a bottom-emission type OLED, the first electrode 210 serves as a transparent electrode, and the second electrode serves as a reflective electrode.

Although not shown, the OLED D may further include a capping layer on the second electrode 230. The emitting efficiency of the OLED D and the organic light emitting display device 100 may be further improved by the capping layer.

An encapsulation film (or an encapsulation layer) 170 is formed on the second electrode 230 to prevent penetration of moisture into the OLED D. The encapsulation film 170 includes a first inorganic insulating layer 172, an organic insulating layer 174 and a second inorganic insulating layer 176 sequentially stacked, but it is not limited thereto.

Alternatively, a metal encapsulation plate may be disposed over the second electrode 230. For example, the metal encapsulation plate may be attached to the OLED D using an adhesive layer.

Although not shown, the organic light emitting display device 100 may include a color filter corresponding to the red, green and blue pixel regions. For example, the color filter may be positioned on or over the OLED D or between the substrate 110 and the OLED D.

The organic light emitting display device 100 may further include a polarization plate for reducing an ambient light reflection. For example, the polarization plate may be a circular polarization plate. In the bottom-emission type organic light emitting display device 100, the polarization plate may be disposed under the substrate 110. In the top-emission type organic light emitting display device 100, the polarization plate may be disposed on or over the encapsulation film 170.

In addition, the organic light emitting display device 100 may further include a cover window on or over the encapsulation film 170 or the polarization plate. In this instance, the substrate 110 and the cover window have a flexible property such that a flexible organic light emitting display device may be provided.

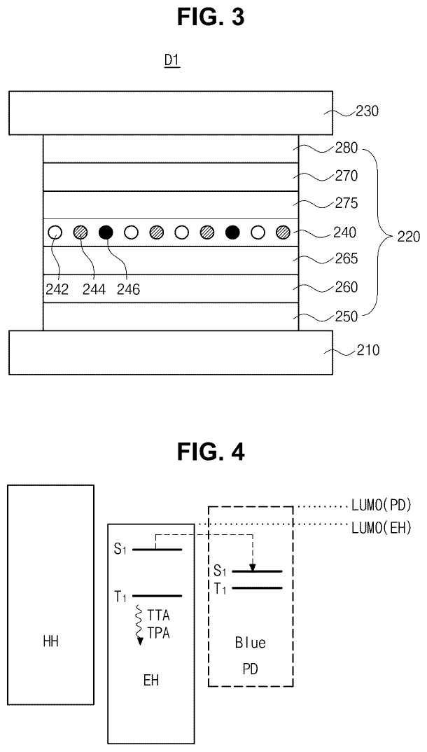

FIG. 3 is a schematic cross-sectional view of an OLED according to a second embodiment of the present disclosure.

As illustrated in FIG. 3, the OLED D1 includes first and second electrodes 210 and 230, which face each other and an organic light emitting layer 220 therebetween. The organic light emitting layer 220 includes an emitting material layer (EML) 240. The OLED D1 may further include a capping layer on the second electrode 230 to enhance a light extraction efficiency.

The organic light emitting display device 100 (of FIG. 2) may include a red pixel region, a green pixel region and a blue pixel region, and the OLED D1 may be positioned in the blue pixel region.

The first electrode 210 may be an anode, and the second electrode 230 may be a cathode. One of the first and second electrodes 210 and 230 may be a reflective electrode, and the other one of the first and second electrodes 210 and 230 may be a transparent (or a semitransparent) electrode. For example, the first electrode 210 may have a single-layered structure of ITO, and the second electrode 230 may be formed of Al.

The light emitting layer 220 further include at least one of a hole transporting layer (HTL) 260 between the first electrode 210 and the EML 240 and an electron transporting layer (ETL) 270 between the second electrode 230 and the EML 240.

In addition, the light emitting layer 220 may further include at least one of a hole injection layer (HIL) 250 between the first electrode 210 and the HTL 260 and an electron injection layer (EIL) 280 between the second electrode 230 and the ETL 270.

Moreover, the light emitting layer 220 may further include at least one of an electron blocking layer (EBL) 265 between the HTL 260 and the EML 240 and a hole blocking layer (HBL) 275 between the EML 240 and the ETL 270.

For example, the HIL 250 may include at least one compound selected from the group consisting of 4,4′,4″-tris(3-methylphenylamino)triphenylamine (MTDATA), 4,4′,4″-tris(N,N-diphenyl-amino)triphenylamine (NATA), 4,4′,4″-tris(N-(naphthalene-1-yl)-N-phenyl-amino)triphenylamine (1T-NATA), 4,4′,4″-tris(N-(naphthalene-2-yl)-N-phenyl-amino)triphenylamine (2T-NATA), copper phthalocyanine (CuPc), tris(4-carbazoyl-9-yl-phenyl)amine (TCTA), N,N′-diphenyl-N,N′-bis(1-naphthyl)-1,1′-biphenyl-4,4″-diamine (NPB or NPD), 1,4,5,8,9,11-hexaazatriphenylenehexacarbonitrile(dipyrazino[2,3-f:2′ 3′-h]quinoxaline-2,3,6,7,10,11-hexacarbonitrile (HAT-CN), 1,3,5-tris[4-(diphenylamino)phenyl]benzene (TDAPB), poly(3,4-ethylenedioxythiphene)polystyrene sulfonate (PEDOT/PSS), and N-(biphenyl-4-yl)-9,9-dimethyl-N-(4-(9-phenyl-9H-carbazol-3-yl)phenyl)-9H-fluoren-2-amine, but it is not limited thereto. For example, the HIL 250 may have a thickness of 1 to 30 nm.

The HTL 260 may include at least one compound selected from the group consisting of N,N′-diphenyl-N,N′-bis(3-methylphenyl)-1,1′-biphenyl-4,4′-diamine (TPD), NPB(NPD), 4,4′-bis(N-carbazolyl)-1,1′-biphenyl (CBP), poly[N,N′-bis(4-butylphenyl)-N,N′-bis(phenyl)-benzidine] (poly-TPD), poly[(9,9-dioctylfluorenyl-2,7-diyl)-co-(4,4′-(N-(4-sec-butylphenyl)diphenylamine))] (TFB), di-[4-(N,N-di-p-tolyl-amino)-phenyl]cyclohexane (TAPC), 3,5-di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, and N-(biphenyl-4-yl)-N-(4-(9-phenyl-9H-carbazol-3-yl)phenyl)biphenyl-4-amine, but it is not limited thereto. For example, the HTL 260 may have a thickness of 10 to 100 nm.

The ETL 270 may include at least one of an oxadiazole-based compound, a triazole-based compound, a phenanthroline-based compound, a benzoxazole-based compound, a benzothiazole-based compound, a benzimidazole-based compound, and a triazine-based compound. For example, the ETL 270 may include at least one compound selected from the group consisting of tris-(8-hydroxyquinoline aluminum) (Alq₃), 2-biphenyl-4-yl-5-(4-t-butylphenyl)-1,3,4-oxadiazole (PBD), spiro-PBD, lithium quinolate (Liq), 1,3,5-tris(N-phenylbenzimidazol-2-yl)benzene (TPBi), bis(2-methyl-8-quinolinolato-N1,O8)-(1,1′-biphenyl-4-olato)aluminum (BAlq), 4,7-diphenyl-1,10-phenanthroline (Bphen), 2,9-bis(naphthalene-2-yl)4,7-diphenyl-1,10-phenanthroline (NBphen), 2,9-dimethyl-4,7-diphenyl-1,10-phenathroline (BCP), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 1,3,5-tri(p-pyrid-3-yl-phenyl)benzene (TpPyPB), 2,4,6-tris(3′-(pyridin-3-yl)biphenyl-3-yl)1,3,5-triazine (TmPPPyTz), Poly[9,9-bis(3′-((N,N-dimethyl)-N-ethylammonium)-propyl)-2,7-fluorene]-alt-2,7-(9,9-dioctylfluorene) (PFNBr), tris(phenylquinoxaline) (TPQ), and diphenyl-4-triphenylsilyl-phenylphosphine oxide (TSPO1), but it is not limited thereto. For example, the ETL 270 may have a thickness of 10 to 100 nm.

The EIL 280 may include at least one of an alkali halide compound, such as LiF, CsF, NaF, or BaF₂, and an organo-metallic compound, such as Liq, lithium benzoate, or sodium stearate, but it is not limited thereto. For example, the EIL 280 may have a thickness of 0.1 to 10 nm.

The EBL 265, which is positioned between the HTL 260 and the EML 240 to block the electron transfer from the EML 240 into the HTL 260, may include at least one compound selected from the group consisting of TCTA, tris[4-(diethylamino)phenyl]amine, N-(biphenyl-4-yl)-9,9-dimethyl-N-(4-(9-phenyl-9H-carbazol-3-yl)phenyl)-9H-fluoren-2-amine, TAPC, MTDATA, 1,3-bis(carbazol-9-yl)benzene (mCP), 3,3′-bis(N-carbazolyl)-1,1′-biphenyl (mCBP), CuPc, N,N′-bis[4-[bis(3-methylphenyl)amino]phenyl]-N,N′-diphenyl-[1,1′-biphenyl]-4,4′-diamine (DNTPD), TDAPB, DCDPA, and 2,8-bis(9-phenyl-9H-carbazol-3-yl)dibenzo[b,d]thiophene, but it is not limited thereto. For example, the EBL 265 may have a thickness of 1 to 30 nm.

The HBL 275, which is positioned between the EML 240 and the ETL 270 to block the hole transfer from the EML 240 into the ETL 270, may include the above material of the ETL 270. For example, the material of the HBL 275 has a HOMO energy level being lower than a material of the EML 240 and may be at least one compound selected from the group consisting of BCP, BAlq, Alq3, PBD, spiro-PBD, Liq, bis-4,6-(3,5-di-3-pyridylphenyl)-2-methylpyrimidine (B3PYMPM), bis[2-(diphenylphosphino)phenyl]ether oxide (DPEPO), 9-(6-9H-carbazol-9-yl)pyridine-3-yl)-9H-3,9′-bicarbazole, and TSPO1, but it is not limited thereto. For example, the HBL 275 may have a thickness of 1 to 30 nm.

The EML 240 includes a first compound 242 being an n-type host, a second compound 244 being a p-type host and a third compound 246 being a phosphorescent dopant. The first compound 242 has a delayed fluorescence property, an exciton is generated in the first and second compounds 242 and 244. After a triplet energy of the exciton is converted into a singlet energy (i.e., a up-conversion system), the singlet energy of the exciton is transferred into the third compound 246. Accordingly, a non-emissive quenching problem of the exciton in the first and second compounds 242 and 244 by a triplet-triplet annihilation (TTA) or a triplet-polaron annihilation (TPA) can be prevented, and the emitting efficiency of the OLED D1 is improved. In addition, since the first compound 242 includes a bulky arylsilyl group, a boron core of the first compound 242 is protected so that the lifespan of the OLED D1 and the organic light emitting display device 100 is significantly improved.

The first compound 242 comprises a moiety represented by Formula 1-1 and a moiety represented by Formula 1-2.

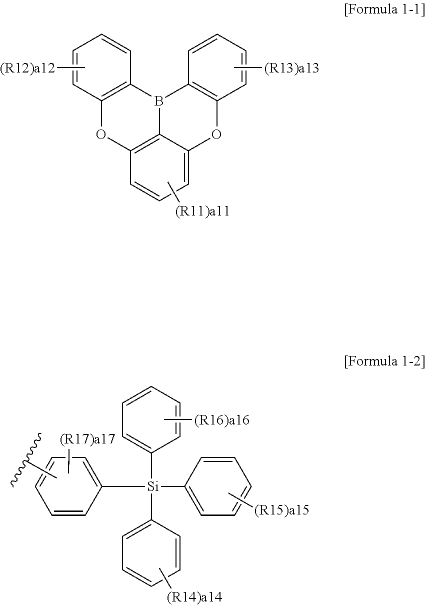

In Formula 1-1,
a11 is an integer of 0 to 3, each of a12 and a13 is independently an integer of 0 to 4, and a summation of a11, a12 and a13 is 2 or more, and
each of R11, R12 and R13 is independently selected from the group consisting of an electron donor moiety, which is selected from a substituted or unsubstituted carbazolyl, a substituted or unsubstituted indolocarbazolyl and a substituted or unsubstituted C6 to C30 arylamine group, a group represented by Formula 1-2, deuterium, halogen, cyano, a substituted or unsubstituted C1 to C20 alkyl group, a substituted or unsubstituted C6 to C30 aryl group and a substituted or unsubstituted C1 to C60 alkylamine group.

In Formula 1-2,
each of a14, a15 and a16 is independently an integer of 0 to 5, and a17 is an integer of 0 to 4, and
each of R14, R15, R16 and R17 is independently selected from the group consisting of deuterium, halogen, cyano, a substituted or unsubstituted C1 to C20 alkyl group, a substituted or unsubstituted C6 to C30 aryl group, a substituted or unsubstituted C3 to C60 heteroaryl group, a substituted or unsubstituted C1 to C60 alkylamine group and a substituted or unsubstituted C6 to C30 arylamine group.

In the present disclosure, without specific definition, a substituent may be selected from deuterium, a C1 to C20 alkyl group and a C6 to C30 aryl group.

In the present disclosure, without specific definition, a C6 to C30 aryl group may be selected from the group consisting of phenyl, biphenyl, terphenyl, naphthyl, anthracenyl, pentanenyl, indenyl, indenoindenyl, heptalenyl, biphenylenyl, indacenyl, phenanthrenyl, benzophenanthrenyl, dibenzophenanthrenyl, azulenyl, pyrenyl, fluoranthenyl, triphenylenyl, chrysenyl, tetraphenyl, tetrasenyl, picenyl, pentaphenyl, pentacenyl, fluorenyl, indenofluorenyl and spiro-fluorenyl.

In the present disclosure, without specific definition, a C3 to C60 heteroaryl group may be selected from the group consisting of pyrrolyl, pyridinyl, pyrimidinyl, pyrazinyl, pyridazinyl, triazinyl, tetrazinyl, imidazolyl, pyrazolyl, indolyl, isoindolyl, indazolyl, indolizinyl, pyrrolizinyl, carbazolyl, benzocarbazolyl, dibenzocarbazolyl, indolocarbazolyl, indenocarbazolyl, benzofurocarbazolyl, benzothienocarbazolyl, quinolinyl, isoquinolinyl, phthalazinyl, quinoxalinyl, cinnolinyl, quinazolinyl, quinozolinyl, purinyl, benzoquinolinyl, benzoisoquinolinyl, benzoquinazolinyl, benzoquinoxalinyl, acridinyl, phenanthrolinyl, perimidinyl, phenanthridinyl, pteridinyl, naphtharidinyl, furanyl, oxazinyl, oxazolyl, oxadiazolyl, triazolyl, dioxynyl, benzofuranyl, dibenzofuranyl, thiopyranyl, xanthenyl, chromanyl, isochromanyl, thioazinyl, thiophenyl, benzothiophenyl, dibenzothiophenyl, difuropyrazinyl, benzofurodibenzofuranyl, benzothienobenzothiophenyl, benzothienodibenzothiophenyl, benzothienobenzofuranyl, and benzothienodibenzofuranyl.

For example, the first compound 242 may be represented by Formula 1.

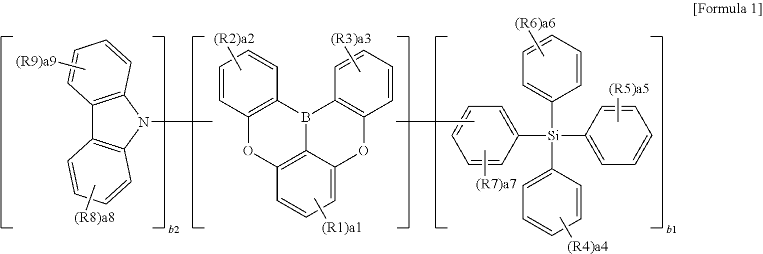

In Formula 1,
a1 is an integer of 0 to 3, each of a2 and a3 is independently an integer of 0 to 4, and a summation of a1, a2 and a3 is 9 or less,
each of a4, a5 and a6 is independently an integer of 0 to 5, and each of a7, a8 and a9 is independently an integer of 0 to 4,
each of b1 and b2 is independently an integer of 1 to 10, and a summation of b1 and b2 is 11 or less,
each of R1, R2, R3, R4, R5, R6 and R7 is independently selected from the group consisting of deuterium, halogen, cyano, a substituted or unsubstituted C1 to C20 alkyl group, a substituted or unsubstituted C6 to C30 aryl group, a substituted or unsubstituted C3 to C60 heteroaryl group, a substituted or unsubstituted C1 to C60 alkylamine group and a substituted or unsubstituted C6 to C30 arylamine group,
each of R8 and R9 is independently selected from the group consisting of deuterium, halogen, cyano, a substituted or unsubstituted C1 to C20 alkyl group, a substituted or unsubstituted C6 to C30 aryl group, a substituted or unsubstituted C3 to C60 heteroaryl group, a substituted or unsubstituted C1 to C60 alkylamine group and a substituted or unsubstituted C6 to C30 arylamine group, or adjacent two R8 and/or adjacent two R9 are connected to each other to form a substituted or unsubstituted aromatic ring or a substituted or unsubstituted heteroaromatic ring.

In an aspect of the present disclosure, b1 may be 1, and b2 may be 1 or 2.

In an aspect of the present disclosure, adjacent two R8 or adjacent two R9 may be connected to each other to form a nitrogen-containing heteroaromatic ring. For example, Formula 1 may be represented by one of Formulas 1a to 1f.

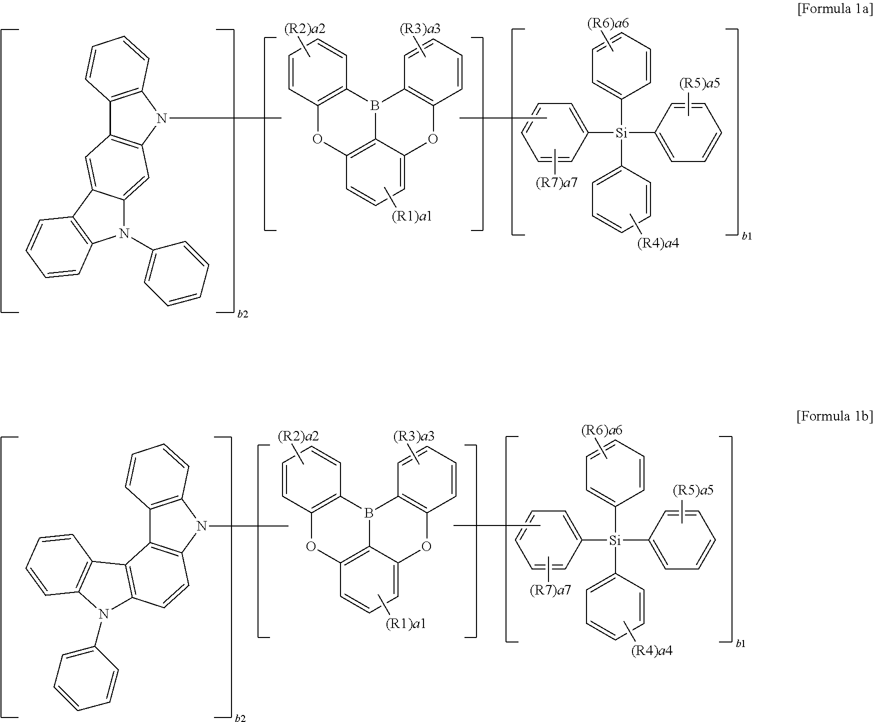

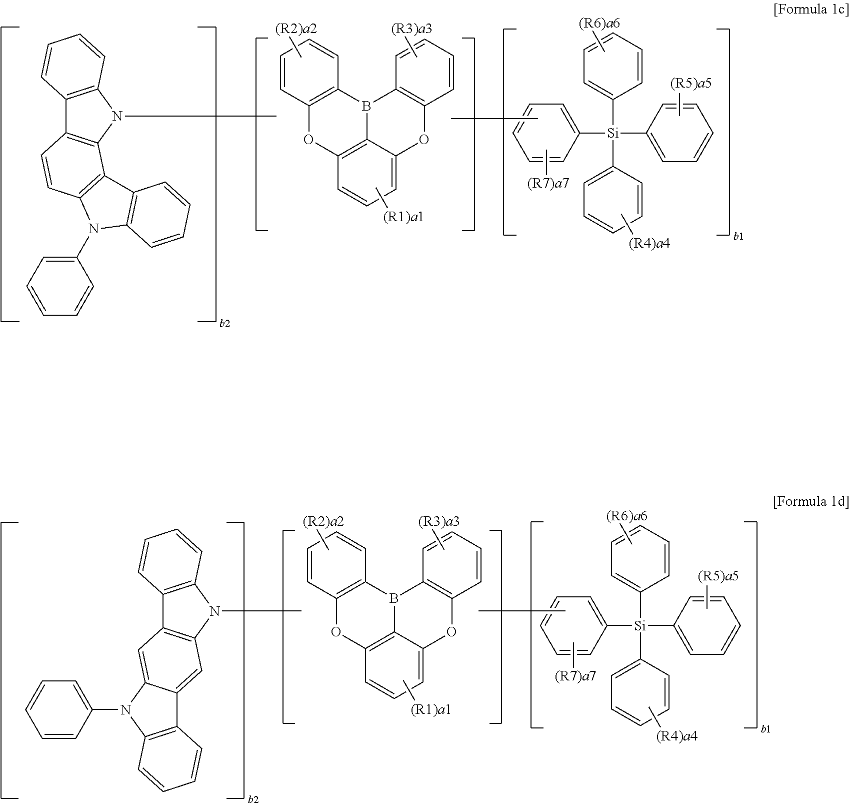

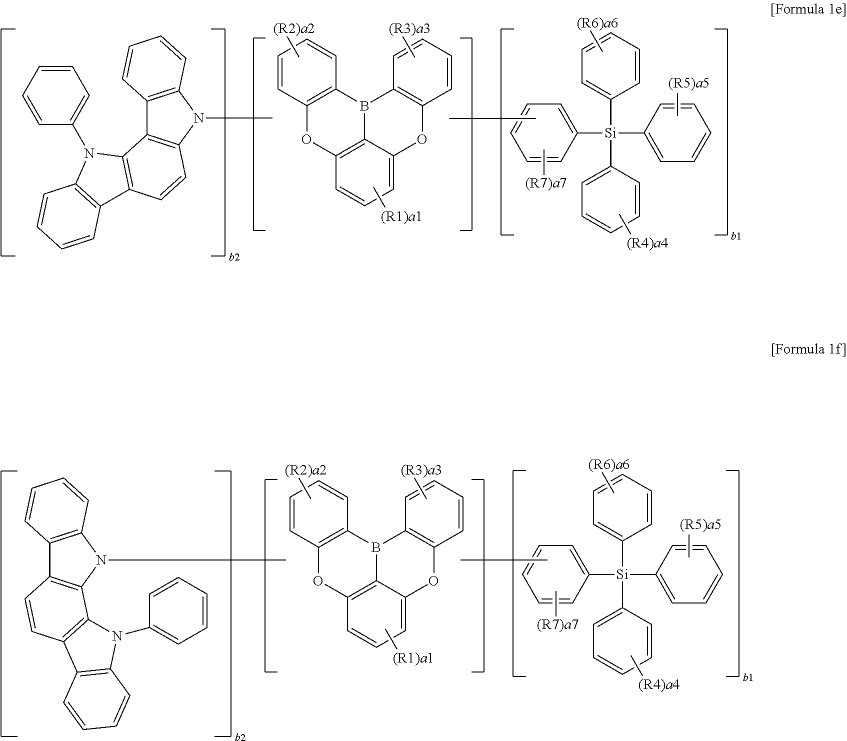

In each of Formulas 1a to 1f,
a1 is an integer of 0 to 3, each of a2 and a3 is independently an integer of 0 to 4, and a summation of a1, a2 and a3 is 9 or less,
each of a4, a5 and a6 is independently an integer of 0 to 5, and a7 is an integer of 0 to 4,
each of b1 and b2 is independently an integer of 1 to 10, and a summation of b1 and b2 is 11 or less,
each of R1, R2, R3, R4, R5, R6 and R7 is independently selected from the group consisting of deuterium, halogen, cyano, a substituted or unsubstituted C1 to C20 alkyl group, a substituted or unsubstituted C6 to C30 aryl group, a substituted or unsubstituted C3 to C60 heteroaryl group, a substituted or unsubstituted C1 to C60 alkylamine group and a substituted or unsubstituted C6 to C30 arylamine group.

For example, the first compound 242 as an n-type host may be one of compounds in Formula 2.

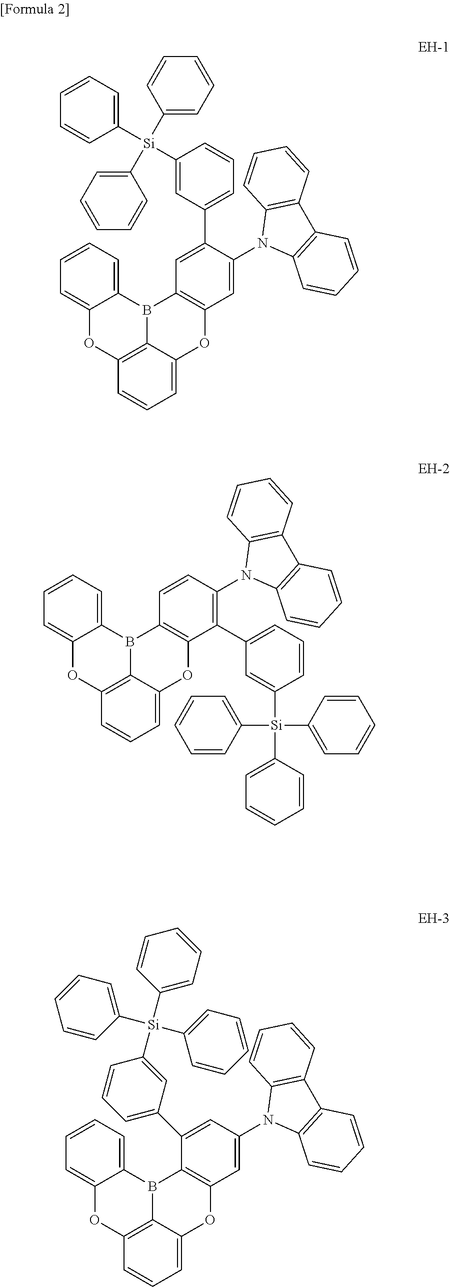 [SMILES: c1ccc([Si](c2ccccc2)(c2ccccc2)c2cccc(-c3cc4c(cc3-n3c5ccccc5c5ccccc53)Oc3cccc5c3B4c3ccccc3O5)c2)cc1 ; c1ccc([Si](c2ccccc2)(c2ccccc2)c2cccc(-c3c(-n4c5ccccc5c5ccccc54)ccc4c3Oc3cccc5c3B4c3ccccc3O5)c2)cc1 ; c1ccc([Si](c2ccccc2)(c2ccccc2)c2cccc(-c3cc(-n4c5ccccc5c5ccccc54)cc4c3B3c5ccccc5Oc5cccc(c53)O4)c2)cc1]

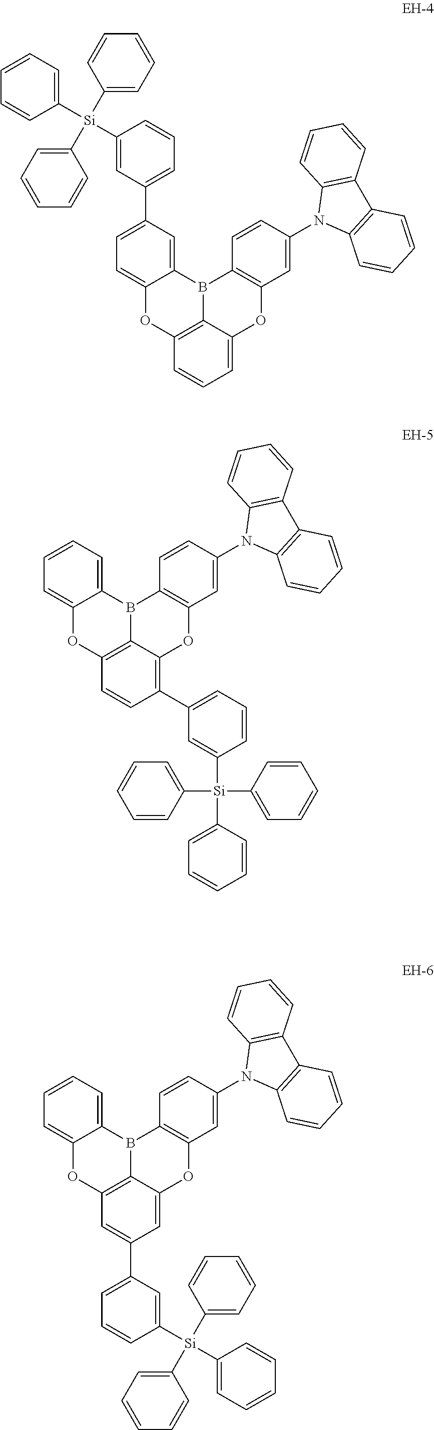 [SMILES: c1ccc([Si](c2ccccc2)(c2ccccc2)c2cccc(-c3ccc4c(c3)B3c5ccc(-n6c7ccccc7c7ccccc76)cc5Oc5cccc(c53)O4)c2)cc1 ; c1ccc([Si](c2ccccc2)(c2ccccc2)c2cccc(-c3ccc4c5c3Oc3cc(-n6c7ccccc7c7ccccc76)ccc3B5c3ccccc3O4)c2)cc1 ; c1ccc([Si](c2ccccc2)(c2ccccc2)c2cccc(-c3cc4c5c(c3)Oc3cc(-n6c7ccccc7c7ccccc76)ccc3B5c3ccccc3O4)c2)cc1]

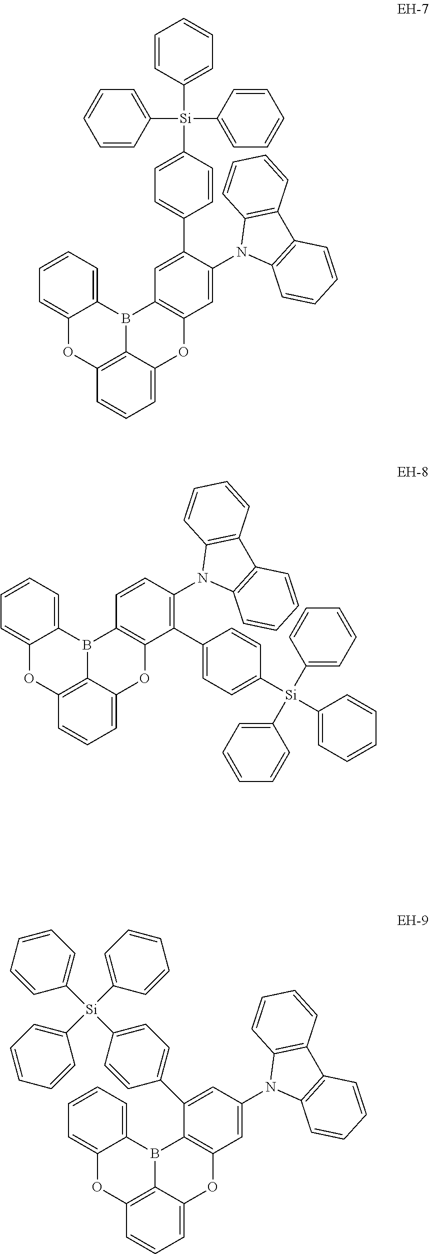 [SMILES: c1ccc([Si](c2ccccc2)(c2ccccc2)c2ccc(-c3cc4c(cc3-n3c5ccccc5c5ccccc53)Oc3cccc5c3B4c3ccccc3O5)cc2)cc1 ; c1ccc([Si](c2ccccc2)(c2ccccc2)c2ccc(-c3c(-n4c5ccccc5c5ccccc54)ccc4c3Oc3cccc5c3B4c3ccccc3O5)cc2)cc1 ; c1ccc([Si](c2ccccc2)(c2ccccc2)c2ccc(-c3cc(-n4c5ccccc5c5ccccc54)cc4c3B3c5ccccc5Oc5cccc(c53)O4)cc2)cc1]

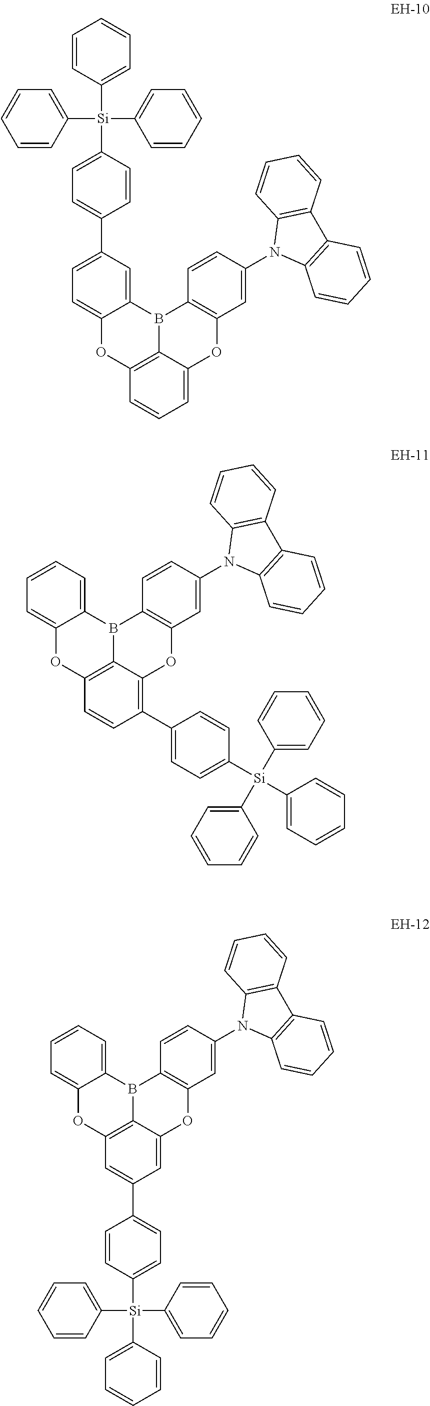 [SMILES: c1ccc([Si](c2ccccc2)(c2ccccc2)c2ccc(-c3ccc4c(c3)B3c5ccc(-n6c7ccccc7c7ccccc76)cc5Oc5cccc(c53)O4)cc2)cc1 ; c1ccc([Si](c2ccccc2)(c2ccccc2)c2ccc(-c3ccc4c5c3Oc3cc(-n6c7ccccc7c7ccccc76)ccc3B5c3ccccc3O4)cc2)cc1 ; c1ccc([Si](c2ccccc2)(c2ccccc2)c2ccc(-c3cc4c5c(c3)Oc3cc(-n6c7ccccc7c7ccccc76)ccc3B5c3ccccc3O4)cc2)cc1]

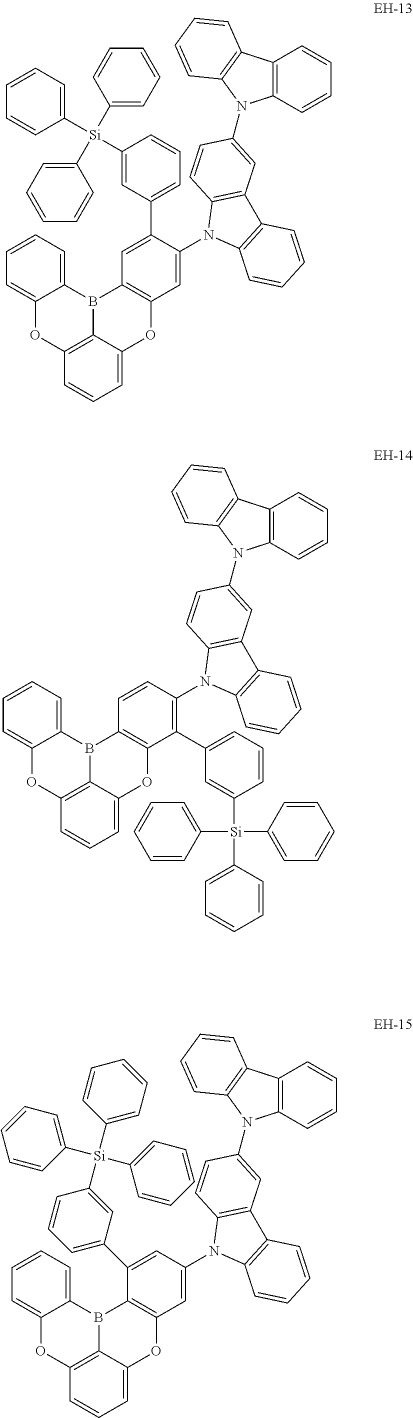 [SMILES: c1ccc([Si](c2ccccc2)(c2ccccc2)c2cccc(-c3cc4c(cc3-n3c5ccccc5c5cc(-n6c7ccccc7c7ccccc76)ccc53)Oc3cccc5c3B4c3ccccc3O5)c2)cc1 ; c1ccc([Si](c2ccccc2)(c2ccccc2)c2cccc(-c3c(-n4c5ccccc5c5cc(-n6c7ccccc7c7ccccc76)ccc54)ccc4c3Oc3cccc5c3B4c3ccccc3O5)c2)cc1 ; c1ccc([Si](c2ccccc2)(c2ccccc2)c2cccc(-c3cc(-n4c5ccccc5c5cc(-n6c7ccccc7c7ccccc76)ccc54)cc4c3B3c5ccccc5Oc5cccc(c53)O4)c2)cc1]

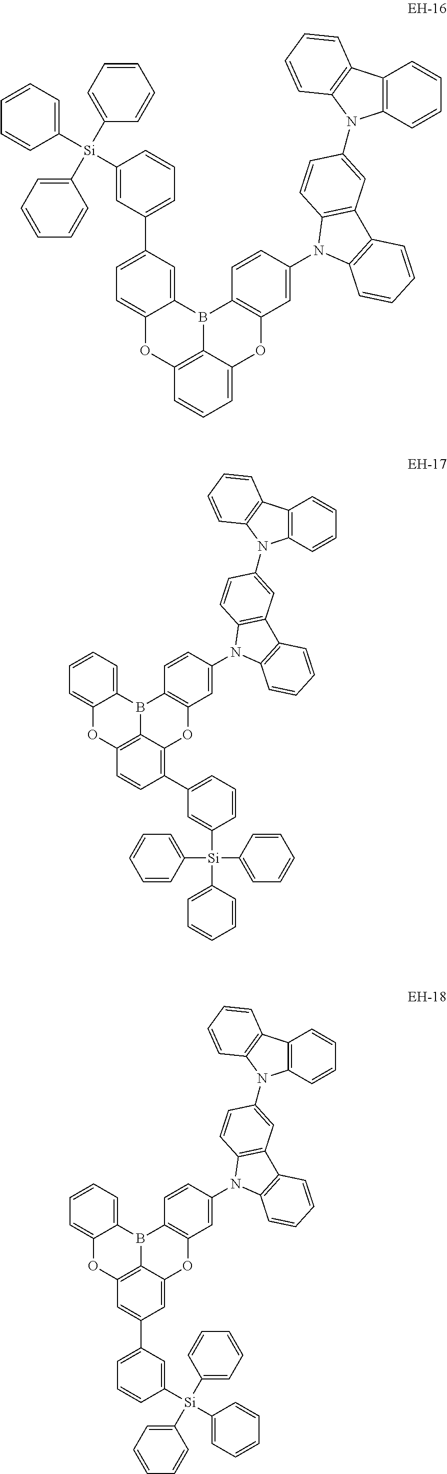 [SMILES: c1ccc([Si](c2ccccc2)(c2ccccc2)c2cccc(-c3ccc4c(c3)B3c5ccc(-n6c7ccccc7c7cc(-n8c9ccccc9c9ccccc98)ccc76)cc5Oc5cccc(c53)O4)c2)cc1 ; c1ccc([Si](c2ccccc2)(c2ccccc2)c2cccc(-c3ccc4c5c3Oc3cc(-n6c7ccccc7c7cc(-n8c9ccccc9c9ccccc98)ccc76)ccc3B5c3ccccc3O4)c2)cc1 ; c1ccc([Si](c2ccccc2)(c2ccccc2)c2cccc(-c3cc4c5c(c3)Oc3cc(-n6c7ccccc7c7cc(-n8c9ccccc9c9ccccc98)ccc76)ccc3B5c3ccccc3O4)c2)cc1]

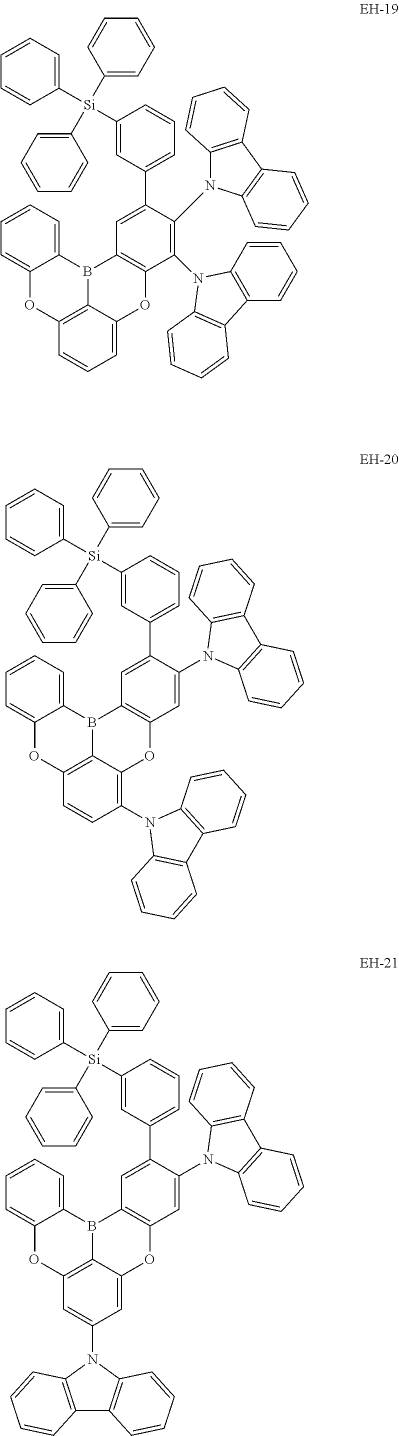 [SMILES: c1ccc([Si](c2ccccc2)(c2ccccc2)c2cccc(-c3cc4c(c(-n5c6ccccc6c6ccccc65)c3-n3c5ccccc5c5ccccc53)Oc3cccc5c3B4c3ccccc3O5)c2)cc1 ; c1ccc([Si](c2ccccc2)(c2ccccc2)c2cccc(-c3cc4c(cc3-n3c5ccccc5c5ccccc53)Oc3c(-n5c6ccccc6c6ccccc65)ccc5c3B4c3ccccc3O5)c2)cc1 ; c1ccc([Si](c2ccccc2)(c2ccccc2)c2cccc(-c3cc4c(cc3-n3c5ccccc5c5ccccc53)Oc3cc(-n5c6ccccc6c6ccccc65)cc5c3B4c3ccccc3O5)c2)cc1]

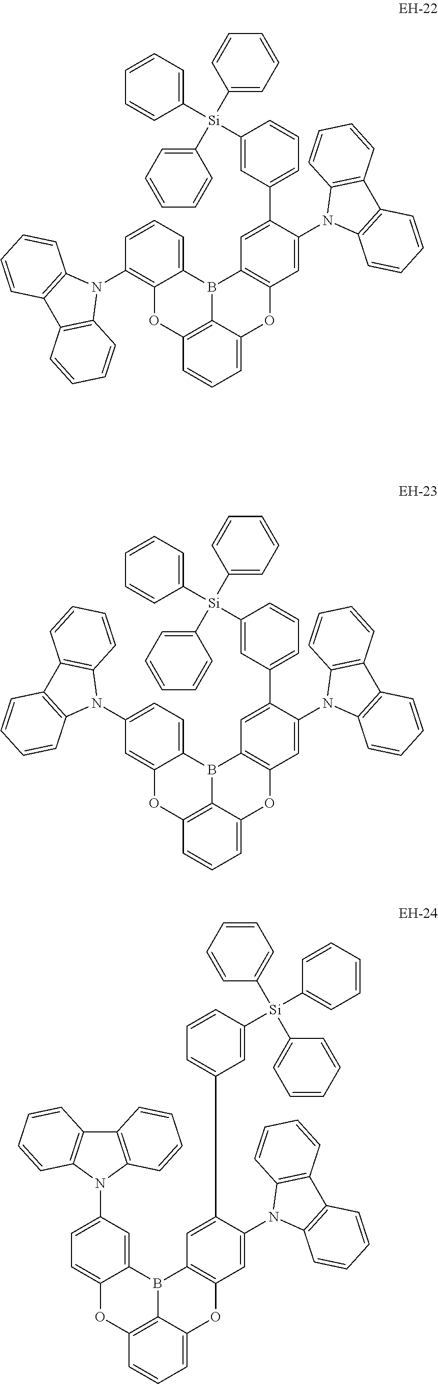 [SMILES: c1ccc([Si](c2ccccc2)(c2ccccc2)c2cccc(-c3cc4c(cc3-n3c5ccccc5c5ccccc53)Oc3cccc5c3B4c3cccc(-n4c6ccccc6c6ccccc64)c3O5)c2)cc1 ; c1ccc([Si](c2ccccc2)(c2ccccc2)c2cccc(-c3cc4c(cc3-n3c5ccccc5c5ccccc53)Oc3cccc5c3B4c3ccc(-n4c6ccccc6c6ccccc64)cc3O5)c2)cc1 ; c1ccc([Si](c2ccccc2)(c2ccccc2)c2cccc(-c3cc4c(cc3-n3c5ccccc5c5ccccc53)Oc3cccc5c3B4c3cc(-n4c6ccccc6c6ccccc64)ccc3O5)c2)cc1]

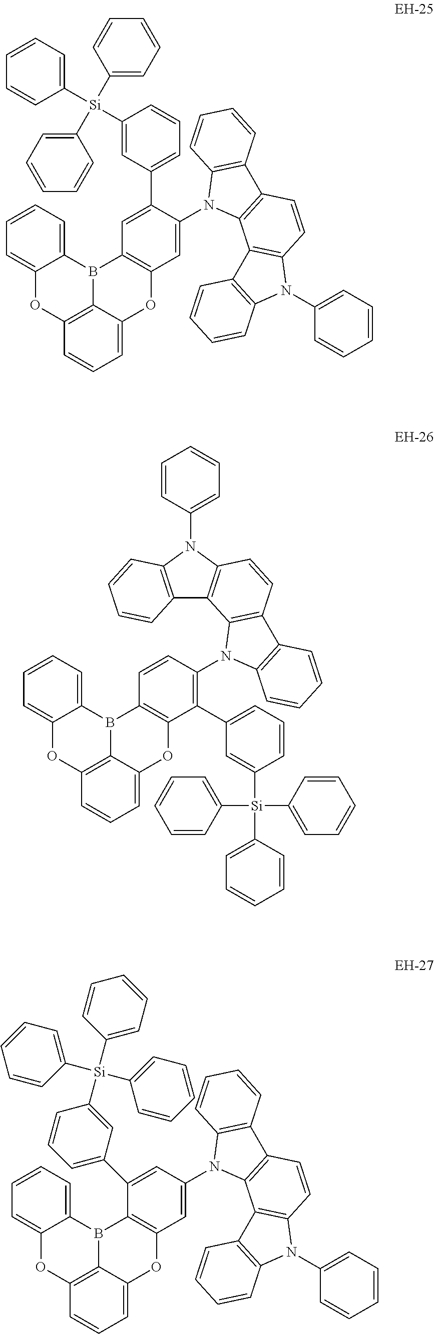 [SMILES: c1ccc(-n2c3ccccc3c3c2ccc2c4ccccc4n(-c4cc5c(cc4-c4cccc([Si](c6ccccc6)(c6ccccc6)c6ccccc6)c4)B4c6ccccc6Oc6cccc(c64)O5)c23)cc1 ; c1ccc(-n2c3ccccc3c3c2ccc2c4ccccc4n(-c4ccc5c(c4-c4cccc([Si](c6ccccc6)(c6ccccc6)c6ccccc6)c4)Oc4cccc6c4B5c4ccccc4O6)c23)cc1 ; c1ccc(-n2c3ccccc3c3c2ccc2c4ccccc4n(-c4cc5c(c(-c6cccc([Si](c7ccccc7)(c7ccccc7)c7ccccc7)c6)c4)B4c6ccccc6Oc6cccc(c64)O5)c23)cc1]

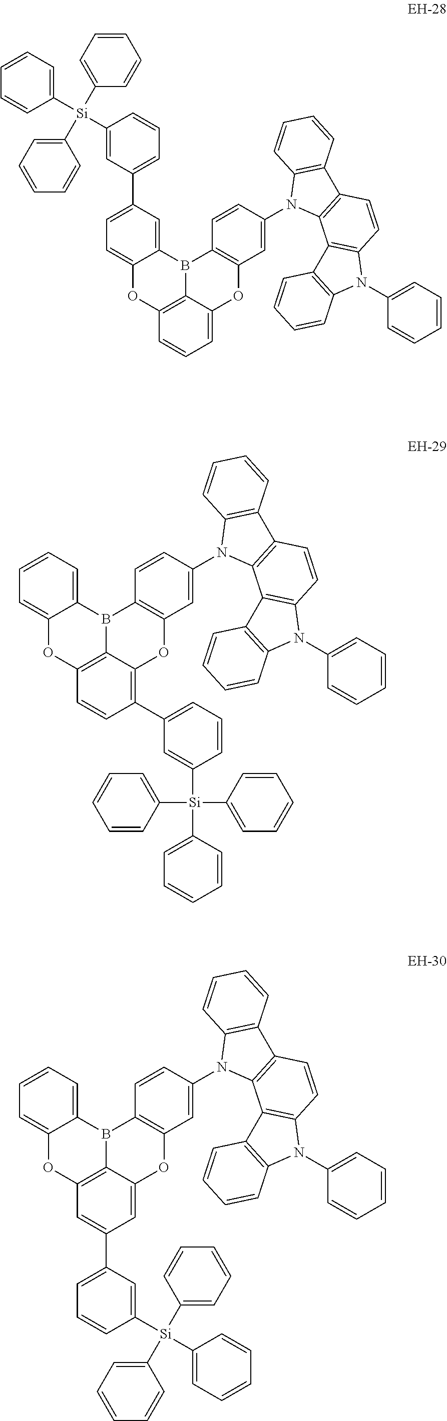 [SMILES: c1ccc(-n2c3ccccc3c3c2ccc2c4ccccc4n(-c4ccc5c(c4)Oc4cccc6c4B5c4cc(-c5cccc([Si](c7ccccc7)(c7ccccc7)c7ccccc7)c5)ccc4O6)c23)cc1 ; c1ccc(-n2c3ccccc3c3c2ccc2c4ccccc4n(-c4ccc5c(c4)Oc4c(-c6cccc([Si](c7ccccc7)(c7ccccc7)c7ccccc7)c6)ccc6c4B5c4ccccc4O6)c23)cc1 ; c1ccc(-n2c3ccccc3c3c2ccc2c4ccccc4n(-c4ccc5c(c4)Oc4cc(-c6cccc([Si](c7ccccc7)(c7ccccc7)c7ccccc7)c6)cc6c4B5c4ccccc4O6)c23)cc1]

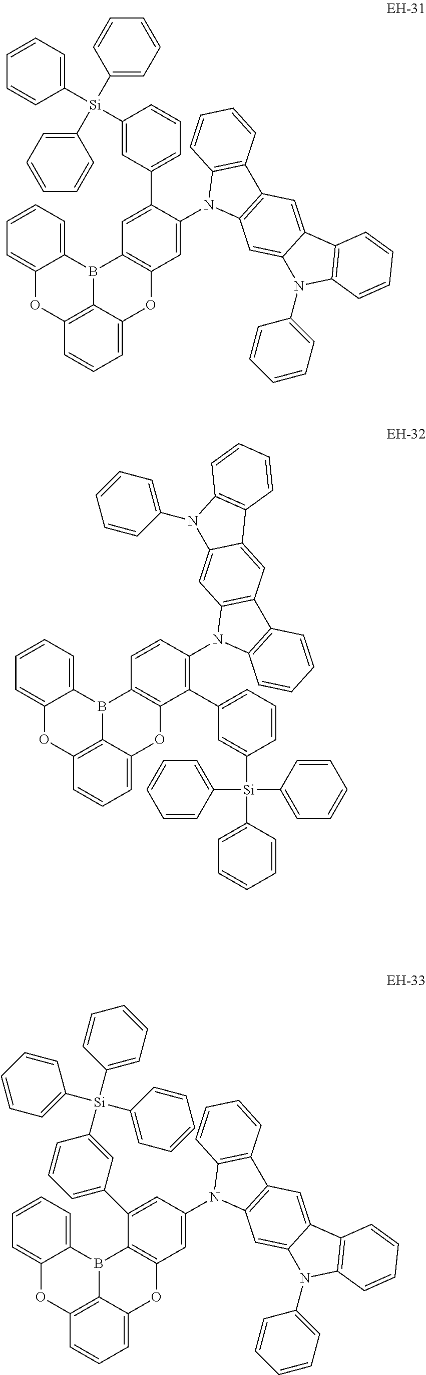 [SMILES: c1ccc(-n2c3ccccc3c3cc4c5ccccc5n(-c5cc6c(cc5-c5cccc([Si](c7ccccc7)(c7ccccc7)c7ccccc7)c5)B5c7ccccc7Oc7cccc(c75)O6)c4cc32)cc1 ; c1ccc(-n2c3ccccc3c3cc4c5ccccc5n(-c5ccc6c(c5-c5cccc([Si](c7ccccc7)(c7ccccc7)c7ccccc7)c5)Oc5cccc7c5B6c5ccccc5O7)c4cc32)cc1 ; c1ccc(-n2c3ccccc3c3cc4c5ccccc5n(-c5cc6c(c(-c7cccc([Si](c8ccccc8)(c8ccccc8)c8ccccc8)c7)c5)B5c7ccccc7Oc7cccc(c75)O6)c4cc32)cc1]

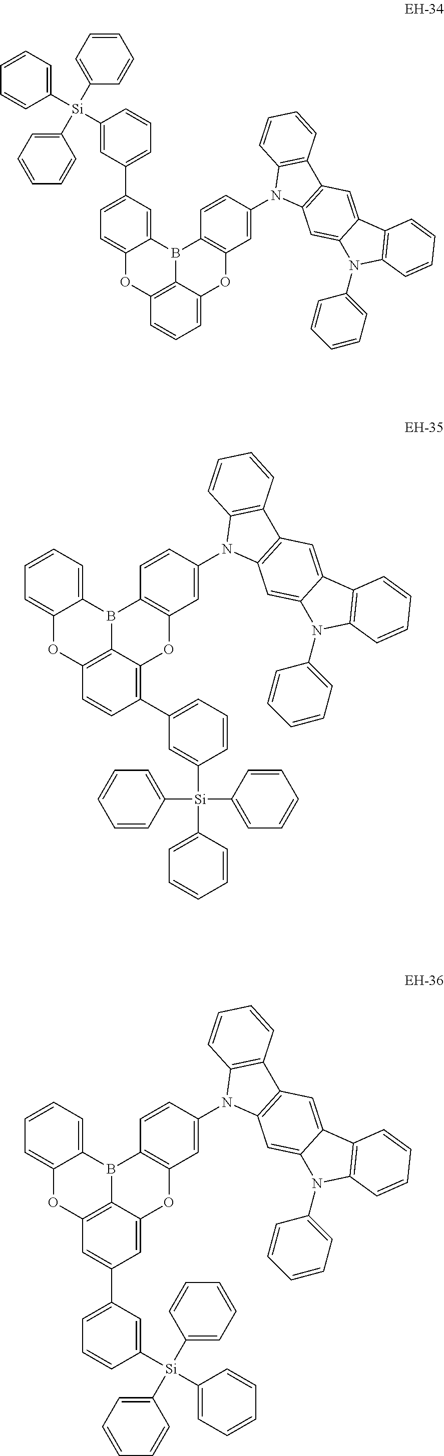 [SMILES: c1ccc(-n2c3ccccc3c3cc4c5ccccc5n(-c5ccc6c(c5)Oc5cccc7c5B6c5cc(-c6cccc([Si](c8ccccc8)(c8ccccc8)c8ccccc8)c6)ccc5O7)c4cc32)cc1 ; c1ccc(-n2c3ccccc3c3cc4c5ccccc5n(-c5ccc6c(c5)Oc5c(-c7cccc([Si](c8ccccc8)(c8ccccc8)c8ccccc8)c7)ccc7c5B6c5ccccc5O7)c4cc32)cc1 ; c1ccc(-n2c3ccccc3c3cc4c5ccccc5n(-c5ccc6c(c5)Oc5cc(-c7cccc([Si](c8ccccc8)(c8ccccc8)c8ccccc8)c7)cc7c5B6c5ccccc5O7)c4cc32)cc1]

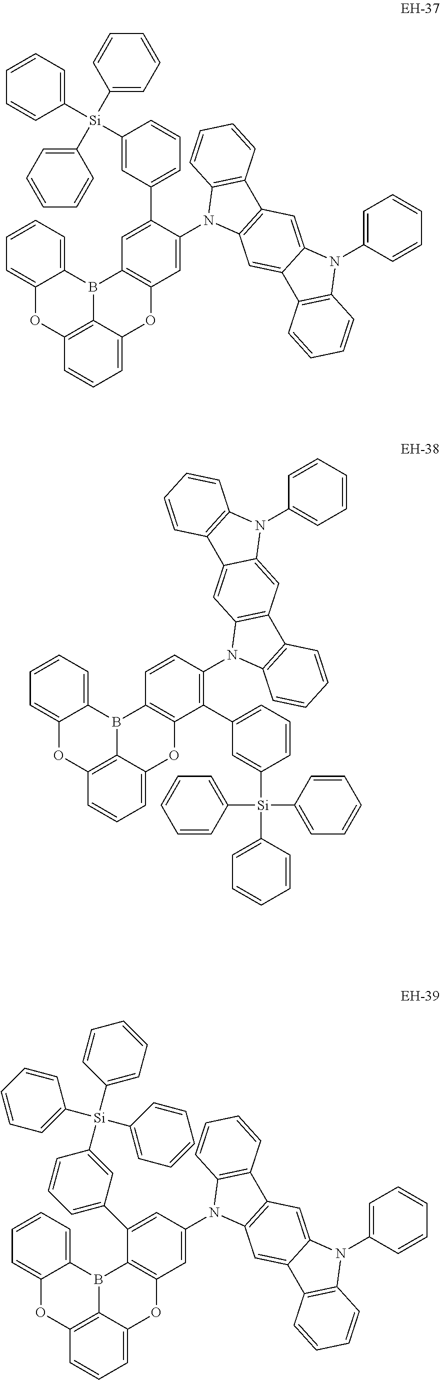 [SMILES: c1ccc(-n2c3ccccc3c3cc4c(cc32)c2ccccc2n4-c2cc3c(cc2-c2cccc([Si](c4ccccc4)(c4ccccc4)c4ccccc4)c2)B2c4ccccc4Oc4cccc(c42)O3)cc1 ; c1ccc(-n2c3ccccc3c3cc4c(cc32)c2ccccc2n4-c2ccc3c(c2-c2cccc([Si](c4ccccc4)(c4ccccc4)c4ccccc4)c2)Oc2cccc4c2B3c2ccccc2O4)cc1 ; c1ccc(-n2c3ccccc3c3cc4c(cc32)c2ccccc2n4-c2cc3c(c(-c4cccc([Si](c5ccccc5)(c5ccccc5)c5ccccc5)c4)c2)B2c4ccccc4Oc4cccc(c42)O3)cc1]

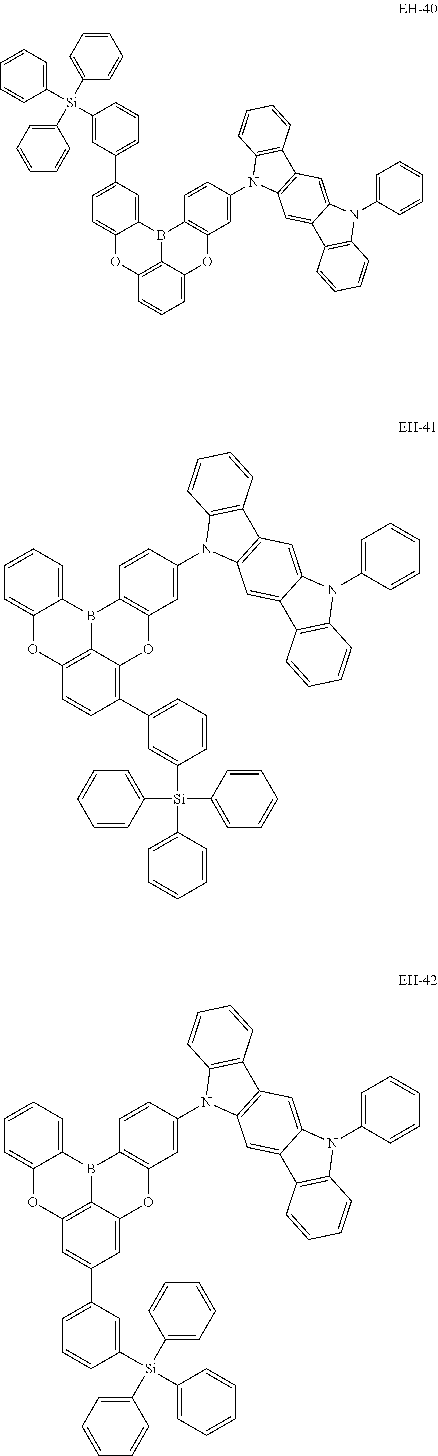 [SMILES: c1ccc(-n2c3ccccc3c3cc4c(cc32)c2ccccc2n4-c2ccc3c(c2)Oc2cccc4c2B3c2cc(-c3cccc([Si](c5ccccc5)(c5ccccc5)c5ccccc5)c3)ccc2O4)cc1 ; c1ccc(-n2c3ccccc3c3cc4c(cc32)c2ccccc2n4-c2ccc3c(c2)Oc2c(-c4cccc([Si](c5ccccc5)(c5ccccc5)c5ccccc5)c4)ccc4c2B3c2ccccc2O4)cc1 ; c1ccc(-n2c3ccccc3c3cc4c(cc32)c2ccccc2n4-c2ccc3c(c2)Oc2cc(-c4cccc([Si](c5ccccc5)(c5ccccc5)c5ccccc5)c4)cc4c2B3c2ccccc2O4)cc1]

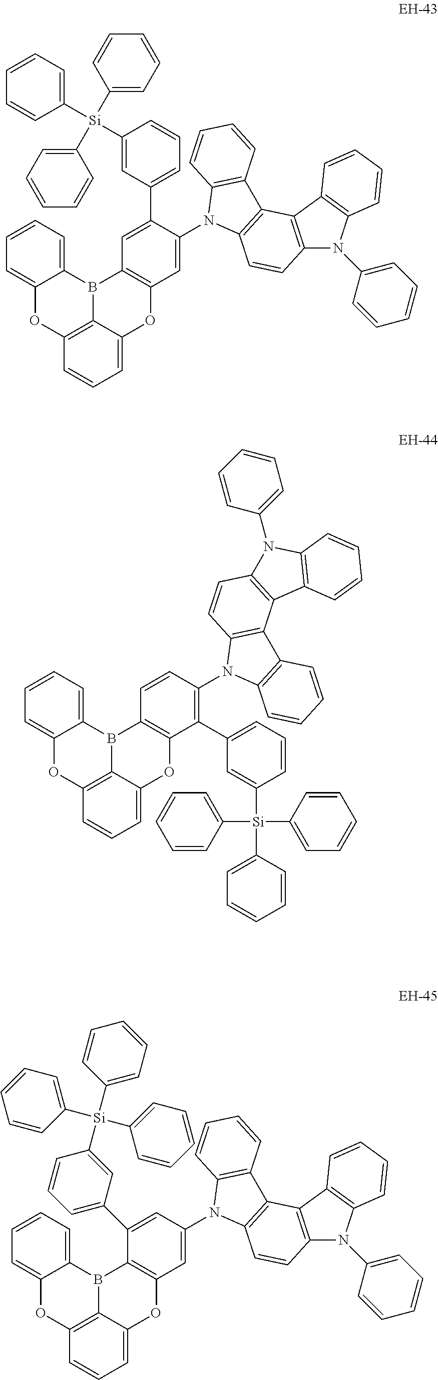 [SMILES: c1ccc(-n2c3ccccc3c3c4c5ccccc5n(-c5cc6c(cc5-c5cccc([Si](c7ccccc7)(c7ccccc7)c7ccccc7)c5)B5c7ccccc7Oc7cccc(c75)O6)c4ccc32)cc1 ; c1ccc(-n2c3ccccc3c3c4c5ccccc5n(-c5ccc6c(c5-c5cccc([Si](c7ccccc7)(c7ccccc7)c7ccccc7)c5)Oc5cccc7c5B6c5ccccc5O7)c4ccc32)cc1 ; c1ccc(-n2c3ccccc3c3c4c5ccccc5n(-c5cc6c(c(-c7cccc([Si](c8ccccc8)(c8ccccc8)c8ccccc8)c7)c5)B5c7ccccc7Oc7cccc(c75)O6)c4ccc32)cc1]

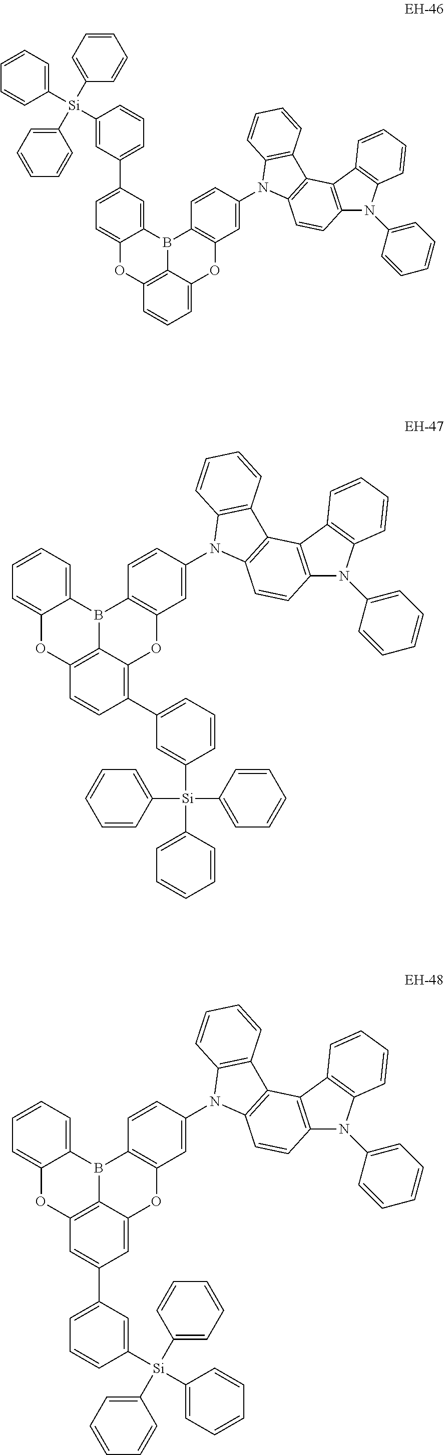 [SMILES: c1ccc(-n2c3ccccc3c3c4c5ccccc5n(-c5ccc6c(c5)Oc5cccc7c5B6c5cc(-c6cccc([Si](c8ccccc8)(c8ccccc8)c8ccccc8)c6)ccc5O7)c4ccc32)cc1 ; c1ccc(-n2c3ccccc3c3c4c5ccccc5n(-c5ccc6c(c5)Oc5c(-c7cccc([Si](c8ccccc8)(c8ccccc8)c8ccccc8)c7)ccc7c5B6c5ccccc5O7)c4ccc32)cc1 ; c1ccc(-n2c3ccccc3c3c4c5ccccc5n(-c5ccc6c(c5)Oc5cc(-c7cccc([Si](c8ccccc8)(c8ccccc8)c8ccccc8)c7)cc7c5B6c5ccccc5O7)c4ccc32)cc1]

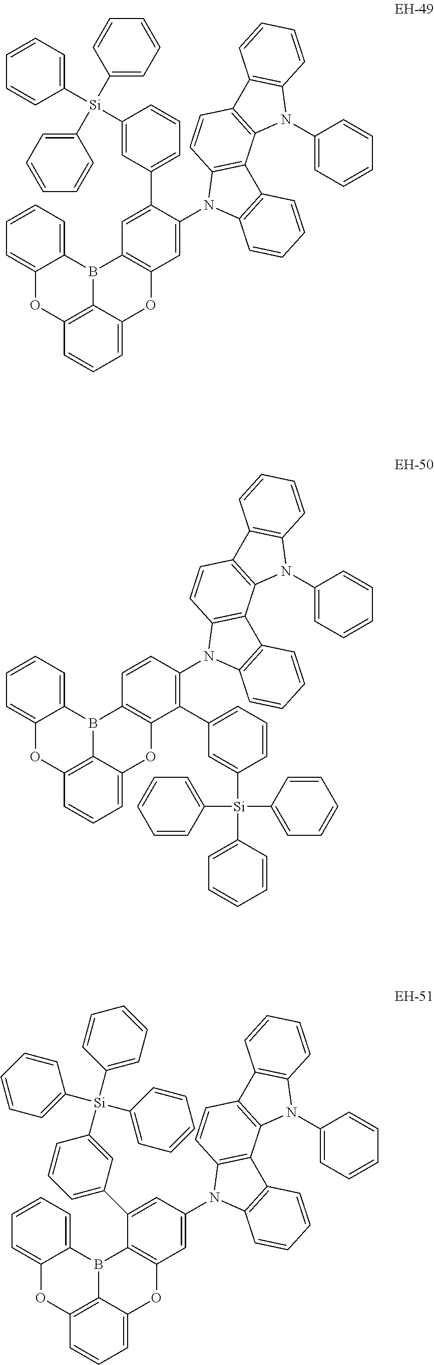 [SMILES: c1ccc(-n2c3ccccc3c3ccc4c(c5ccccc5n4-c4cc5c(cc4-c4cccc([Si](c6ccccc6)(c6ccccc6)c6ccccc6)c4)B4c6ccccc6Oc6cccc(c64)O5)c32)cc1 ; c1ccc(-n2c3ccccc3c3ccc4c(c5ccccc5n4-c4ccc5c(c4-c4cccc([Si](c6ccccc6)(c6ccccc6)c6ccccc6)c4)Oc4cccc6c4B5c4ccccc4O6)c32)cc1 ; c1ccc(-n2c3ccccc3c3ccc4c(c5ccccc5n4-c4cc5c(c(-c6cccc([Si](c7ccccc7)(c7ccccc7)c7ccccc7)c6)c4)B4c6ccccc6Oc6cccc(c64)O5)c32)cc1]

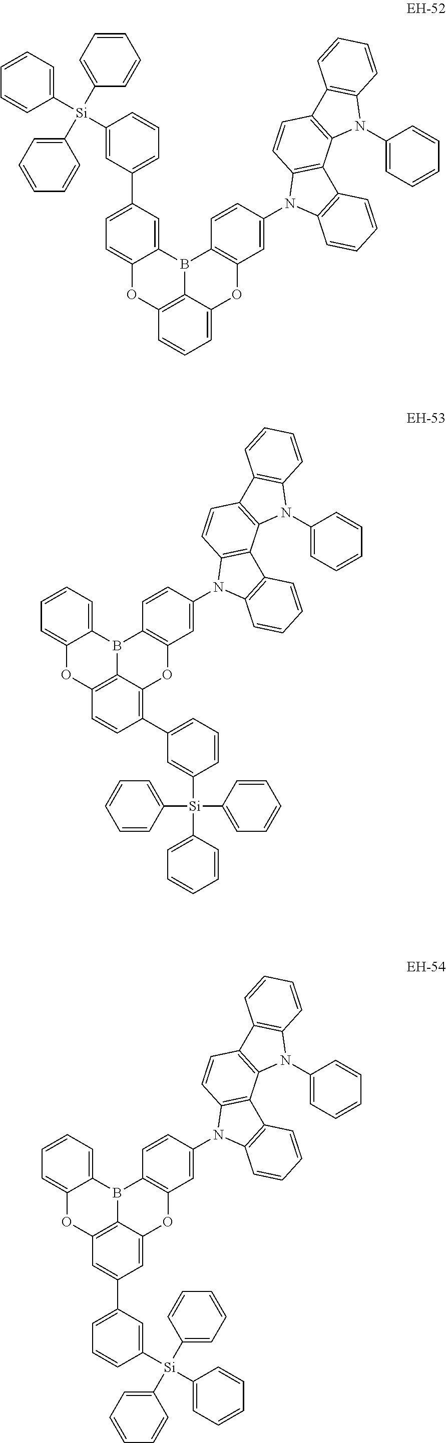 [SMILES: c1ccc(-n2c3ccccc3c3ccc4c(c5ccccc5n4-c4ccc5c(c4)Oc4cccc6c4B5c4cc(-c5cccc([Si](c7ccccc7)(c7ccccc7)c7ccccc7)c5)ccc4O6)c32)cc1 ; c1ccc(-n2c3ccccc3c3ccc4c(c5ccccc5n4-c4ccc5c(c4)Oc4c(-c6cccc([Si](c7ccccc7)(c7ccccc7)c7ccccc7)c6)ccc6c4B5c4ccccc4O6)c32)cc1 ; c1ccc(-n2c3ccccc3c3ccc4c(c5ccccc5n4-c4ccc5c(c4)Oc4cc(-c6cccc([Si](c7ccccc7)(c7ccccc7)c7ccccc7)c6)cc6c4B5c4ccccc4O6)c32)cc1]

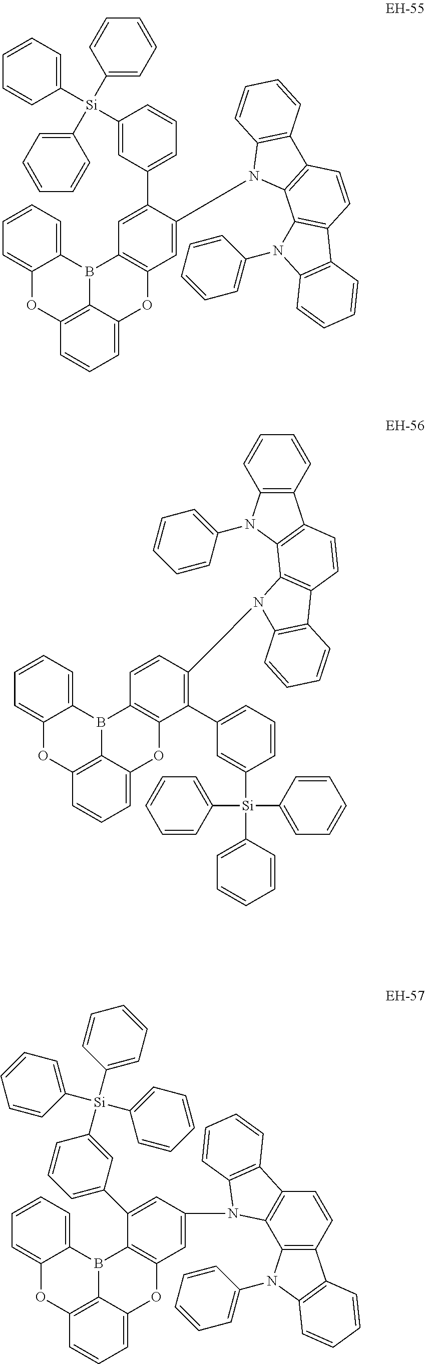 [SMILES: c1ccc(-n2c3ccccc3c3ccc4c5ccccc5n(-c5cc6c(cc5-c5cccc([Si](c7ccccc7)(c7ccccc7)c7ccccc7)c5)B5c7ccccc7Oc7cccc(c75)O6)c4c32)cc1 ; c1ccc(-n2c3ccccc3c3ccc4c5ccccc5n(-c5ccc6c(c5-c5cccc([Si](c7ccccc7)(c7ccccc7)c7ccccc7)c5)Oc5cccc7c5B6c5ccccc5O7)c4c32)cc1 ; c1ccc(-n2c3ccccc3c3ccc4c5ccccc5n(-c5cc6c(c(-c7cccc([Si](c8ccccc8)(c8ccccc8)c8ccccc8)c7)c5)B5c7ccccc7Oc7cccc(c75)O6)c4c32)cc1]

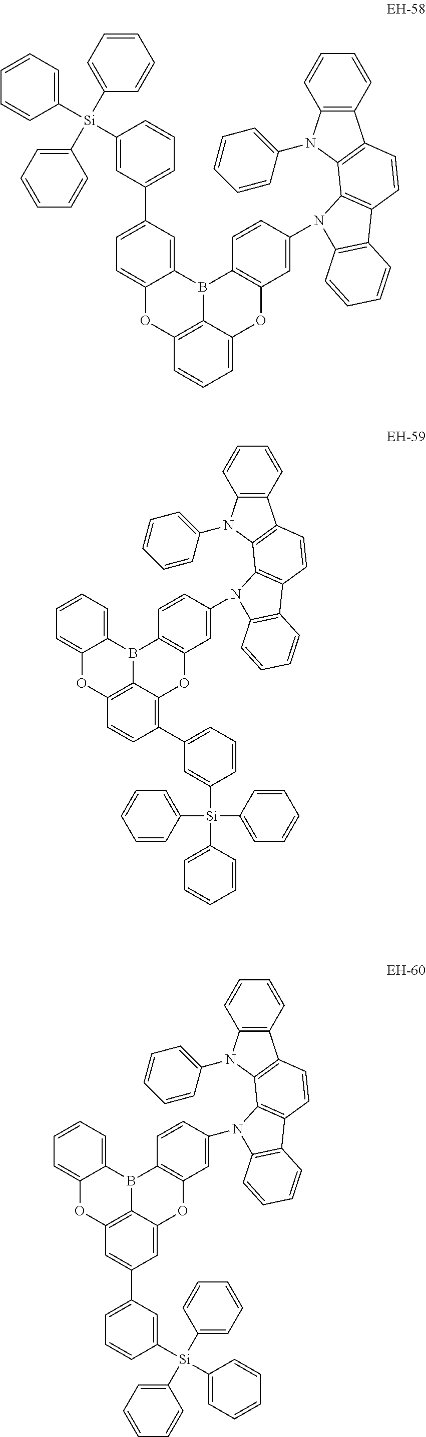 [SMILES: c1ccc(-n2c3ccccc3c3ccc4c5ccccc5n(-c5ccc6c(c5)Oc5cccc7c5B6c5cc(-c6cccc([Si](c8ccccc8)(c8ccccc8)c8ccccc8)c6)ccc5O7)c4c32)cc1 ; c1ccc(-n2c3ccccc3c3ccc4c5ccccc5n(-c5ccc6c(c5)Oc5c(-c7cccc([Si](c8ccccc8)(c8ccccc8)c8ccccc8)c7)ccc7c5B6c5ccccc5O7)c4c32)cc1 ; c1ccc(-n2c3ccccc3c3ccc4c5ccccc5n(-c5ccc6c(c5)Oc5cc(-c7cccc([Si](c8ccccc8)(c8ccccc8)c8ccccc8)c7)cc7c5B6c5ccccc5O7)c4c32)cc1]

In the EML 240, the second compound 244 is represented by Formula 3.

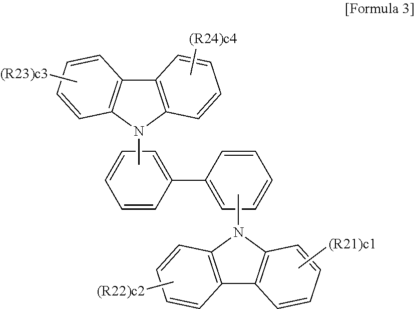

In Formula 3,
each of c1, c2, c3 and c4 is independently an integer of 0 to 4, and
each of R21, R22, R23 and R24 is independently selected from the group consisting of deuterium, halogen, cyano, a substituted or unsubstituted C1 to C20 alkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group.

In an aspect of the present disclosure, each of R21, R22, R23 and R24 may be independently selected from the group consisting of a substituted or unsubstituted C1 to C20 alkyl group, e.g., methyl, a substituted or unsubstituted C6 to C30 aryl group, e.g., phenyl, and a substituted or unsubstituted C3 to C60 heteroaryl group, e.g., carbazolyl.

In an aspect of the present disclosure, each of c1, c2, c3 and c4 may be 0.

In Formula 3, a bonding site of a carbazole group may be specified. For example, Formula 3 may be represented by Formula 3-1 or Formula 3-2.

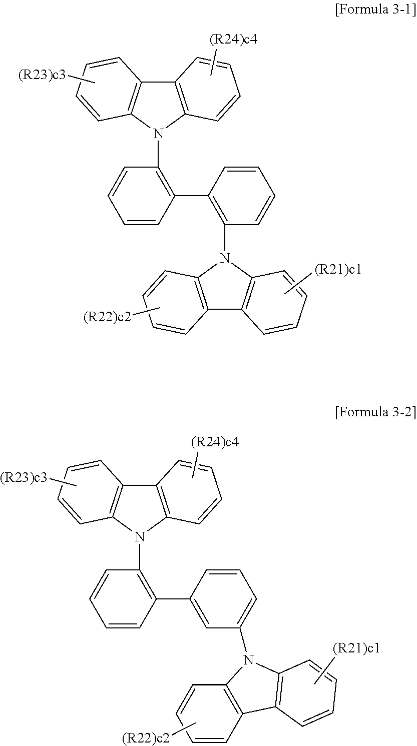

In each of Formulas 3-1 and 3-2,
each of c1, c2, c3 and c4 is independently an integer of 0 to 4, and
each of R21, R22, R23 and R24 is independently selected from the group consisting of deuterium, halogen, cyano, a substituted or unsubstituted C1 to C20 alkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group.

In an aspect of the present disclosure, c1 may be a positive integer, and R21 may be a substituted or unsubstituted C3 to C30 heteroaryl group, e.g., carbazolyl. Namely, Formula 3 may be represented by Formula 3a.

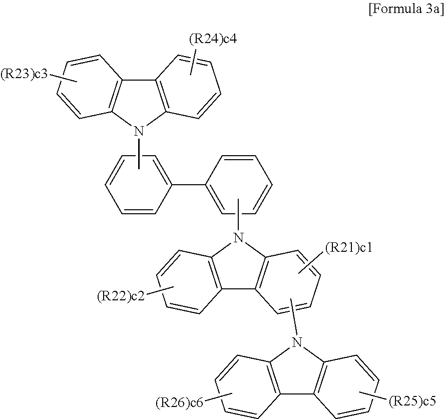

In Formula 3a,
each of c1, c2, c3, c4, c5 and c6 is independently an integer of 0 to 4, and
each of R21, R22, R23, R24, R25 and R26 is independently selected from the group consisting of deuterium, halogen, cyano, a substituted or unsubstituted C1 to C20 alkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group.

In Formula 3a, a position of a carbazolyl group and/or a biscarbazolyl group (a bicarbazolyl group) may be specified. For example, Formula 3 may be represented by Formula 3a-1 or Formula 3a-2.

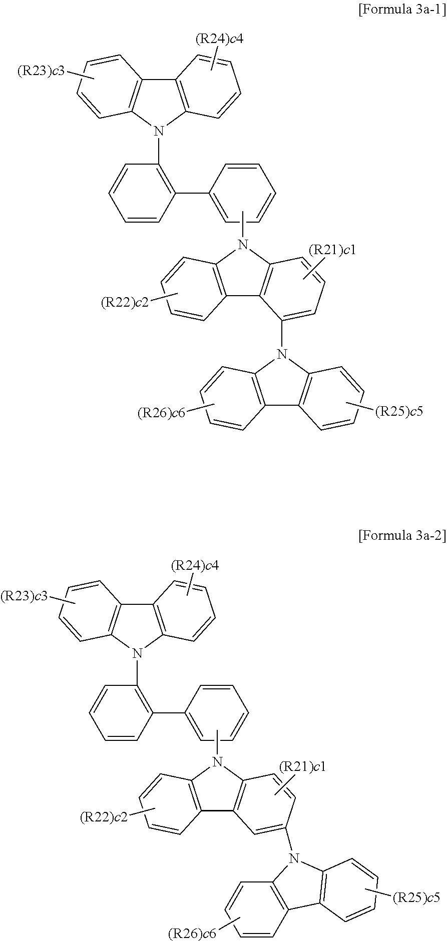

In each of Formulas 3a-1 and 3a-2,
each of c1, c2, c3, c4, c5 and c6 is independently an integer of 0 to 4, and
each of R21, R22, R23, R24, R25 and R26 is independently selected from the group consisting of deuterium, halogen, cyano, a substituted or unsubstituted C1 to C20 alkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group.

For example, the second compound 244 as a p-type host may be one of compounds in Formula 4.

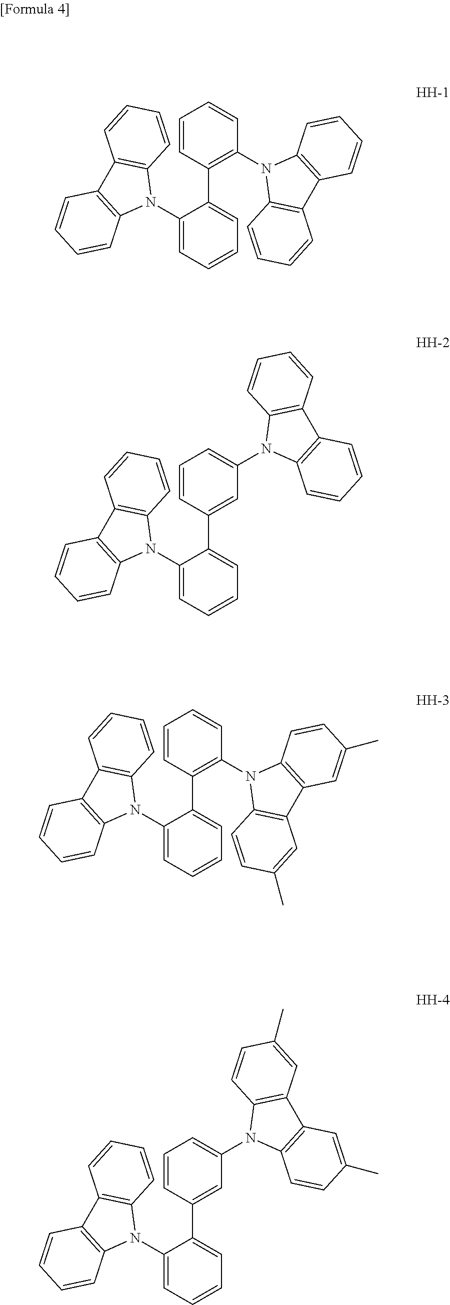 [SMILES: c1ccc(-n2c3ccccc3c3ccccc32)c(-c2ccccc2-n2c3ccccc3c3ccccc32)c1 ; c1cc(-c2ccccc2-n2c3ccccc3c3ccccc32)cc(-n2c3ccccc3c3ccccc32)c1 ; Cc1ccc2c(c1)c1cc(C)ccc1n2-c1ccccc1-c1ccccc1-n1c2ccccc2c2ccccc21 ; Cc1ccc2c(c1)c1cc(C)ccc1n2-c1cccc(-c2ccccc2-n2c3ccccc3c3ccccc32)c1]

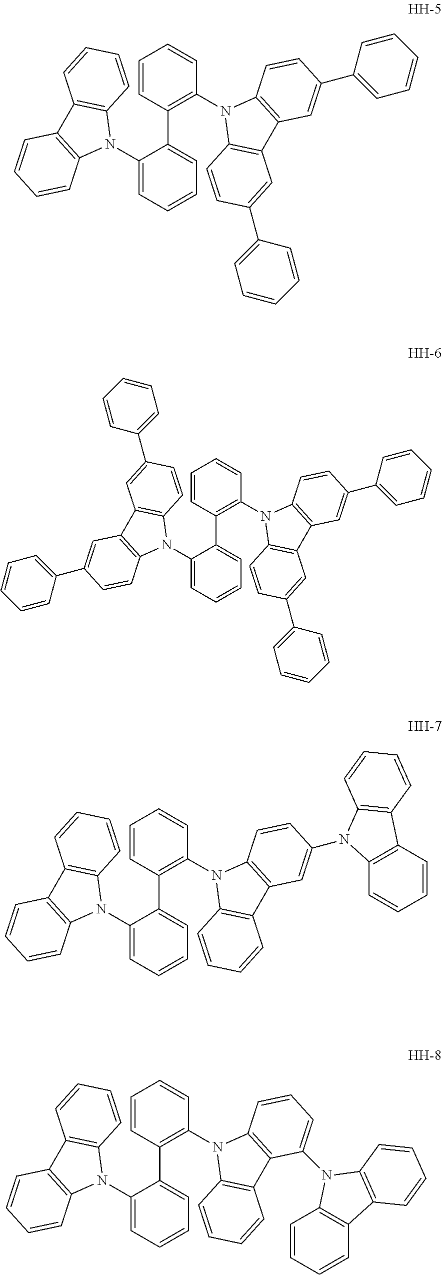 [SMILES: c1ccc(-c2ccc3c(c2)c2cc(-c4ccccc4)ccc2n3-c2ccccc2-c2ccccc2-n2c3ccccc3c3ccccc32)cc1 ; c1ccc(-c2ccc3c(c2)c2cc(-c4ccccc4)ccc2n3-c2ccccc2-c2ccccc2-n2c3ccc(-c4ccccc4)cc3c3cc(-c4ccccc4)ccc32)cc1 ; c1ccc(-n2c3ccccc3c3ccccc32)c(-c2ccccc2-n2c3ccccc3c3cc(-n4c5ccccc5c5ccccc54)ccc32)c1 ; c1ccc(-n2c3ccccc3c3ccccc32)c(-c2ccccc2-n2c3ccccc3c3c(-n4c5ccccc5c5ccccc54)cccc32)c1]

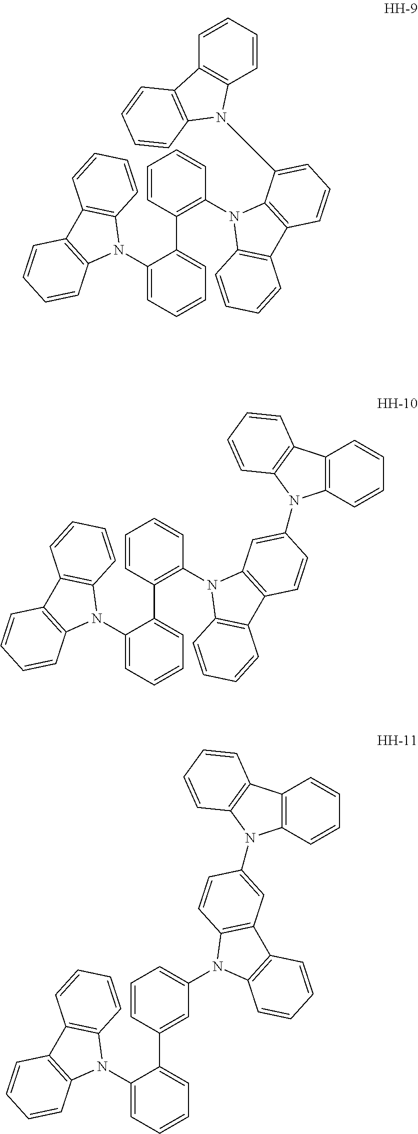 [SMILES: c1ccc(-n2c3ccccc3c3ccccc32)c(-c2ccccc2-n2c3ccccc3c3cccc(-n4c5ccccc5c5ccccc54)c32)c1 ; c1ccc(-n2c3ccccc3c3ccccc32)c(-c2ccccc2-n2c3ccccc3c3ccc(-n4c5ccccc5c5ccccc54)cc32)c1 ; c1cc(-c2ccccc2-n2c3ccccc3c3ccccc32)cc(-n2c3ccccc3c3cc(-n4c5ccccc5c5ccccc54)ccc32)c1]

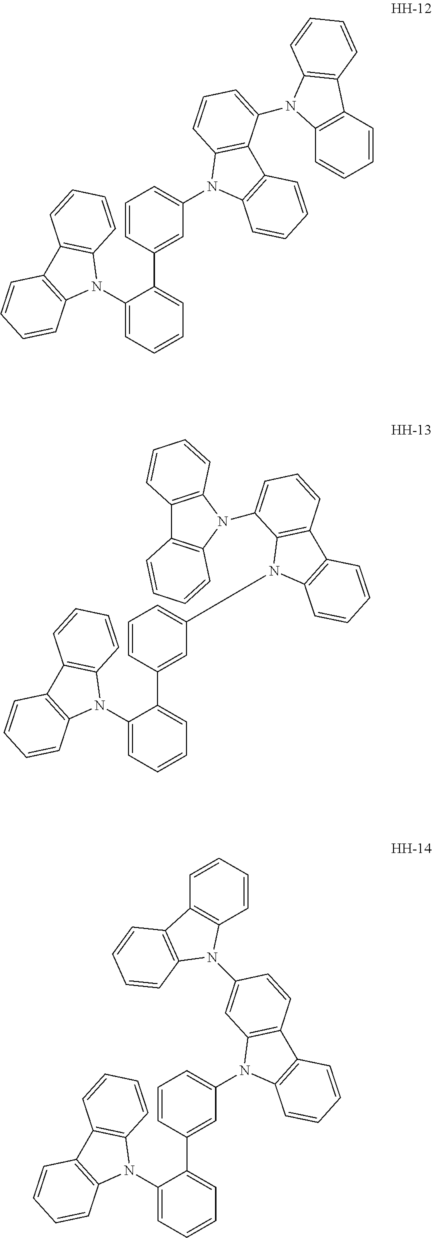 [SMILES: c1cc(-c2ccccc2-n2c3ccccc3c3ccccc32)cc(-n2c3ccccc3c3c(-n4c5ccccc5c5ccccc54)cccc32)c1 ; c1cc(-c2ccccc2-n2c3ccccc3c3ccccc32)cc(-n2c3ccccc3c3cccc(-n4c5ccccc5c5ccccc54)c32)c1 ; c1cc(-c2ccccc2-n2c3ccccc3c3ccccc32)cc(-n2c3ccccc3c3ccc(-n4c5ccccc5c5ccccc54)cc32)c1]

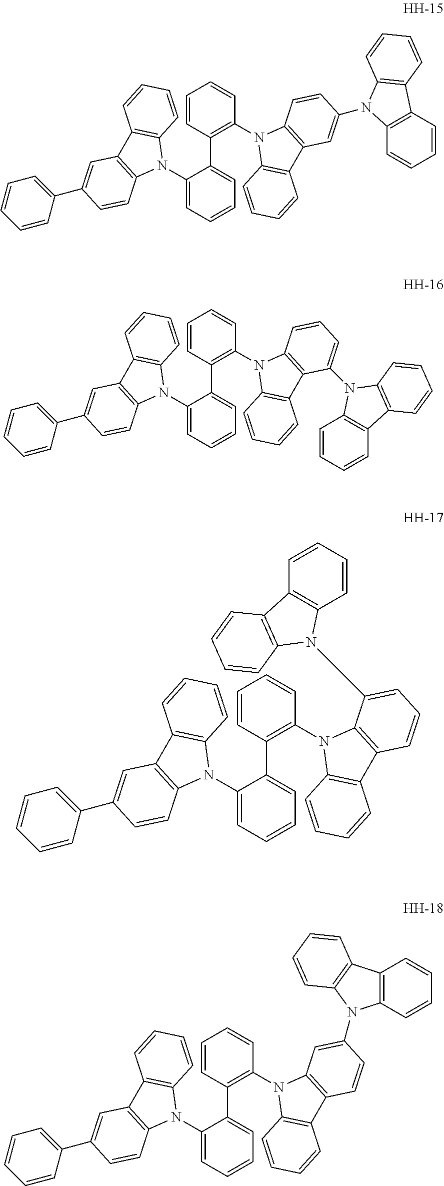 [SMILES: c1ccc(-c2ccc3c(c2)c2ccccc2n3-c2ccccc2-c2ccccc2-n2c3ccccc3c3cc(-n4c5ccccc5c5ccccc54)ccc32)cc1 ; c1ccc(-c2ccc3c(c2)c2ccccc2n3-c2ccccc2-c2ccccc2-n2c3ccccc3c3c(-n4c5ccccc5c5ccccc54)cccc32)cc1 ; c1ccc(-c2ccc3c(c2)c2ccccc2n3-c2ccccc2-c2ccccc2-n2c3ccccc3c3cccc(-n4c5ccccc5c5ccccc54)c32)cc1 ; c1ccc(-c2ccc3c(c2)c2ccccc2n3-c2ccccc2-c2ccccc2-n2c3ccccc3c3ccc(-n4c5ccccc5c5ccccc54)cc32)cc1]

A triplet energy of each of the first compound 242 and the second compound 244 may be greater than 2.7 eV.

In the EML 240, the third compound 246 as a phosphorescent dopant is represented by Formula 5.

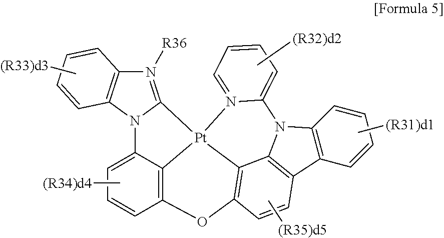

In Formula 5,
each of R31, R32, R33, R34, R35 and R36 is independently selected from the group consisting of deuterium, halogen, cyano, a substituted or unsubstituted C1 to C20 alkyl group, a substituted or unsubstituted C3 to C30 cycloalkyl group, a substituted or unsubstituted C1 to C20 alkylsilyl group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group,
each of d1, d2 and d3 is independently an integer of 0 to 4, d4 is an integer of 0 to 3, and d5 is an integer of 0 to 2.

In an aspect of the present disclosure, each of R31, R32, R33, R34, R35 and R36 may be independently selected from the group consisting of a substituted or unsubstituted C1 to C20 alkyl group, e.g., methyl or tert-butyl, a substituted or unsubstituted C3 to C30 cycloalkyl group, e.g., adamantanyl, and a substituted or unsubstituted C6 to C30 aryl group, e.g., phenyl. In addition, at least one of d1, d2, d3, d4 and d5 may be a positive integer.

For example, the third compound 246 as the phosphorescent dopant may be one of compounds in Formula 6.

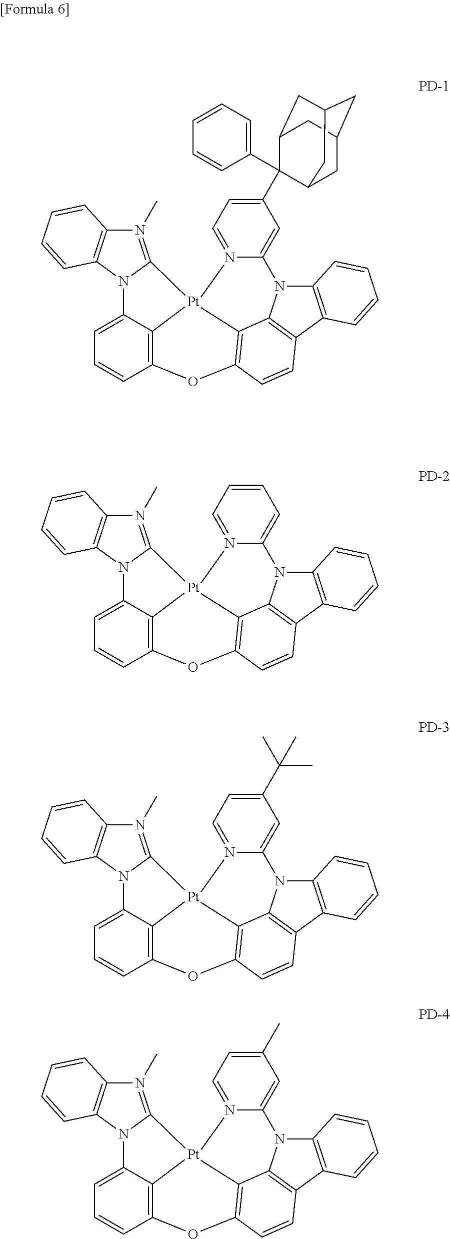

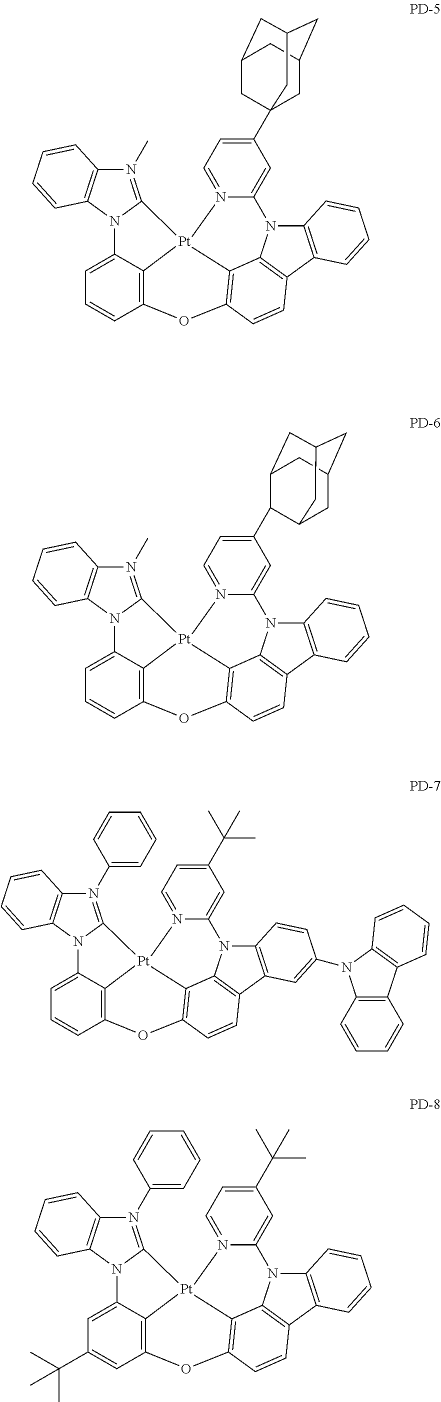

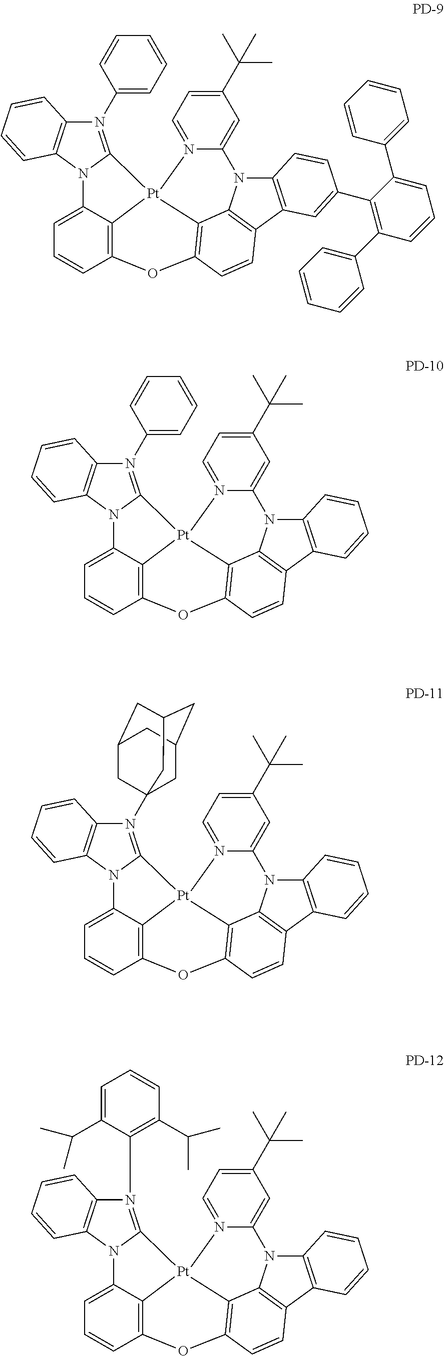

The third compound 246 may have a maximum emission peak in a range of 430 to 490 nm. A singlet energy of the third compound 246 may be smaller than that of each of the first and second compounds 242 and 244, and a triplet energy of the third compound 246 may be smaller than that of each of the first and second compounds 242 and 244.

The EML 240 only includes the first compound 242, the second compound 244 and the third compound 246. Namely, in the EML 240, a summation of a weight % of the first compound 242, a weight % of the second compound 244 and a weight % of the third compound 246 is 100%.

In the EML 240, a weight % of each of the first and second compounds 242 and 244 is greater than that of the third compound 246. A weight % of the first compound 242 and a weight % of the second compound 244 may be same or different. For example, in the EML 240, the third compound 246 may have a weight % in a range of 8 to 20, preferably 12 to 20.

A difference “ΔE_{ST}” between a singlet energy “Si” of the first compound 242 and a triplet energy “Ti” of the first compound 242 is 0.3 eV or less. (ΔE_{ST}<0.3) Namely, the first compound 242 as an n-type host has a delayed fluorescence (or thermally activated delayed fluorescence) property.

In addition, a lowest unoccupied molecular orbital (LUMO) energy level “LUMO(EH)” of the first compound 242 is lower than a LUMO energy level “LUMO(HH)” of the second compound 244 and is equal to or higher than a LUMO “LUMO(PD)” of the third compound 246. Preferably, the LUMO energy level of the first compound 242 may be higher than that of the third compound 246. For example, a LUMO energy level of the second compound 244 may be in a range of −2.6 to −2.5 eV, and a LUMO energy level of the third compound 246 may be lower than −2.6 eV.

A triplet energy of each of the first and second compounds 242 and 244 may be 2.7 eV or more.

In the red pixel region, the organic light emitting layer 220 includes a red EML. The red EML includes a red host and a red dopant. In the green pixel region, the organic light emitting layer 220 includes a green EML. The green EML includes a green host and a green dopant. Each of the red and green dopants may be one of a fluorescent compound, a phosphorescent compound and a delayed fluorescent compound.

As described above, in the blue pixel region, the EML 240 of the OLED D1 includes the first compound 242 represented by Formula 1, the second compound 244 represented by Formula 3 and the third compound 246 represented by Formula 5. As a result, in the OLED D1 and the organic light emitting display device 100 including the OLED D1, the driving voltage is reduced, and the emitting efficiency, the color purity and the lifespan are improved.

### [OLED]

An anode (ITO, 50 nm), an HIL (Formula 7-1, 7 nm), an HTL (Formula 7-2, 45 nm), an EBL (Formula 7-3, 10 nm), an EML (30 nm), an HBL (Formula 7-4, 10 nm), an ETL (Formula 7-5, 30 nm), an EIL (LiF, 0.1 nm) and a cathode (Al, 80 nm) are sequentially deposited to form an OLED.

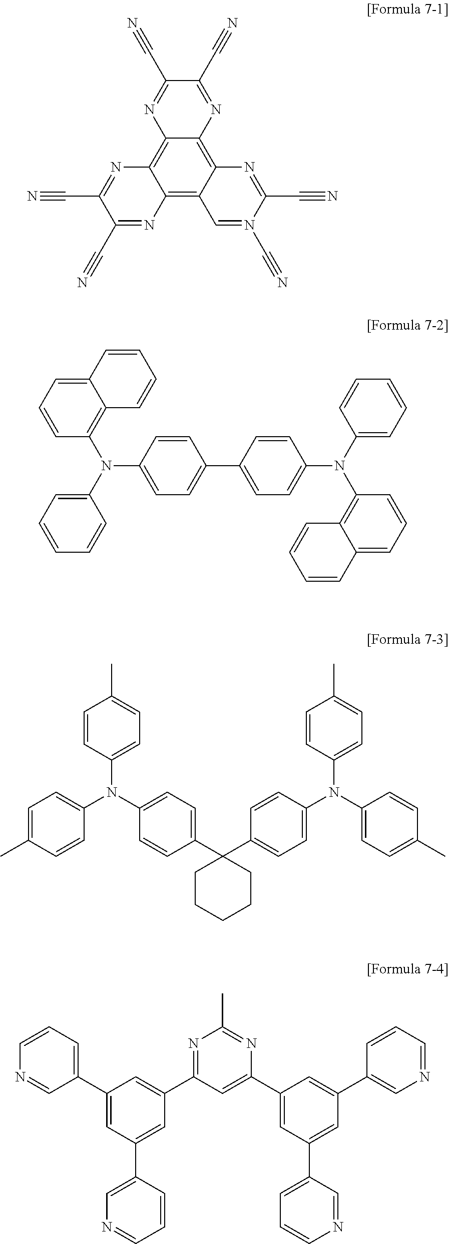

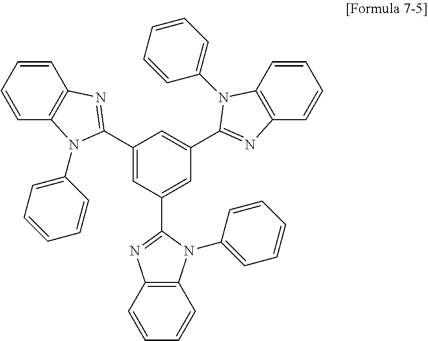 [SMILES: c1ccc(-n2c(-c3cc(-c4nc5ccccc5n4-c4ccccc4)cc(-c4nc5ccccc5n4-c4ccccc4)c3)nc3ccccc32)cc1]

### 1. COMPARATIVE EXAMPLES

### (1) Comparative Example 1 (Ref1)

The compound HH-1 (44 wt %) in Formula 4, the compound Ref EH1 (44 wt %) in Formula 8-1, the compound PD-1 (12 wt %) in Formula 6 were used to form the EML.

### (2) Comparative Example 2 (Ref2)

The compound HH-1 (42 wt %) in Formula 4, the compound Ref EH1 (42 wt %) in Formula 8-1, the compound PD-1 (16 wt %) in Formula 6 were used to form the EML.

### (3) Comparative Example 3 (Ref3)

The compound HH-1 (44 wt %) in Formula 4, the compound Ref EH2 (44 wt %) in Formula 8-2, the compound PD-1 (12 wt %) in Formula 6 were used to form the EML.

### (4) Comparative Example 4 (Ref4)

The compound HH-1 (42 wt %) in Formula 4, the compound Ref EH2 (42 wt %) in Formula 8-2, the compound PD-1 (16 wt %) in Formula 6 were used to form the EML.

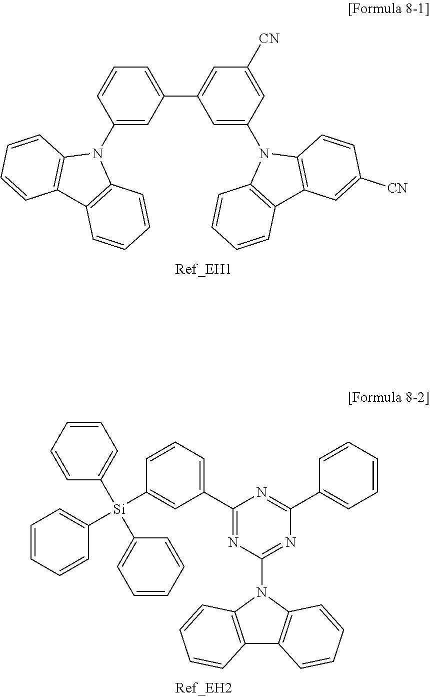 [SMILES: N#Cc1cc(-c2cccc(-n3c4ccccc4c4ccccc43)c2)cc(-n2c3ccccc3c3cc(C#N)ccc32)c1 ; c1ccc(-c2nc(-c3cccc([Si](c4ccccc4)(c4ccccc4)c4ccccc4)c3)nc(-n3c4ccccc4c4ccccc43)n2)cc1]

### 2. EXAMPLES

### (1) Example 1 (Ex1)

The compound HH-1 (46 wt %) in Formula 4, the compound EH-1 (46 wt %) in Formula 2, the compound PD-1 (8 wt %) in Formula 6 were used to form the EML.

### (2) Example 2 (Ex2)

The compound HH-1 (44 wt %) in Formula 4, the compound EH-1 (44 wt %) in Formula 2, the compound PD-1 (12 wt %) in Formula 6 were used to form the EML.

### (3) Example 3 (Ex3)

The compound HH-1 (42 wt %) in Formula 4, the compound EH-1 (42 wt %) in Formula 2, the compound PD-1 (16 wt %) in Formula 6 were used to form the EML.

### (4) Example 4 (Ex4)

The compound HH-1 (40 wt %) in Formula 4, the compound EH-1 (40 wt %) in Formula 2, the compound PD-1 (20 wt %) in Formula 6 were used to form the EML.

### (5) Example 5 (Ex5)

The compound HH-1 (46 wt %) in Formula 4, the compound EH-2 (46 wt %) in Formula 2, the compound PD-1 (8 wt %) in Formula 6 were used to form the EML.

### (6) Example 6 (Ex6)

The compound HH-1 (44 wt %) in Formula 4, the compound EH-2 (44 wt %) in Formula 2, the compound PD-1 (12 wt %) in Formula 6 were used to form the EML.

### (7) Example 7 (Ex7)

The compound HH-1 (42 wt %) in Formula 4, the compound EH-2 (42 wt %) in Formula 2, the compound PD-1 (16 wt %) in Formula 6 were used to form the EML.

### (8) Example 8 (Ex8)

The compound HH-1 (40 wt %) in Formula 4, the compound EH-2 (40 wt %) in Formula 2, the compound PD-1 (20 wt %) in Formula 6 were used to form the EML.

The emitting properties, i.e., a driving voltage (V), an external quantum efficiency (EQE), a color coordinate index (CIEy) and a lifespan (T95), of the OLED in Comparative Examples 1 to 4 and Examples 1 to 8 are measured at 8.6 mA/cm2 and listed in Table 1. In Table 1, a difference (ΔE_{ST}) between a singlet energy and a triplet energy and a LUMO energy level are a value of the n-type host compound.

TABLE 1

| | | ΔE_{ST} | LUMO | | | | | |
|---|---|---|---|---|---|---|---|---|
| | n-host | (eV) | (eV) | PD % | V | EQE (%) | CIEy | T95 |
| Ref1 | Ref_EH1 | 0.45 | −3.01 | 12% | 4.0 | 12.5 | 0.201 | 100 |
| Ref2 | | | | 16% | 4.1 | 10.6 | 0.286 | 60 |
| Ref3 | Ref_EH2 | 0.35 | −2.69 | 12% | 3.8 | 14.5 | 0.188 | 84 |
| Ref4 | | | | 16% | 4.1 | 12.2 | 0.256 | 40 |
| Ex1 | EH-1 | 0.17 | −2.56 | 8% | 3.9 | 19.3 | 0.156 | 130 |
| Ex2 | | | | 12% | 3.8 | 19.4 | 0.159 | 145 |
| Ex3 | | | | 16% | 3.7 | 18.4 | 0.159 | 146 |
| Ex4 | | | | 20% | 3.8 | 18.6 | 0.159 | 163 |
| Ex5 | EH-2 | 0.19 | −2.45 | 8% | 3.7 | 17.1 | 0.139 | 120 |
| Ex6 | | | | 12% | 3.6 | 17.1 | 0.143 | 137 |
| Ex7 | | | | 16% | 3.5 | 15.7 | 0.144 | 138 |
| Ex8 | | | | 20% | 3.5 | 15.8 | 0.145 | 143 |

As shown in Table 1, in comparison to the OLED of Comparative Examples 1 to 4, in which the EML includes the compound Ref_EH1 or the compound Ref_EH2, in the OLED of Examples 1 to 8, in which the EML includes the first compound, i.e., an n-type host, of Formula 1 with the second compound, i.e., a p-type host, of Formula 3 and the third compound, i.e., an emission dopant, of Formula 5, the driving voltage is reduced, and the emitting efficiency, the color purity and the lifespan are improved.

In Particular, in the OLED of Examples 1 to 8, in which the EML includes the first compound, i.e., an n-type host, of Formula 1 with the second compound, i.e., a p-type host, of Formula 3 and the third compound, i.e., an emission dopant, of Formula 5, even if a weight % of the emission dopant is increased to improve brightness, the lifespan is not decreased. Accordingly, in the OLED of the present disclosure, the lifespan is increased with improved brightness.

Referring to FIG. 4, which is a view illustrating a relation between compounds in an EML of an OLED of Comparative Example, a LUMO energy level “LUMO(EH)” of the n-type host, i.e., the compound Ref_EH1 of Formula 8-1 and the compound Ref_EH2 of Formula 8-1, is lower than a LUMO energy level “LUMO(PD)” of the phosphorescent dopant. In this case, an electron is trapped into the n-type host, and a hole is trapped into the phosphorescent dopant. As a result, an exciton having a relatively small (narrow) bandgap is generated between the n-type host and the phosphorescent dopant so that the exciton may be non-radiatively quenched or a long wavelength light may be emitted. In addition, a non-emissive quenching problem of the exciton in the first and second compounds 242 and 244 by a triplet-triplet annihilation (TTA) or a triplet-polaron annihilation (TPA) between the n-type host and the p-type host may be generated so that the emitting efficiency may be decreased. Moreover, when a weight % of the phosphorescent dopant is increased to enhance the emitting efficiency, the above problems are intensified so that the lifespan is significantly decreased.

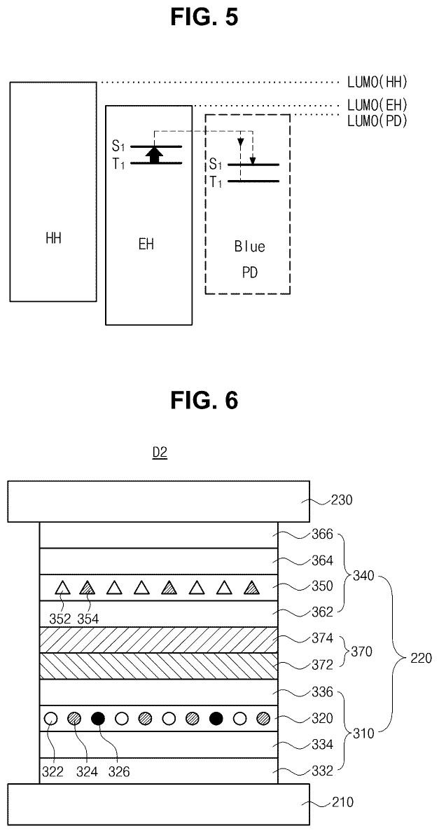

However, referring to FIG. 5, which is a view illustrating a relation between compounds in an EML of an OLED according to the second embodiment of the present disclosure, since a LUMO energy level “LUMO(EH)” of the n-type host is higher than a LUMO energy level “LUMO(PD)” of the phosphorescent dopant, the above problems can be prevented. In particular, even if a weight % of the emission dopant is increased to improve brightness, the lifespan is not decreased.

FIG. 6 is a schematic cross-sectional view of an OLED according to a third embodiment of the present disclosure.

As illustrated in FIG. 6, the OLED D2 includes first and second electrodes 210 and 230 facing each other and an organic light emitting layer 220 therebetween. The organic light emitting layer 220 includes a first emitting part 310 including a first blue EML 320 and a second emitting part 340 including a second EML 350. The organic light emitting layer 220 may include a CGL 370 between the first and second emitting parts 310 and 340. The OLED D2 may further include a capping layer on the second electrode 230 to enhance a light extraction efficiency.

The organic light emitting display device 100 may include a red pixel region, a green pixel region and a blue pixel region, and the OLED D2 may be positioned in the blue pixel region.

The first electrode 210 may be an anode, and the second electrode 230 may be a cathode. One of the first and second electrodes 210 and 230 may be a reflective electrode, and the other one of the first and second electrodes 210 and 230 may be a transparent (or a semitransparent) electrode. For example, the first electrode 210 may have a single-layered structure of ITO, and the second electrode 230 may be formed of Al.

The first emitting part 310 may further include at least one of a first HTL 334 under the first blue EML 320 and a first ETL 336 over the first blue EML 320.

In addition, the first emitting part 310 may further include an HIL 332 between the first electrode 210 and the first HTL 334.

Moreover, the first emitting part 310 may further include at least one of a first EBL between the first HTL 334 and the first blue EML 320 and a first HBL between the first blue EML 320 and the first ETL 336.

The second emitting part 340 may further include at least one of a second HTL 362 under the second blue EML 350 and a second ETL 364 over the second blue EML 350.

In addition, the second emitting part 340 may further include an EIL 366 between the second electrode 230 and the second ETL 364.

Moreover, the second emitting part 340 may further include at least one of a second EBL between the second HTL 362 and the second EML 350 and a second HBL between the second EML 350 and the second ETL 364.

For example, the HIL 332 may include at least one compound selected from the group consisting of MTDATA, NATA, 1T-NATA, 2T-NATA, CuPc, TCTA, NPB (or NPD), HAT-CN, TDAPB, PEDOT/PSS and N-(biphenyl-4-yl)-9,9-dimethyl-N-(4-(9-phenyl-9H-carbazol-3-yl)phenyl)-9H-fluoren-2-amine.

Each of the first and second HTLs 334 and 362 may include at least one compound selected from the group consisting of TPD, NPB (or NPD), CBP, Poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine and N-(biphenyl-4-yl)-N-(4-(9-phenyl-9H-carbazol-3-yl)phenyl)biphenyl-4-amine.

Each of the first and second ETLs 336 and 364 may include at least one of an oxadiazole-based compound, a triazole-based compound, a phenanthroline-based compound, a benzoxazole-based compound, a benzothiazole-based compound, a benzimidazole-based compound, and a triazine-based compound. For example, each of the first and second ETLs 336 and 364 may include at least one compound selected from the group consisting of Alq₃, PBD, spiro-PBD, Liq, TPBi, BAlq, Bphen, NBphen, BCP, TAZ, NTAZ, TpPyPB, TmPPPyTz, PFNBr, TPQ and TSPO1.

The EIL 366 may include at least one of an alkali halide compound, such as LiF, CsF, NaF, or BaF₂, and an organo-metallic compound, such as Liq, lithium benzoate, or sodium stearate.

Each of the first and second EBLs may include at least one compound selected from the group consisting of TCTA, tris[4-(diethylamino)phenyl]amine, N-(biphenyl-4-yl)-9,9-dimethyl-N-(4-(9-phenyl-9H-carbazol-3-yl)phenyl)-9H-fluoren-2-amine, TAPC, MTDATA, mCP, mCBP, CuPc, DNTPD, TDAPB, DCDPA and 2,8-bis(9-phenyl-9H-carbazol-3-yl)dibenzo[b,d]thiophene.

Each of the first and second HBLs may include at least one compound selected from the group consisting of BCP, BAlq, Alq3, PBD, spiro-PBD, Liq, B3PYMPM, DPEPO, 9-(6-9H-carbazol-9-yl)pyridine-3-yl)-9H-3,9′-bicarbazole and TSPO1.

The CGL 370 is positioned between the first and second emitting parts 310 and 340. Namely, the first and second emitting parts 310 and 340 is connected to each other through the CGL 370. The CGL 370 may be a PN-junction CGL of an N-type CGL 372 and a P-type CGL 374.

The N-type CGL 372 is positioned between the first ETL 336 and the second HTL 362, and the P-type CGL 374 is positioned between the N-type CGL 372 and the second HTL 362.

The N-type CGL 372 provides an electron into the first blue EML 320 of the first emitting part 310, and the P-type CGL 374 provides a hole into the second blue EML 350 of the second emitting part 340.

The N-type CGL 372 may be an organic layer doped with an alkali metal, e.g., Li, Na, K and Cs, and/or an alkali earth metal, e.g., Mg, Sr, Ba and Ra. For example, the N-type CGL 372 may be formed of an N-type charge generation material including a host being the organic material, e.g., 4,7-diphenyl-1,10-phenanthroline (Bphen) and MTDATA, a dopant being an alkali metal and/or an alkali earth metal, and the dopant may be doped with a weight % of 0.01 to 30.

The P-type CGL 374 may be formed of a P-type charge generation material including an inorganic material, e.g., tungsten oxide (WOₓ), molybdenum oxide (MoOₓ), beryllium oxide (Be₂O₃) or vanadium oxide (V₂O₅), an organic material, e.g., NPD, HAT-CN, F4TCNQ, TPD, TNB, TCTA, N,N′-dioctyl-3,4,9,10-perylenedicarboximide (PTCDI-C8) or their combination.

The first blue EML 320 includes a first compound 322, e.g., a first host, being an n-type host, a second compound 324, e.g., a second host, being a p-type host and a third compound 326 being a phosphorescent dopant. The first blue EML 320 may have a thickness in a range of 10 to 100 nm.

The first blue EML 320 only includes the first compound 322, the second compound 324 and the third compound 326. Namely, in the first blue EML 320, a summation of a weight % of the first compound 322, a weight % of the second compound 324 and a weight % of the third compound 326 is 100%.

In the first blue EML 320, a weight % of each of the first and second compounds 322 and 324 is greater than that of the third compound 326. A weight % of the first compound 322 and a weight % of the second compound 324 may be same or different. For example, in the first blue EML 320, the third compound 326 may have a weight % in a range of 8 to 20, preferably 12 to 20.

The first compound 322 is represented by Formula 1 and may be one of the compounds in Formula 2. The second compound 324 is represented by Formula 3 and may be one of the compounds in Formula 4. The third compound 326 is represented by Formula 5 and may be one of the compounds in Formula 6.

The second blue EML 350 includes a fourth compound 352 being a host and a fifth compound 354 being a blue dopant. The fifth compound 354 may be a blue fluorescent dopant. The second blue EML 350 may have a thickness in a range of 10 to 100 nm.

For example, the fourth compound 352 may be selected from the group consisting of mCP, 9-(3-(9H-carbazol-9-yl)phenyl)-9H-carbazole-3-carbonitrile (mCP-CN), mCBP, CBP-CN, 9-(3-(9H-Carbazol-9-yl)phenyl)-3-(diphenylphosphoryl)-9H-carbazole (mCPPO1), 3,5-Di(9H-carbazol-9-yl)biphenyl (Ph-mCP), TSPO1, 9-(3′-(9H-carbazol-9-yl)-[1,1′-biphenyl]-3-yl)-9H-pyrido[2,3-b]indole (CzBPCb), bis(2-methylphenyl)diphenylsilane (UGH-1), 1,4-bis(triphenylsilyl)benzene (UGH-2), 1,3-bis(triphenylsilyl)benzene (UGH-3), 9,9-spiorobifluoren-2-yl-diphenyl-phosphine oxide (SPPO1), and 9,9′-(5-(triphenylsilyl)-1,3-phenylene)bis(9H-carbazole) (SimCP).

For example, the fifth compound 354 may be selected from the group consisting of perylene, 4,4′-bis[4-(di-p-tolylamino)styryl]biphenyl (DPAVBi), 4-(di-p-tolylamino)-4-4′-[(di-p-tolylamino)styryl]stilbene (DPAVB), 4,4′-bis[4-(diphenylamino)styryl]biphenyl (BDAVBi), 2,7-bis(4-diphenylamino)styryl)-9,9-spirofluorene (spiro-DPVBi), [1,4-bis[2-[4-[N,N-di(p-tolyl)amino]phenyl]vinyl] benzene (DSB), 1-4-di-[4-(N,N-diphenyl)amino]styryl-benzene (DSA), 2,5,8,11-tetra-tetr-butylperylene (TBPe), bis((2-hydroxylphenyl)-pyridine)beryllium (Bepp2) and 9-(9-Phenylcarbazole-3-yl)-10-(naphthalene-1-yl)anthracene (PCAN).

For example, the second blue EML 350 may include an anthracene derivative as a host and a boron derivative as a blue host.

In the blue pixel region, the organic light emitting layer 220 of the OLED D2 includes the first blue EML 320 and the second blue EML 350 to have a tandem structure.

In this case, the first blue EML 320 includes the first compound 322 represented by Formula 1, the second compound 324 represented by Formula 3 and the third compound 326 represented by Formula 5. As a result, in the OLED D2 and the organic light emitting display device 100 including the OLED D2, the driving voltage is reduced, and the emitting efficiency, the color purity and the lifespan are improved.

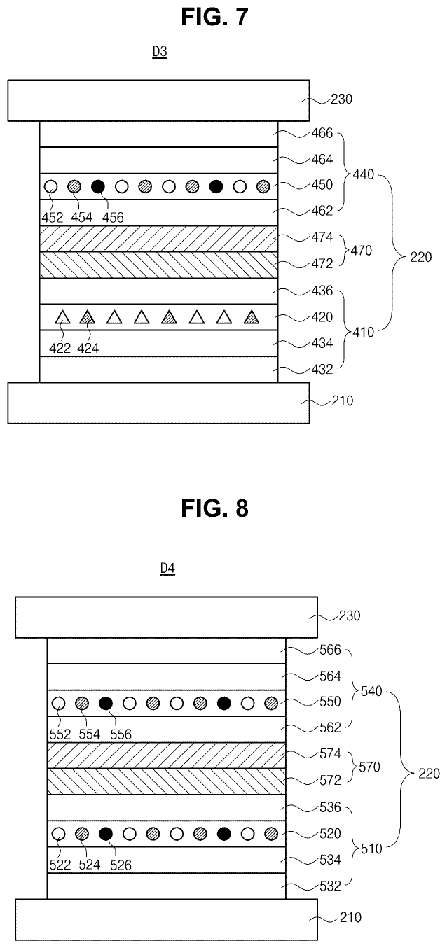

FIG. 7 is a schematic cross-sectional view of an OLED according to a fourth embodiment of the present disclosure.

As illustrated in FIG. 7, the OLED D3 includes first and second electrodes 210 and 230 facing each other and an organic light emitting layer 220 therebetween. The organic light emitting layer 220 includes a first emitting part 410 including a first blue EML 420 and a second emitting part 440 including a second EML 450. The organic light emitting layer 220 may include a CGL 470 between the first and second emitting parts 410 and 440. The OLED D3 may further include a capping layer on the second electrode 230 to enhance a light extraction efficiency.

The organic light emitting display device 100 may include a red pixel region, a green pixel region and a blue pixel region, and the OLED D3 may be positioned in the blue pixel region.

The first electrode 210 may be an anode, and the second electrode 230 may be a cathode. One of the first and second electrodes 210 and 230 may be a reflective electrode, and the other one of the first and second electrodes 210 and 230 may be a transparent (or a semitransparent) electrode. For example, the first electrode 210 may have a single-layered structure of ITO, and the second electrode 230 may be formed of Al.

The first emitting part 410 may further include at least one of a first HTL 434 under the first blue EML 420 and a first ETL 436 over the first blue EML 420.

In addition, the first emitting part 410 may further include an HIL 432 between the first electrode 210 and the first HTL 434.

Moreover, the first emitting part 410 may further include at least one of a first EBL between the first HTL 434 and the first blue EML 420 and a first HBL between the first blue EML 420 and the first ETL 436.

The second emitting part 440 may further include at least one of a second HTL 462 under the second blue EML 450 and a second ETL 464 over the second blue EML 450.

In addition, the second emitting part 440 may further include an EIL 466 between the second electrode 230 and the second ETL 464.

Moreover, the second emitting part 440 may further include at least one of a second EBL between the second HTL 462 and the second EML 450 and a second HBL between the second EML 450 and the second ETL 464.

For example, the HIL 432 may include at least one compound selected from the group consisting of MTDATA, NATA, 1T-NATA, 2T-NATA, CuPc, TCTA, NPB (or NPD), HAT-CN, TDAPB, PEDOT/PSS and N-(biphenyl-4-yl)-9,9-dimethyl-N-(4-(9-phenyl-9H-carbazol-3-yl)phenyl)-9H-fluoren-2-amine.

Each of the first and second HTLs 434 and 462 may include at least one compound selected from the group consisting of TPD, NPB (or NPD), CBP, Poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine and N-(biphenyl-4-yl)-N-(4-(9-phenyl-9H-carbazol-3-yl)phenyl)biphenyl-4-amine.

Each of the first and second ETLs 436 and 464 may include at least one of an oxadiazole-based compound, a triazole-based compound, a phenanthroline-based compound, a benzoxazole-based compound, a benzothiazole-based compound, a benzimidazole-based compound, and a triazine-based compound. For example, each of the first and second ETLs 436 and 464 may include at least one compound selected from the group consisting of Alq₃, PBD, spiro-PBD, Liq, TPBi, BAlq, Bphen, NBphen, BCP, TAZ, NTAZ, TpPyPB, TmPPPyTz, PFNBr, TPQ and TSPO1.

The EIL 466 may include at least one of an alkali halide compound, such as LiF, CsF, NaF, or BaF₂, and an organo-metallic compound, such as Liq, lithium benzoate, or sodium stearate.

Each of the first and second EBLs may include at least one compound selected from the group consisting of TCTA, tris[4-(diethylamino)phenyl]amine, N-(biphenyl-4-yl)-9,9-dimethyl-N-(4-(9-phenyl-9H-carbazol-3-yl)phenyl)-9H-fluoren-2-amine, TAPC, MTDATA, mCP, mCBP, CuPc, DNTPD, TDAPB, DCDPA and 2,8-bis(9-phenyl-9H-carbazol-3-yl)dibenzo[b,d]thiophene.

Each of the first and second HBLs may include at least one compound selected from the group consisting of BCP, BAlq, Alq3, PBD, spiro-PBD, Liq, B3PYMPM, DPEPO, 9-(6-9H-carbazol-9-yl)pyridine-3-yl)-9H-3,9′-bicarbazole and TSPO1.

The CGL 470 is positioned between the first and second emitting parts 410 and 440. Namely, the first and second emitting parts 410 and 440 is connected to each other through the CGL 470. The CGL 470 may be a PN-junction CGL of an N-type CGL 472 and a P-type CGL 474.

The N-type CGL 472 is positioned between the first ETL 436 and the second HTL 462, and the P-type CGL 474 is positioned between the N-type CGL 472 and the second HTL 462.

The N-type CGL 472 provides an electron into the first blue EML 420 of the first emitting part 410, and the P-type CGL 474 provides a hole into the second blue EML 450 of the second emitting part 440.

The N-type CGL 472 may be an organic layer doped with an alkali metal, e.g., Li, Na, K and Cs, and/or an alkali earth metal, e.g., Mg, Sr, Ba and Ra. For example, the N-type CGL 472 may be formed of an N-type charge generation material including a host being the organic material, e.g., 4,7-diphenyl-1,10-phenanthroline (Bphen) and MTDATA, a dopant being an alkali metal and/or an alkali earth metal, and the dopant may be doped with a weight % of 0.01 to 30.

The P-type CGL 474 may be formed of a P-type charge generation material including an inorganic material, e.g., tungsten oxide (WOₓ), molybdenum oxide (MoOₓ), beryllium oxide (Be₂O₃) or vanadium oxide (V₂O₅), an organic material, e.g., NPD, HAT-CN, F4TCNQ, TPD, TNB, TCTA, N,N′-dioctyl-3,4,9,10-perylenedicarboximide (PTCDI-C8) or their combination.

The first blue EML 420 includes a fourth compound 422 being a host and a fifth compound 424 being a blue dopant. The fifth compound 424 may be a blue fluorescent dopant. The first blue EML 420 may have a thickness in a range of 10 to 100 nm.

For example, the fourth compound 422 may be selected from the group consisting of mCP, mCP-CN, mCBP, CBP-CN, mCPPO1, Ph-mCP, TSPO1, CzBPCb, UGH-1, UGH-2, UGH-3, SPPO1 and SimCP, and the fifth compound 424 may be selected from the group consisting of DPAVBi, DPAVB, BDAVBi, spiro-DPVBi, DSB, DSA, TBPe, Bepp2 and PCAN.

For example, the first blue EML 420 may include an anthracene derivative as a host and a boron derivative as a blue host.

The second blue EML 450 includes a first compound 452, e.g., a first host, being an n-type host, a second compound 454, e.g., a second host, being a p-type host and a third compound 456 being a phosphorescent dopant. The second blue EML 450 may have a thickness in a range of 10 to 100 nm.

The second blue EML 450 only includes the first compound 452, the second compound 454 and the third compound 456. Namely, in the second blue EML 450, a summation of a weight % of the first compound 452, a weight % of the second compound 454 and a weight % of the third compound 456 is 100%.

In the second blue EML 450, a weight % of each of the first and second compounds 452 and 454 is greater than that of the third compound 456. A weight % of the first compound 452 and a weight % of the second compound 454 may be same or different. For example, in the second blue EML 450, the third compound 456 may have a weight % in a range of 8 to 20, preferably 12 to 20.

The first compound 452 is represented by Formula 1 and may be one of the compounds in Formula 2. The second compound 454 is represented by Formula 3 and may be one of the compounds in Formula 4. The third compound 456 is represented by Formula 5 and may be one of the compounds in Formula 6.

In the blue pixel region, the organic light emitting layer 220 of the OLED D3 includes the first blue EML 420 and the second blue EML 450 to have a tandem structure.

In this case, the second blue EML 450 includes the first compound 452 represented by Formula 1, the second compound 454 represented by Formula 3 and the third compound 456 represented by Formula 5. As a result, in the OLED D3 and the organic light emitting display device 100 including the OLED D3, the driving voltage is reduced, and the emitting efficiency, the color purity and the lifespan are improved.

FIG. 8 is a schematic cross-sectional view of an OLED according to a fifth embodiment of the present disclosure.

As illustrated in FIG. 8, the OLED D4 includes first and second electrodes 210 and 230 facing each other and an organic light emitting layer 220 therebetween. The organic light emitting layer 220 includes a first emitting part 510 including a first blue EML 520 and a second emitting part 540 including a second blue EML 550. The organic light emitting layer 220 may include a CGL 570 between the first and second emitting parts 510 and 540. The OLED D4 may further include a capping layer on the second electrode 230 to enhance a light extraction efficiency.

The organic light emitting display device 100 may include a red pixel region, a green pixel region and a blue pixel region, and the OLED D4 may be positioned in the blue pixel region.

The first electrode 210 may be an anode, and the second electrode 230 may be a cathode. One of the first and second electrodes 210 and 230 may be a reflective electrode, and the other one of the first and second electrodes 210 and 230 may be a transparent (or a semitransparent) electrode. For example, the first electrode 210 may have a single-layered structure of ITO, and the second electrode 230 may be formed of Al.

The first emitting part 510 may further include at least one of a first HTL 534 under the first blue EML 520 and a first ETL 536 over the first blue EML 520.

In addition, the first emitting part 510 may further include an HIL 532 between the first electrode 210 and the first HTL 534.

Moreover, the first emitting part 510 may further include at least one of a first EBL between the first HTL 534 and the first blue EML 520 and a first HBL between the first blue EML 520 and the first ETL 536.

The second emitting part 540 may further include at least one of a second HTL 562 under the second blue EML 550 and a second ETL 564 over the second blue EML 550.

In addition, the second emitting part 540 may further include an EIL 566 between the second electrode 230 and the second ETL 564.

Moreover, the second emitting part 540 may further include at least one of a second EBL between the second HTL 562 and the second blue EML 550 and a second HBL between the second blue EML 550 and the second ETL 564.

For example, the HIL 532 may include at least one compound selected from the group consisting of MTDATA, NATA, 1T-NATA, 2T-NATA, CuPc, TCTA, NPB (or NPD), HAT-CN, TDAPB, PEDOT/PSS and N-(biphenyl-4-yl)-9,9-dimethyl-N-(4-(9-phenyl-9H-carbazol-3-yl)phenyl)-9H-fluoren-2-amine.

Each of the first and second HTLs 534 and 562 may include at least one compound selected from the group consisting of TPD, NPB (or NPD), CBP, Poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine and N-(biphenyl-4-yl)-N-(4-(9-phenyl-9H-carbazol-3-yl)phenyl)biphenyl-4-amine.

Each of the first and second ETLs 536 and 564 may include at least one of an oxadiazole-based compound, a triazole-based compound, a phenanthroline-based compound, a benzoxazole-based compound, a benzothiazole-based compound, a benzimidazole-based compound, and a triazine-based compound. For example, each of the first and second ETLs 536 and 564 may include at least one compound selected from the group consisting of Alq₃, PBD, spiro-PBD, Liq, TPBi, BAlq, Bphen, NBphen, BCP, TAZ, NTAZ, TpPyPB, TmPPPyTz, PFNBr, TPQ and TSPO1.

The EIL 566 may include at least one of an alkali halide compound, such as LiF, CsF, NaF, or BaF₂, and an organo-metallic compound, such as Liq, lithium benzoate, or sodium stearate.

Each of the first and second EBLs may include at least one compound selected from the group consisting of TCTA, tris[4-(diethylamino)phenyl]amine, N-(biphenyl-4-yl)-9,9-dimethyl-N-(4-(9-phenyl-9H-carbazol-3-yl)phenyl)-9H-fluoren-2-amine, TAPC, MTDATA, mCP, mCBP, CuPc, DNTPD, TDAPB, DCDPA and 2,8-bis(9-phenyl-9H-carbazol-3-yl)dibenzo[b,d]thiophene.

Each of the first and second HBLs may include at least one compound selected from the group consisting of BCP, BAlq, Alq3, PBD, spiro-PBD, Liq, B3PYMPM, DPEPO, 9-(6-9H-carbazol-9-yl)pyridine-3-yl)-9H-3,9′-bicarbazole and TSPO1.

The CGL 570 is positioned between the first and second emitting parts 510 and 540. Namely, the first and second emitting parts 510 and 540 is connected to each other through the CGL 570. The CGL 570 may be a PN-junction CGL of an N-type CGL 572 and a P-type CGL 574.

The N-type CGL 572 is positioned between the first ETL 536 and the second HTL 562, and the P-type CGL 574 is positioned between the N-type CGL 572 and the second HTL 562.

The N-type CGL 572 provides an electron into the first blue EML 520 of the first emitting part 510, and the P-type CGL 574 provides a hole into the second blue EML 550 of the second emitting part 540.

The N-type CGL 572 may be an organic layer doped with an alkali metal, e.g., Li, Na, K and Cs, and/or an alkali earth metal, e.g., Mg, Sr, Ba and Ra. For example, the N-type CGL 572 may be formed of an N-type charge generation material including a host being the organic material, e.g., 4,7-diphenyl-1,10-phenanthroline (Bphen) and MTDATA, a dopant being an alkali metal and/or an alkali earth metal, and the dopant may be doped with a weight % of 0.01 to 30.

The P-type CGL 574 may be formed of a P-type charge generation material including an inorganic material, e.g., tungsten oxide (WOₓ), molybdenum oxide (MoOₓ), beryllium oxide (Be₂O₃) or vanadium oxide (V₂O₅), an organic material, e.g., NPD, HAT-CN, F4TCNQ, TPD, TNB, TCTA, N,N′-dioctyl-3,4,9,10-perylenedicarboximide (PTCDI-C8) or their combination.

The first blue EML 520 includes a first compound 522, e.g., a first host, being an n-type host, a second compound 524, e.g., a second host, being a p-type host and a third compound 526 being a phosphorescent dopant. The first blue EML 520 may have a thickness in a range of 10 to 100 nm.

The first blue EML 520 only includes the first compound 522, the second compound 524 and the third compound 526. Namely, in the first blue EML 520, a summation of a weight % of the first compound 522, a weight % of the second compound 524 and a weight % of the third compound 526 is 100%.

In the first blue EML 520, a weight % of each of the first and second compounds 522 and 524 is greater than that of the third compound 526. A weight % of the first compound 522 and a weight % of the second compound 524 may be same or different. For example, in the first blue EML 520, the third compound 526 may have a weight % in a range of 8 to 20, preferably 12 to 20.

The first compound 522 is represented by Formula 1 and may be one of the compounds in Formula 2. The second compound 524 is represented by Formula 3 and may be one of the compounds in Formula 4. The third compound 526 is represented by Formula 5 and may be one of the compounds in Formula 6.

The second blue EML 550 includes a fourth compound 552, e.g., a third host, being an n-type host, a fifth compound 554, e.g., a fourth host, being a p-type host and a sixth compound 556 being a phosphorescent dopant. The second blue EML 550 may have a thickness in a range of 10 to 100 nm.

The second blue EML 550 only includes the fourth compound 552, the fifth compound 554 and the sixth compound 556. Namely, in the second blue EML 550, a summation of a weight % of the fourth compound 552, a weight % of the fifth compound 554 and a weight % of the sixth compound 556 is 100%.

In the second blue EML 550, a weight % of each of the fourth and fifth compounds 552 and 554 is greater than that of the sixth compound 556. A weight % of the fourth compound 552 and a weight % of the fifth compound 554 may be same or different. For example, in the second blue EML 550, the sixth compound 556 may have a weight % in a range of 8 to 20, preferably 12 to 20.

The fourth compound 552 is represented by Formula 1 and may be one of the compounds in Formula 2. The fifth compound 554 is represented by Formula 3 and may be one of the compounds in Formula 4. The sixth compound 556 is represented by Formula 5 and may be one of the compounds in Formula 6.

The first compound 522 in the first blue EML 520 and the fourth compound 552 in the second blue EML 550 may be same or different. The second compound 524 in the first blue EML 520 and the fifth compound 554 in the second blue EML 550 may be same or different. The third compound 526 in the first blue EML 520 and the sixth compound 556 in the second blue EML 550 may be same or different.

In the blue pixel region, the organic light emitting layer 220 of the OLED D4 includes the first blue EML 520 and the second blue EML 550 to have a tandem structure.

In this case, the first blue EML 520 includes the first compound 522 represented by Formula 1, the second compound 524 represented by Formula 3 and the third compound 526 represented by Formula 5, and the second blue EML 550 includes the fourth compound 552 represented by Formula 1, the fifth compound 554 represented by Formula 3 and the sixth compound 556 represented by Formula 5. As a result, in the OLED D4 and the organic light emitting display device 100 including the OLED D4, the driving voltage is reduced, and the emitting efficiency, the color purity and the lifespan are improved.

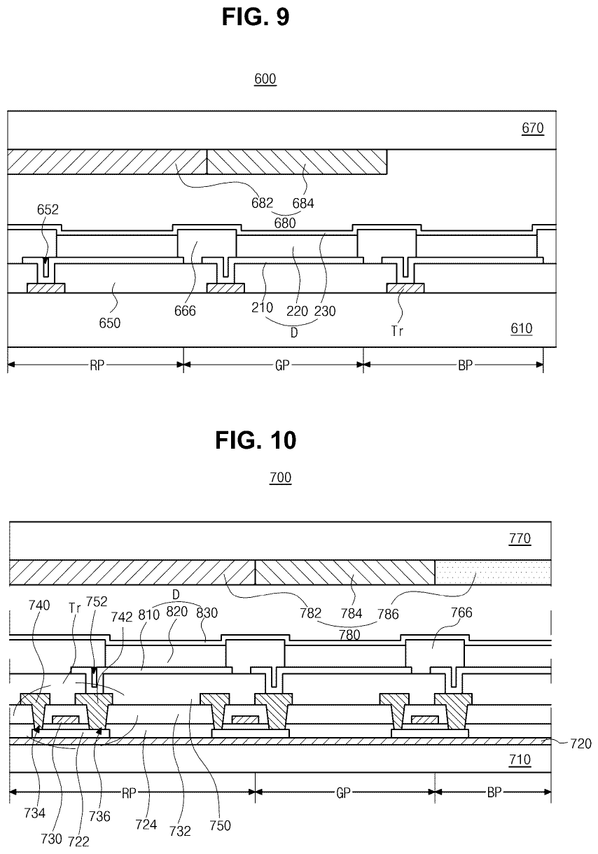

FIG. 9 is a schematic cross-sectional view illustrating an organic light emitting display device according to a sixth embodiment of the present disclosure.

As illustrated in FIG. 9, the organic light emitting display device 600 includes a first substrate 610, where a red pixel region RP, a green pixel region GP and a blue pixel region BP are defined, a second substrate 670 facing the first substrate 610, an OLED D, which is positioned between the first and second substrates 610 and 670 and providing white emission, and a color conversion layer 680 between the OLED D and the second substrate 670.

Although not shown, a color filter may be formed between the second substrate 670 and each color conversion layer 680.

Each of the first and second substrates 610 and 670 may be a glass substrate or a flexible substrate. For example, the flexible substrate may be a polyimide (PI) substrate, a polyethersulfone (PES) substrate, a polyethylenenaphthalate (PEN) substrate, a polyethylene terephthalate (PET) substrate or a polycarbonate (PC) substrate.

A TFT Tr, which corresponding to each of the red, green and blue pixel regions RP, GP and BP, is formed on the first substrate 610, and a planarization layer 650, which has a drain contact hole 652 exposing an electrode, e.g., a drain electrode, of the TFT Tr is formed to cover the TFT Tr.

The OLED D including a first electrode 210, an organic light emitting layer 220 and a second electrode 230 is formed on the planarization layer 650. In this instance, the first electrode 210 may be connected to the drain electrode of the TFT Tr through the drain contact hole 652.

The first electrode 210 may be an anode, and the second electrode 230 may be a cathode. One of the first and second electrodes 210 and 230 may be a reflective electrode, and the other one of the first and second electrodes 210 and 230 may be a transparent (or a semitransparent) electrode. For example, the first electrode 210 may have a single-layered structure of ITO, and the second electrode 230 may be formed of Al.

A bank layer 666 is formed on the planarization layer 650 to cover an edge of the first electrode 210. Namely, the bank layer 666 is positioned at a boundary of the pixel and exposes a center of the first electrode 210 in the pixel. Since the OLED D emits blue light in each of the red, green and blue pixel regions RP, GP and BP, the organic light emitting layer 220 may be integrally formed as a common layer in the red, green and blue pixel regions RP, GP and BP without separation. The bank layer 666 may be formed to prevent a current leakage at an edge of the first electrode 210 and may be omitted.

The OLED D emits a blue light and may have a structure shown in FIGS. 3 and 6 to 8. Namely, the OLED D is formed in each of the red, green and blue pixel regions RP, GP and BP and provides the blue light.

For example, referring to FIG. 3, the organic light emitting layer 220 of the OLED D includes the blue EML 240, and the blue EML 240 include the first compound 242 as an n-type host represented by Formula 1, the second compound 244 as a p-type host represented by Formula 3 and the third compound 246 as a phosphorescent dopant represented by Formula 5.

The color conversion layer 680 includes a first color conversion layer 682 corresponding to the red pixel region RP and a second color conversion layer 684 corresponding to the green pixel region GP. For example, the color conversion layer 680 may include an inorganic color conversion material such as a quantum dot. The color conversion layer is not presented in the blue pixel region BP so that the OLED D in the blue pixel region BP may directly face the second substrate 670.

The blue light from the OLED D is converted into the red light by the first color conversion layer 682 in the red pixel region RP, and the blue light from the OLED D is converted into the green light by the second color conversion layer 684 in the green pixel region GP.

Accordingly, the organic light emitting display device 600 can display a full-color image.

When the light from the OLED D passes through the first substrate 610 to display an image, the color conversion layer 680 may be disposed between the OLED D and the first substrate 610.

FIG. 10 is a schematic cross-sectional view illustrating an organic light emitting display device according to a seventh embodiment of the present disclosure.

As illustrated in FIG. 10, the organic light emitting display device 700 includes a first substrate 710, where a red pixel region RP, a green pixel region GP and a blue pixel region BP are defined, a second substrate 770 facing the first substrate 710, an OLED D, which is positioned between the first and second substrates 710 and 770 and providing white emission, and a color filter layer 780 between the OLED D and the second substrate 770.

Each of the first and second substrates 710 and 770 may be a glass substrate or a flexible substrate. For example, the flexible substrate may be a polyimide (PI) substrate, a polyethersulfone (PES) substrate, a polyethylenenaphthalate (PEN) substrate, a polyethylene terephthalate (PET) substrate or a polycarbonate (PC) substrate.

A buffer layer 720 is formed on the substrate, and the TFT Tr corresponding to each of the red, green and blue pixel regions RP, GP and BP is formed on the buffer layer 720. The buffer layer 720 may be omitted.

A semiconductor layer 722 is formed on the buffer layer 720. The semiconductor layer 722 may include an oxide semiconductor material or polycrystalline silicon.

A gate insulating layer 724 is formed on the semiconductor layer 722. The gate insulating layer 724 may be formed of an inorganic insulating material such as silicon oxide or silicon nitride.

A gate electrode 730, which is formed of a conductive material, e.g., metal, is formed on the gate insulating layer 724 to correspond to a center of the semiconductor layer 722.

An interlayer insulating layer 732, which is formed of an insulating material, is formed on the gate electrode 730. The interlayer insulating layer 732 may be formed of an inorganic insulating material, e.g., silicon oxide or silicon nitride, or an organic insulating material, e.g., benzocyclobutene or photo-acryl.

The interlayer insulating layer 732 includes first and second contact holes 734 and 736 exposing both sides of the semiconductor layer 722. The first and second contact holes 734 and 736 are positioned at both sides of the gate electrode 730 to be spaced apart from the gate electrode 730.

A source electrode 740 and a drain electrode 742, which are formed of a conductive material, e.g., metal, are formed on the interlayer insulating layer 732.

The source electrode 740 and the drain electrode 742 are spaced apart from each other with respect to the gate electrode 730 and respectively contact both sides of the semiconductor layer 722 through the first and second contact holes 734 and 736.

The semiconductor layer 722, the gate electrode 730, the source electrode 740 and the drain electrode 742 constitute the TFT Tr. The TFT Tr serves as a driving element. Namely, the TFT Tr may correspond to the driving TFT Td (of FIG. 1).

Although not shown, the gate line and the data line cross each other to define the pixel, and the switching TFT is formed to be connected to the gate and data lines. The switching TFT is connected to the TFT Tr as the driving element.

In addition, the power line, which may be formed to be parallel to and spaced apart from one of the gate and data lines, and the storage capacitor for maintaining the voltage of the gate electrode of the TFT Tr in one frame may be further formed.

A planarization layer 750, which includes a drain contact hole 752 exposing the drain electrode 742 of the TFT Tr, is formed to cover the TFT Tr.

A first electrode 810, which is connected to the drain electrode 742 of the TFT Tr through the drain contact hole 752, is separately formed in each pixel and on the planarization layer 750. The first electrode 810 may be an anode and may be formed of a conductive material having a relatively high work function. For example, the first electrode 810 may include a transparent conductive oxide layer formed of a transparent conductive oxide (TCO).

For example, the transparent conductive oxide material layer of the first electrode 810 may be formed of one of indium-tin-oxide (ITO), indium-zinc-oxide (IZO), indium-tin-zinc-oxide (ITZO), tin oxide (SnO), zinc oxide (ZnO), indium-copper-oxide (ICO) and aluminum-zinc-oxide (Al:ZnO, AZO).

The first electrode 810 may further include a reflective layer to have a double-layered structure or a triple-layered structure. Namely, the first electrode 810 may be a reflective electrode.

For example, the reflective layer may be formed of one of silver (Ag), an alloy of Ag and one of palladium (Pd), copper (Cu), indium (In) and neodymium (Nd), and aluminum-palladium-copper (APC) alloy. For example, the first electrode 810 may have a double-layered structure of Ag/ITO or APC/ITO or a triple-layered structure of ITO/Ag/ITO or ITO/APC/ITO.

A bank layer 766 is formed on the planarization layer 750 to cover an edge of the first electrode 810. Namely, the bank layer 766 is positioned at a boundary of the pixel and exposes a center of the first electrode 810 in the pixel. Since the OLED D emits blue light in each of the red, green and blue pixel regions RP, GP and BP, the organic light emitting layer 820 may be integrally formed as a common layer in the red, green and blue pixel regions RP, GP and BP without separation. The bank layer 766 may be formed to prevent a current leakage at an edge of the first electrode 810 and may be omitted.

An organic emitting layer 820 is formed on the first electrode 810.

A second electrode 830 is formed over the substrate 710 where the organic emitting layer 820 is formed.

In the organic light emitting display device 700, since the light emitted from the organic emitting layer 820 is incident to the color filter layer 780 through the second electrode 830, the second electrode 830 has a thin profile for transmitting the light.

The first electrode 810, the organic emitting layer 820 and the second electrode 830 constitute the OLED D.

The color filter layer 780 is disposed over the OLED D and includes a red color filter 782, a green color filter 784 and a blue color filter 786 respectively corresponding to the red pixel region RP, the green pixel region GP and the blue pixel region BP. The red color filter 782 includes at least one of a red dye and a red pigment, the green color filter 784 includes at least one of a green dye and a green pigment, and the blue color filter 786 includes at least one of a blue dye and a blue pigment.

The color filter layer 780 may be attached to the OLED D using an adhesive layer. Alternatively, the color filter layer 780 may be formed directly on the OLED D.

An encapsulation layer (or an encapsulation film) may be formed to prevent penetration of moisture into the OLED D. For example, the encapsulation film may include a first inorganic insulating layer, an organic insulating layer and a second inorganic insulating layer sequentially stacked, but it is not limited thereto. The encapsulation film may be omitted.

In the bottom-emission type organic light emitting display device 700, a metal plate may be disposed over the second electrode 830. The metal plate may be attached to the OLED D using an adhesive layer.

A polarization plate for reducing an ambient light reflection may be disposed over an outer side of the second electrode 830 of the top-emission type OLED D. For example, the polarization plate may be a circular polarization plate.

In the OLED D of FIG. 10, the first electrode 810 and the second electrode 830 are a reflective electrode and a transparent (a semitransparent) electrode, respectively, and the color filter layer 780 is disposed over the OLED D.

Alternatively, the first electrode 810 and the second electrode 830 may be a transparent (a semitransparent) electrode and a reflective electrode, respectively, and the color filter layer 780 may be disposed between the OLED D and the first substrate 710. In this case, first electrode 810 may have a single-layered structure of the transparent conductive oxide layer.

A color conversion layer may be formed between the OLED D and the color filter layer 780. The color conversion layer may include a red color conversion layer, a green color conversion layer and a blue color conversion layer respectively corresponding to the red, green and blue pixel regions RP, GP and BP. The white light from the OLED D is converted into the red light, the green light and the blue light by the red, green and blue color conversion layer, respectively.

The color conversion layer may be included instead of the color filter layer 780.

As described above, in the organic light emitting display device 700, the OLED D in the red, green and blue pixel regions RP, GP and BP emits the white light, and the white light from the OLED D passes through the red color filter 782, the green color filter 784 and the blue color filter 786. As a result, the red light, the green light and the blue light are provided from the red pixel region RP, the green pixel region GP and the blue pixel region BP, respectively.

In FIG. 10, the OLED D emitting the white light is used for a display device. Alternatively, the OLED D may be formed on an entire surface of a substrate without at least one of the driving element and the color filter layer to be used for a lightening device. The display device and the lightening device each including the OLED D of the present disclosure may be referred to as an organic light emitting device.

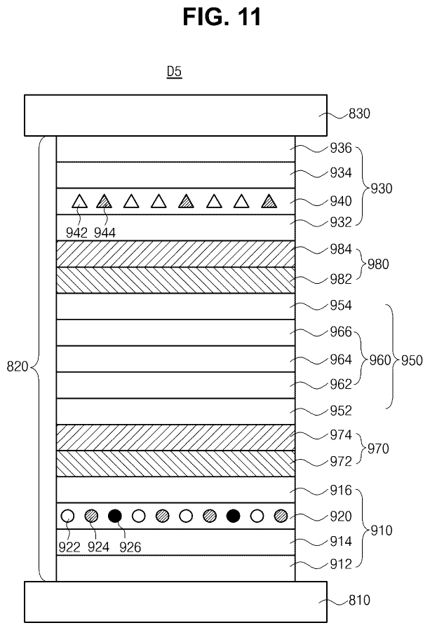

FIG. 11 is a schematic cross-sectional view of an OLED according to an eighth embodiment of the present disclosure.

As illustrated in FIG. 11, the OLED D5 includes first and second electrodes 810 and 830, which face each other and an organic light emitting layer 820 therebetween. The organic light emitting layer 820 includes a first emitting part 910 including a first EML 920, e.g., a first blue EML, a second emitting part 930 including a second EML 940, e.g., a second blue EML, and a third emitting part 950 including a third EML 960. The organic light emitting layer 820 may further includes a first CGL 970 between the first and third emitting parts 910 and 950 and a second CGL 980 between the second and third emitting parts 930 and 950. The OLED D5 may further include a capping layer on the second electrode 830 to enhance a light extraction efficiency.

The organic light emitting display device 700 may include a red pixel region, a green pixel region and a blue pixel region, and the OLED D5 may be positioned in the red, green and blue pixel regions RP, GP and BP and emits blue light.

The first electrode 810 may be an anode, and the second electrode 830 may be a cathode. One of the first and second electrodes 810 and 830 may be a reflective electrode, and the other one of the first and second electrodes 810 and 830 may be a transparent (or a semitransparent) electrode. For example, the first electrode 810 may have a single-layered structure of ITO, and the second electrode 830 may be formed of Al.

The first emitting part 910 may further include at least one of a first HTL 914 under the first blue EML 920 and a first ETL 916 over the first blue EML 920.

In addition, the first emitting part 910 may further include an HIL 912 between the first electrode 810 and the first HTL 914.

Moreover, the first emitting part 910 may further include at least one of a first EBL between the first HTL 914 and the first blue EML 920 and a first HBL between the first blue EML 920 and the first ETL 916.

The second emitting part 930 may further include at least one of a second HTL 932 under the second blue EML 940 and a second ETL 934 over the second blue EML 940.

In addition, the second emitting part 930 may further include an EIL 936 between the second electrode 830 and the second ETL 934.

Moreover, the second emitting part 930 may further include at least one of a second EBL between the second HTL 932 and the second EML 940 and a second HBL between the second EML 940 and the second ETL 934.

In the third emitting part 950, the third EML 960 may include a red EML 962, a yellow-green EML 964 and a green EML 966. In this case, the yellow-green EML 964 is disposed between the red and green EMLs 962 and 966. Alternatively, the yellow-green EML 964 may be omitted, and the third EML 960 may have a double-layered structure including the red and green EMLs 962 and 966.

The red EML 962 includes a red host and a red dopant, the green EML 966 includes a green host and a green dopant, and the yellow-green EML 964 includes a yellow-green host and a yellow-green dopant. Each of the red dopant, the green dopant and the yellow-green dopant may be one of a fluorescent compound, a phosphorescent compound and a delayed fluorescent compound.

For example, in the green EML 966, the green host may be CBP (4,4′-bis(carbazol-9-yl)biphenyl), and the green dopant may be Ir(ppy)₃ (fac tris(2-phenylpyridine)iridium) or Alq3 (tris(8-hydroxyquinolino)aluminum).

The third emitting part 950 may include at least one of a third HTL 952 under the third EML 960 and a third ETL 954 over the third EML 960.

In addition, the third emitting part 950 may further include at least one of a third EBL between the third HTL 952 and the third EML 960 and a third HBL between the third EML 960 and the third ETL 954.

For example, the HIL 912 may include at least one compound selected from the group consisting of MTDATA, NATA, 1T-NATA, 2T-NATA, CuPc, TCTA, NPB (or NPD), HAT-CN, TDAPB, PEDOT/PSS and N-(biphenyl-4-yl)-9,9-dimethyl-N-(4-(9-phenyl-9H-carbazol-3-yl)phenyl)-9H-fluoren-2-amine.

Each of the first to third HTLs 914, 932 and 952 may include at least one compound selected from the group consisting of TPD, NPB (or NPD), CBP, Poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine and N-(biphenyl-4-yl)-N-(4-(9-phenyl-9H-carbazol-3-yl)phenyl)biphenyl-4-amine.

Each of the first to third ETLs 916, 934 and 954 may include at least one of an oxadiazole-based compound, a triazole-based compound, a phenanthroline-based compound, a benzoxazole-based compound, a benzothiazole-based compound, a benzimidazole-based compound, and a triazine-based compound. For example, each of the first to third ETLs 916, 934 and 954 may include at least one compound selected from the group consisting of Alq3, PBD, spiro-PBD, Liq, TPBi, BAlq, Bphen, NBphen, BCP, TAZ, NTAZ, TpPyPB, TmPPPyTz, PFNBr, TPQ and TSPO1.

The EIL 936 may include at least one of an alkali halide compound, such as LiF, CsF, NaF, or BaF₂, and an organo-metallic compound, such as Liq, lithium benzoate, or sodium stearate.

Each of the first to third EBLs may include at least one compound selected from the group consisting of TCTA, tris[4-(diethylamino)phenyl]amine, N-(biphenyl-4-yl)-9,9-dimethyl-N-(4-(9-phenyl-9H-carbazol-3-yl)phenyl)-9H-fluoren-2-amine, TAPC, MTDATA, mCP, mCBP, CuPc, DNTPD, TDAPB, DCDPA and 2,8-bis(9-phenyl-9H-carbazol-3-yl)dibenzo[b,d]thiophene.

Each of the first to third HBLs may include at least one compound selected from the group consisting of BCP, BAlq, Alq3, PBD, spiro-PBD, Liq, B3PYMPM, DPEPO, 9-(6-9H-carbazol-9-yl)pyridine-3-yl)-9H-3,9′-bicarbazole and TSPO1.

The first CGL 970 is positioned between the first and third emitting parts 910 and 950, and the second CGL 980 is positioned between the second and third emitting parts 930 and 950. Namely, the first and third emitting parts 910 and 950 may be connected to each other through the first CGL 970, and the second and third emitting parts 930 and 950 may be connected to each other through the second CGL 980. The first CGL 970 may be a P-N junction CGL of a first N-type CGL 972 and a first P-type CGL 974, and the second CGL 980 may be a P-N junction CGL of a second N-type CGL 982 and a second P-type CGL 984.

In the first CGL 970, the first N-type CGL 972 is positioned between the first ETL 916 and the third HTL 952, and the first P-type CGL 974 is positioned between the first N-type CGL 972 and the third HTL 952.

In the second CGL 980, the second N-type CGL 982 is positioned between the third ETL 954 and the second HTL 932, and the second P-type CGL 984 is positioned between the second N-type CGL 982 and the second HTL 932.

Each of the first and second N-type CGLs 972 and 982 may be an organic layer doped with an alkali metal, e.g., Li, Na, K and Cs, and/or an alkali earth metal, e.g., Mg, Sr, Ba and Ra. For example, each of the first and second N-type CGLs 972 and 982 may be formed of an N-type charge generation material including a host being the organic material, e.g., 4,7-diphenyl-1,10-phenanthroline (Bphen) and MTDATA, a dopant being an alkali metal and/or an alkali earth metal, and the dopant may be doped with a weight % of 0.01 to 30.

Each of the first and second P-type CGLs 974 and 984 may be formed of a P-type charge generation material including an inorganic material, e.g., tungsten oxide (WOₓ), molybdenum oxide (MoOₓ), beryllium oxide (Be₂O₃) or vanadium oxide (V₂O₅), an organic material, e.g., NPD, HAT-CN, F4TCNQ, TPD, TNB, TCTA, N,N′-dioctyl-3,4,9,10-perylenedicarboximide (PTCDI-C8) or their combination.

The first blue EML 920 includes a first compound 922, e.g., a first host, being an n-type host, a second compound 924, e.g., a second host, being a p-type host and a third compound 926 being a phosphorescent dopant. The first blue EML 920 may have a thickness in a range of 10 to 100 nm.

The first blue EML 920 only includes the first compound 922, the second compound 924 and the third compound 926. Namely, in the first blue EML 920, a summation of a weight % of the first compound 922, a weight % of the second compound 924 and a weight % of the third compound 926 is 100%.

In the first blue EML 920, a weight % of each of the first and second compounds 922 and 924 is greater than that of the third compound 926. A weight % of the first compound 922 and a weight % of the second compound 924 may be same or different. For example, in the first blue EML 920, the third compound 926 may have a weight % in a range of 8 to 20, preferably 12 to 20.

The first compound 922 is represented by Formula 1 and may be one of the compounds in Formula 2. The second compound 924 is represented by Formula 3 and may be one of the compounds in Formula 4. The third compound 926 is represented by Formula 5 and may be one of the compounds in Formula 6.

The second blue EML 940 includes a fourth compound 942 being a host and a fifth compound 944 being a blue dopant. The fifth compound 944 may be a blue fluorescent dopant. The second blue EML 940 may have a thickness in a range of 10 to 100 nm.

For example, the fourth compound 942 may be selected from the group consisting of mCP, mCP-CN, mCBP, CBP-CN, mCPPO1, Ph-mCP, TSPO1, CzBPCb, UGH-1, UGH-2, UGH-3, SPPO1 and SimCP, the fifth compound 944 may be selected from the group consisting of perylene, DPAVBi, DPAVB, BDAVBi, spiro-DPVBi, DSB, DSA, TBPe, Bepp2 and PCAN.

For example, the second blue EML 940 may include an anthracene derivative as a host and a boron derivative as a blue host.

The organic light emitting layer 820 of the OLED D5 includes the first emitting part 910 including the first blue EML 920, the second emitting part 930 including the second blue EML 940 and the third emitting part 950 including the red, yellow-green and green EMLs 962, 964 and 966 so that the OLED D5 has a tandem structure.

In this case, the first blue EML 920 includes the first compound 922 represented by Formula 1, the second compound 924 represented by Formula 3 and the third compound 926 represented by Formula 5. As a result, in the OLED D5 and the organic light emitting display device 700 including the OLED D5, the driving voltage is reduced, and the emitting efficiency, the color purity and the lifespan are improved.

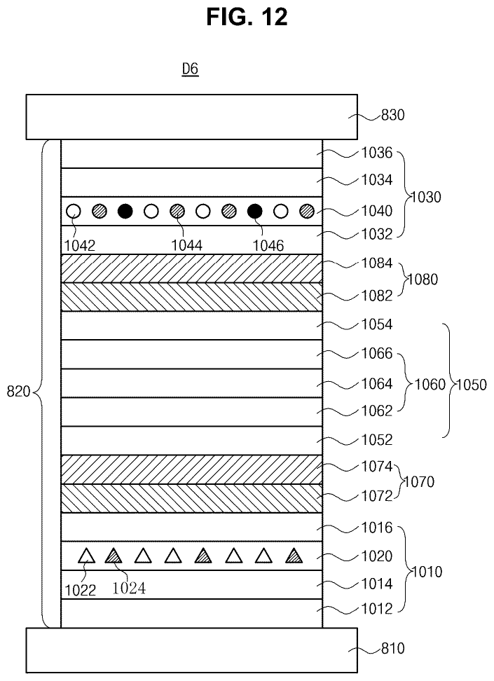

FIG. 12 is a schematic cross-sectional view of an OLED according to a ninth embodiment of the present disclosure.

As illustrated in FIG. 12, the OLED D6 includes first and second electrodes 810 and 830, which face each other and an organic light emitting layer 820 therebetween. The organic light emitting layer 820 includes a first emitting part 1010 including a first EML 1020, e.g., a first blue EML, a second emitting part 1030 including a second EML 1040, e.g., a second blue EML, and a third emitting part 1050 including a third EML 1060. The organic light emitting layer 820 may further includes a first CGL 1070 between the first and third emitting parts 1010 and 1050 and a second CGL 1080 between the second and third emitting parts 1030 and 1050. The OLED D6 may further include a capping layer on the second electrode 830 to enhance a light extraction efficiency.

The organic light emitting display device 700 may include a red pixel region, a green pixel region and a blue pixel region, and the OLED D6 may be positioned in the red, green and blue pixel regions RP, GP and BP and emits blue light.

The first electrode 810 may be an anode, and the second electrode 830 may be a cathode. One of the first and second electrodes 810 and 830 may be a reflective electrode, and the other one of the first and second electrodes 810 and 830 may be a transparent (or a semitransparent) electrode. For example, the first electrode 810 may have a single-layered structure of ITO, and the second electrode 830 may be formed of Al.

The first emitting part 1010 may further include at least one of a first HTL 1014 under the first blue EML 1020 and a first ETL 1016 over the first blue EML 1020.

In addition, the first emitting part 1010 may further include an HIL 1012 between the first electrode 810 and the first HTL 1014.

Moreover, the first emitting part 1010 may further include at least one of a first EBL between the first HTL 1014 and the first blue EML 1020 and a first HBL between the first blue EML 1020 and the first ETL 1016.

The second emitting part 1030 may further include at least one of a second HTL 1032 under the second blue EML 1040 and a second ETL 1034 over the second blue EML 1040.

In addition, the second emitting part 1030 may further include an EIL 1036 between the second electrode 830 and the second ETL 1034.

Moreover, the second emitting part 1030 may further include at least one of a second EBL between the second HTL 1032 and the second blue EML 1040 and a second HBL between the second blue EML 1040 and the second ETL 1034.

In the third emitting part 1050, the third EML 1060 may include a red EML 1062, a yellow-green EML 1064 and a green EML 1066. In this case, the yellow-green EML 1064 is disposed between the red and green EMLs 1062 and 1066. Alternatively, the yellow-green EML 1064 may be omitted, and the third EML 1060 may have a double-layered structure including the red and green EMLs 1062 and 1066.

The red EML 1062 includes a red host and a red dopant, the green EML 1066 includes a green host and a green dopant, and the yellow-green EML 1064 includes a yellow-green host and a yellow-green dopant. Each of the red dopant, the green dopant and the yellow-green dopant may be one of a fluorescent compound, a phosphorescent compound and a delayed fluorescent compound.

The third emitting part 1050 may include at least one of a third HTL 1052 under the third EML 1060 and a third ETL 1054 over the third EML 1060.

In addition, the third emitting part 1050 may further include at least one of a third EBL between the third HTL 1052 and the third EML 1060 and a third HBL between the third EML 1060 and the third ETL 1054.

The first CGL 1070 is positioned between the first and third emitting parts 1010 and 1050, and the second CGL 1080 is positioned between the second and third emitting parts 1030 and 1050. Namely, the first and third emitting parts 1010 and 1050 may be connected to each other through the first CGL 1070, and the second and third emitting parts 1030 and 1050 may be connected to each other through the second CGL 1080. The first CGL 1070 may be a P-N junction CGL of a first N-type CGL 1072 and a first P-type CGL 1074, and the second CGL 1080 may be a P-N junction CGL of a second N-type CGL 1082 and a second P-type CGL 1084.

In the first CGL 1070, the first N-type CGL 1072 is positioned between the first ETL 1016 and the third HTL 1052, and the first P-type CGL 1074 is positioned between the first N-type CGL 1072 and the third HTL 1052.

In the second CGL 1080, the second N-type CGL 1082 is positioned between the third ETL 1054 and the second HTL 1032, and the second P-type CGL 1084 is positioned between the second N-type CGL 1082 and the second HTL 1032.

The first blue EML 1020 includes a fourth compound 1022 being a host and a fifth compound 1024 being a blue dopant. The fifth compound 1024 may be a blue fluorescent dopant. The first blue EML 1020 may have a thickness in a range of 10 to 100 nm.

For example, the first blue EML 1020 may include an anthracene derivative as a host and a boron derivative as a blue host.

The second blue EML 1040 includes a first compound 1042, e.g., a first host, being an n-type host, a second compound 1044, e.g., a second host, being a p-type host and a third compound 1046 being a phosphorescent dopant. The second blue EML 1040 may have a thickness in a range of 10 to 100 nm.

The second blue EML 1040 only includes the first compound 1042, the second compound 1044 and the third compound 1046. Namely, in the second blue EML 1040, a summation of a weight % of the first compound 1042, a weight % of the second compound 1044 and a weight % of the third compound 1046 is 100%.

In the second blue EML 1040, a weight % of each of the first and second compounds 1042 and 1044 is greater than that of the third compound 1046. A weight % of the first compound 1042 and a weight % of the second compound 1044 may be same or different. For example, in the second blue EML 1040, the third compound 1046 may have a weight % in a range of 8 to 20, preferably 12 to 20.

The first compound 1042 is represented by Formula 1 and may be one of the compounds in Formula 2. The second compound 1044 is represented by Formula 3 and may be one of the compounds in Formula 4. The third compound 1046 is represented by Formula 5 and may be one of the compounds in Formula 6.

The organic light emitting layer 820 of the OLED D6 includes the first emitting part 1010 including the first blue EML 1020, the second emitting part 1030 including the second blue EML 1040 and the third emitting part 1050 including the red, yellow-green and green EMLs 1062, 1064 and 1066 so that the OLED D6 has a tandem structure.

In this case, the second blue EML 1040 includes the first compound 1042 represented by Formula 1, the second compound 1044 represented by Formula 3 and the third compound 1046 represented by Formula 5. As a result, in the OLED D6 and the organic light emitting display device 700 including the OLED D6, the driving voltage is reduced, and the emitting efficiency, the color purity and the lifespan are improved.

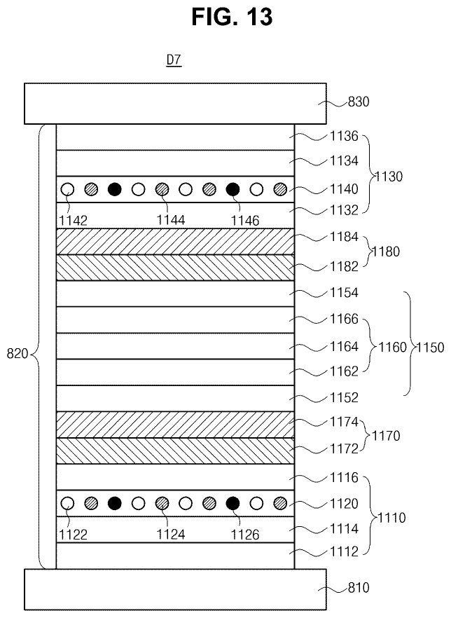

FIG. 13 is a schematic cross-sectional view of an OLED according to a tenth embodiment of the present disclosure.

As illustrated in FIG. 13, the OLED D7 includes first and second electrodes 810 and 830, which face each other and an organic light emitting layer 820 therebetween. The organic light emitting layer 820 includes a first emitting part 1110 including a first EML 1120, e.g., a first blue EML, a second emitting part 1130 including a second EML 1140, e.g., a second blue EML, and a third emitting part 1150 including a third EML 1160. The organic light emitting layer 820 may further includes a first CGL 1170 between the first and third emitting parts 1110 and 1150 and a second CGL 1180 between the second and third emitting parts 1130 and 1150. The OLED D7 may further include a capping layer on the second electrode 830 to enhance a light extraction efficiency.

The organic light emitting display device 700 may include a red pixel region, a green pixel region and a blue pixel region, and the OLED D7 may be positioned in the red, green and blue pixel regions RP, GP and BP and emits blue light.

The first electrode 810 may be an anode, and the second electrode 830 may be a cathode. One of the first and second electrodes 810 and 830 may be a reflective electrode, and the other one of the first and second electrodes 810 and 830 may be a transparent (or a semitransparent) electrode. For example, the first electrode 810 may have a single-layered structure of ITO, and the second electrode 830 may be formed of Al.

The first emitting part 1110 may further include at least one of a first HTL 1114 under the first blue EML 1120 and a first ETL 1116 over the first blue EML 1120.

In addition, the first emitting part 1110 may further include an HIL 1112 between the first electrode 810 and the first HTL 1114.

Moreover, the first emitting part 1110 may further include at least one of a first EBL between the first HTL 1114 and the first blue EML 1120 and a first HBL between the first blue EML 1120 and the first ETL 1116.

The second emitting part 1130 may further include at least one of a second HTL 1132 under the second blue EML 1140 and a second ETL 1134 over the second blue EML 1140.

In addition, the second emitting part 1130 may further include an EIL 1136 between the second electrode 830 and the second ETL 1134.

Moreover, the second emitting part 1130 may further include at least one of a second EBL between the second HTL 1132 and the second blue EML 1140 and a second HBL between the second blue EML 1140 and the second ETL 1134.

In the third emitting part 1150, the third EML 1160 may include a red EML 1162, a yellow-green EML 1164 and a green EML 1166. In this case, the yellow-green EML 1164 is disposed between the red and green EMLs 1162 and 1166. Alternatively, the yellow-green EML 1164 may be omitted, and the third EML 1160 may have a double-layered structure including the red and green EMLs 1162 and 1166.

The red EML 1162 includes a red host and a red dopant, the green EML 1166 includes a green host and a green dopant, and the yellow-green EML 1164 includes a yellow-green host and a yellow-green dopant. Each of the red dopant, the green dopant and the yellow-green dopant may be one of a fluorescent compound, a phosphorescent compound and a delayed fluorescent compound.

The third emitting part 1150 may include at least one of a third HTL 1152 under the third EML 1160 and a third ETL 1154 over the third EML 1160.

In addition, the third emitting part 1150 may further include at least one of a third EBL between the third HTL 1152 and the third EML 1160 and a third HBL between the third EML 1160 and the third ETL 1154.

The first CGL 1170 is positioned between the first and third emitting parts 1110 and 1150, and the second CGL 1180 is positioned between the second and third emitting parts 1130 and 1150. Namely, the first and third emitting parts 1110 and 1150 may be connected to each other through the first CGL 1170, and the second and third emitting parts 1130 and 1150 may be connected to each other through the second CGL 1180.

The first CGL 1170 may be a P-N junction CGL of a first N-type CGL 1172 and a first P-type CGL 1174, and the second CGL 1180 may be a P-N junction CGL of a second N-type CGL 1182 and a second P-type CGL 1184.

In the first CGL 1170, the first N-type CGL 1172 is positioned between the first ETL 1116 and the third HTL 1152, and the first P-type CGL 1174 is positioned between the first N-type CGL 1172 and the third HTL 1152.

In the second CGL 1180, the second N-type CGL 1182 is positioned between the third ETL 1154 and the second HTL 1132, and the second P-type CGL 1184 is positioned between the second N-type CGL 1182 and the second HTL 1132.

The first blue EML 1120 includes a first compound 1122, e.g., a first host, being an n-type host, a second compound 1124, e.g., a second host, being a p-type host and a third compound 1126 being a phosphorescent dopant. The first blue EML 1120 may have a thickness in a range of 10 to 100 nm.

The first blue EML 1120 only includes the first compound 1122, the second compound 1124 and the third compound 1126. Namely, in the first blue EML 1120, a summation of a weight % of the first compound 1122, a weight % of the second compound 1124 and a weight % of the third compound 1126 is 100%.

In the first blue EML 1120, a weight % of each of the first and second compounds 1122 and 1124 is greater than that of the third compound 1126. A weight % of the first compound 1122 and a weight % of the second compound 1124 may be same or different. For example, in the first blue EML 1120, the third compound 1126 may have a weight % in a range of 8 to 20, preferably 12 to 20.

The first compound 1122 is represented by Formula 1 and may be one of the compounds in Formula 2. The second compound 1124 is represented by Formula 3 and may be one of the compounds in Formula 4. The third compound 1126 is represented by Formula 5 and may be one of the compounds in Formula 6.

The second blue EML 1140 includes a fourth compound 1142, e.g., a third host, being an n-type host, a fifth compound 1144, e.g., a fourth host, being a p-type host and a sixth compound 1146 being a phosphorescent dopant. The second blue EML 1140 may have a thickness in a range of 10 to 100 nm.

The second blue EML 1140 only includes the fourth compound 1142, the fifth compound 1144 and the sixth compound 1146. Namely, in the second blue EML 1140, a summation of a weight % of the fourth compound 1142, a weight % of the fifth compound 1144 and a weight % of the sixth compound 1146 is 100%.

In the second blue EML 1140, a weight % of each of the fourth and fifth compounds 1142 and 1144 is greater than that of the sixth compound 1146. A weight % of the fourth compound 1142 and a weight % of the fifth compound 1144 may be same or different. For example, in the second blue EML 1140, the sixth compound 1146 may have a weight % in a range of 8 to 20, preferably 12 to 20.

The fourth compound 1142 is represented by Formula 1 and may be one of the compounds in Formula 2. The fifth compound 1144 is represented by Formula 3 and may be one of the compounds in Formula 4. The sixth compound 1146 is represented by Formula 5 and may be one of the compounds in Formula 6.

The first compound 1122 in the first blue EML 1120 and the fourth compound 1142 in the second blue EML 1140 may be same or different. The second compound 1124 in the first blue EML 1120 and the fifth compound 1144 in the second blue EML 1140 may be same or different. The third compound 1126 in the first blue EML 1120 and the sixth compound 1146 in the second blue EML 1140 may be same or different.

The organic light emitting layer 820 of the OLED D7 includes the first emitting part 1110 including the first blue EML 1120, the second emitting part 1130 including the second blue EML 1140 and the third emitting part 1150 including the red, yellow-green and green EMLs 1162, 1164 and 1166 so that the OLED D7 has a tandem structure.

In this case, the second blue EML 1140 includes the first compound 1142 represented by Formula 1, the second compound 1144 represented by Formula 3 and the third compound 1146 represented by Formula 5. As a result, in the OLED D7 and the organic light emitting display device 700 including the OLED D7, the driving voltage is reduced, and the emitting efficiency, the color purity and the lifespan are improved.

It will be apparent to those skilled in the art that various modifications and variations can be made in the present disclosure without departing from the spirit or scope of the present disclosure. Thus, it is intended that the present disclosure cover the modifications and variations of this disclosure provided they come within the scope of the appended claims and their equivalents.

What is claimed is:

1. An organic light emitting diode, comprising:
a first electrode;
a second electrode facing the first electrode; and
a first blue emitting material layer including a first compound, a second compound and a third compound and positioned between the first and second electrodes,
wherein the first compound is represented by Formula 1: 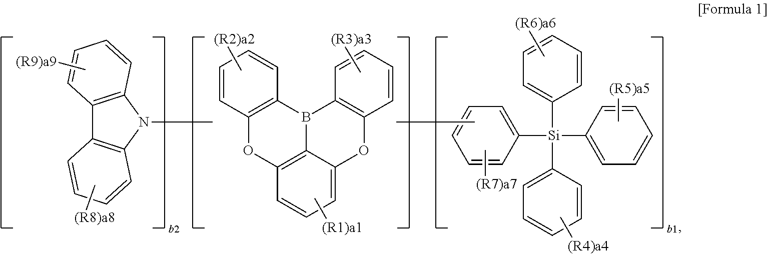
wherein in the Formula 1,
a1 is an integer of 0 to 3, each of a2 and a3 is independently an integer of 0 to 4, and a summation of a1, a2 and a3 is 9 or less,
each of a4, a5 and a6 is independently an integer of 0 to 5, and each of a7, a8 and a9 is independently an integer of 0 to 4,
each of b1 and b2 is independently an integer of 1 to 10, and a summation of b1 and b2 is 11 or less,
each of R1, R2, R3, R4, R5, R6 and R7 is independently selected from the group consisting of deuterium, halogen, cyano, a substituted or unsubstituted C1 to C20 alkyl group, a substituted or unsubstituted C6 to C30 aryl group, a substituted or unsubstituted C3 to C60 heteroaryl group, a substituted or unsubstituted C1 to C60 alkylamine group and a substituted or unsubstituted C6 to C30 arylamine group, and
each of R8 and R9 is independently selected from the group consisting of deuterium, halogen, cyano, a substituted or unsubstituted C1 to C20 alkyl group, a substituted or unsubstituted C6 to C30 aryl group, a substituted or unsubstituted C3 to C60 heteroaryl group, a substituted or unsubstituted C1 to C60 alkylamine group and a substituted or unsubstituted C6 to C30 arylamine group, or adjacent two R8 and/or adjacent two R9 are connected to each other to form a substituted or unsubstituted aromatic ring or a substituted or unsubstituted heteroaromatic ring,
wherein the second compound is represented by Formula 3: 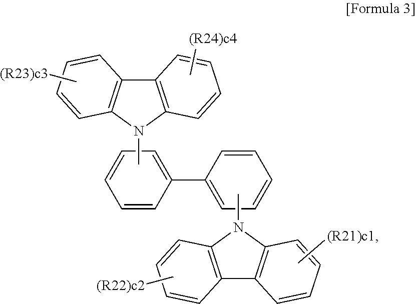
wherein in the Formula 3,
each of c1, c2, c3 and c4 is independently an integer of 0 to 4, and
each of R21, R22, R23 and R24 is independently selected from the group consisting of deuterium, halogen, cyano, a substituted or unsubstituted C1 to C20 alkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group,
wherein the third compound is represented by Formula 5: 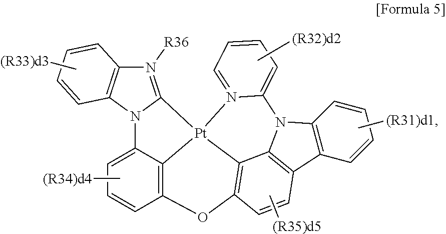
wherein in the Formula 5,
each of R31, R32, R33, R34, R35 and R36 is independently selected from the group consisting of deuterium, halogen, cyano, a substituted or unsubstituted C1 to C20 alkyl group, a substituted or unsubstituted C3 to C30 cycloalkyl group, a substituted or unsubstituted C1 to C20 alkylsilyl group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group,
each of d1, d2 and d3 is independently an integer of 0 to 4, d4 is an integer of 0 to 3, and d5 is an integer of 0 to 2, and
wherein in the first blue emitting material layer, a summation of a weight % of the first compound, a weight % of the second compound and a weight % of the third compound is 100%, and the weight % of each of the first and second compounds is greater than the weight % of the third compound.

2. The organic light emitting diode according to claim 1, wherein the Formula 1 is represented by one of Formulas 1a to 1f: 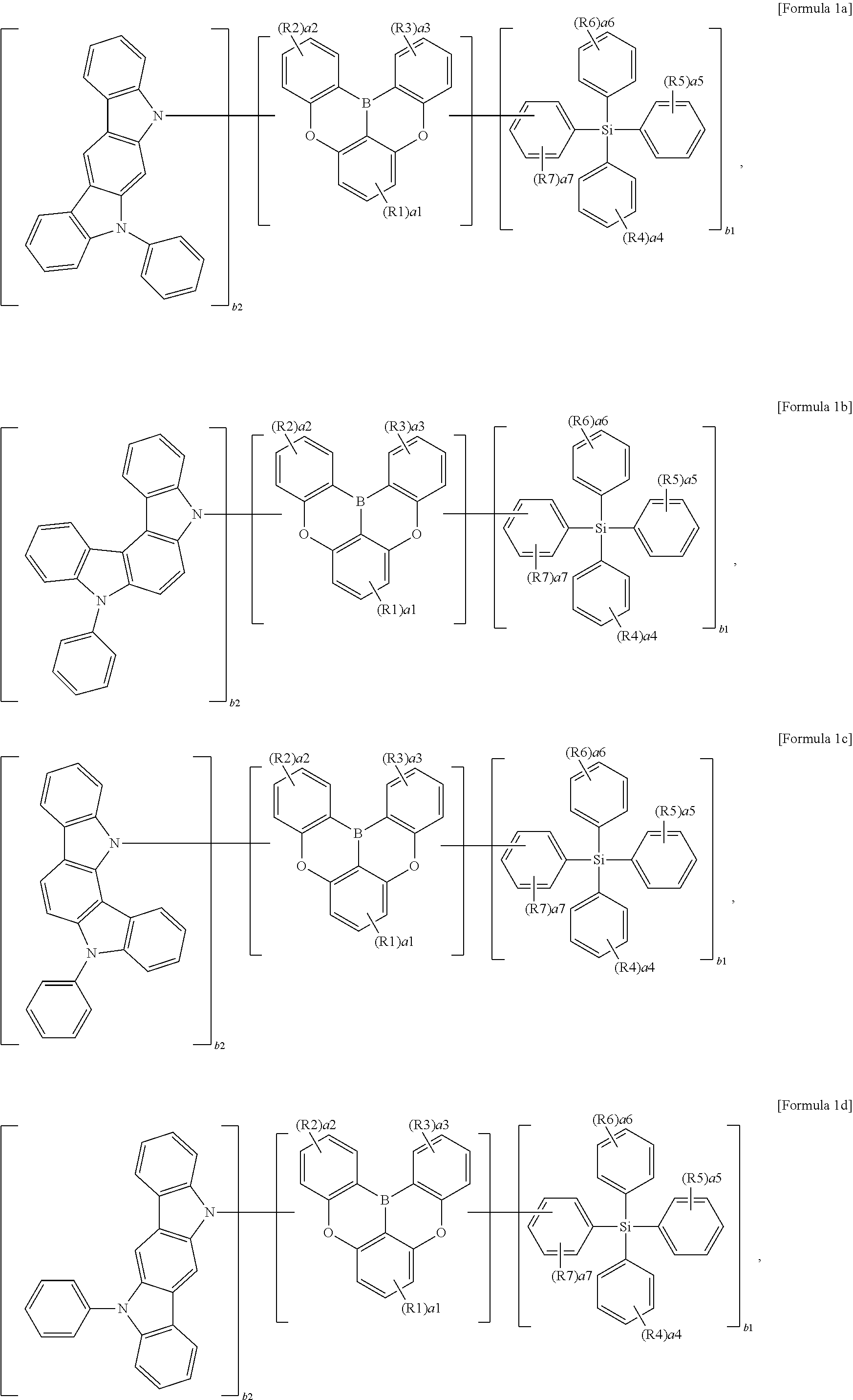 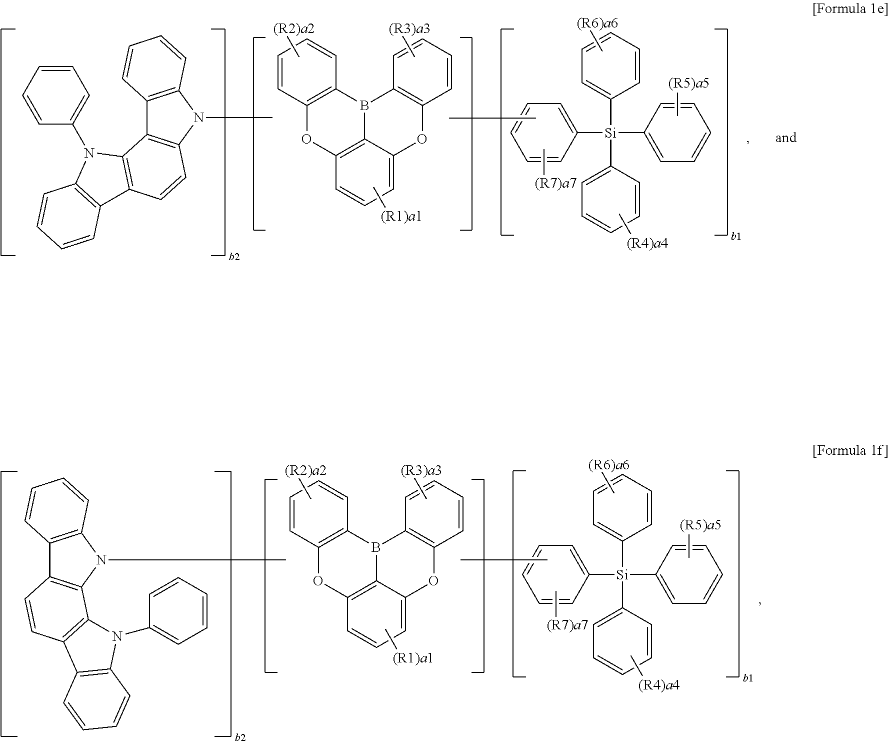
wherein in each of the Formulas 1a to 1f,
a1 is an integer of 0 to 3, each of a2 and a3 is independently an integer of 0 to 4, and a summation of a1, a2 and a3 is 9 or less,
each of a4, a5 and a6 is independently an integer of 0 to 5, and a7 is an integer of 0 to 4,
each of b1 and b2 is independently an integer of 1 to 10, and a summation of b1 and b2 is 11 or less,
each of R1, R2, R3, R4, R5, R6 and R7 is independently selected from the group consisting of deuterium, halogen, cyano, a substituted or unsubstituted C1 to C20 alkyl group, a substituted or unsubstituted C6 to C30 aryl group, a substituted or unsubstituted C3 to C60 heteroaryl group, a substituted or unsubstituted C1 to C60 alkylamine group and a substituted or unsubstituted C6 to C30 arylamine group.

3. The organic light emitting diode according to claim 2, wherein the first compound is one of compounds in Formula 2:

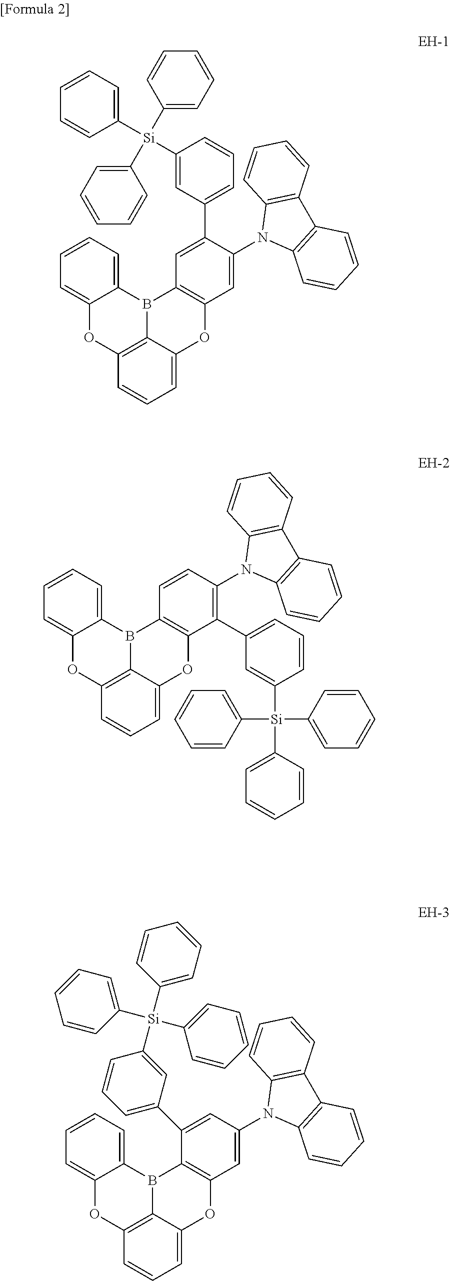 [SMILES: c1ccc([Si](c2ccccc2)(c2ccccc2)c2cccc(-c3cc4c(cc3-n3c5ccccc5c5ccccc53)Oc3cccc5c3B4c3ccccc3O5)c2)cc1 ; c1ccc([Si](c2ccccc2)(c2ccccc2)c2cccc(-c3c(-n4c5ccccc5c5ccccc54)ccc4c3Oc3cccc5c3B4c3ccccc3O5)c2)cc1 ; c1ccc([Si](c2ccccc2)(c2ccccc2)c2cccc(-c3cc(-n4c5ccccc5c5ccccc54)cc4c3B3c5ccccc5Oc5cccc(c53)O4)c2)cc1]

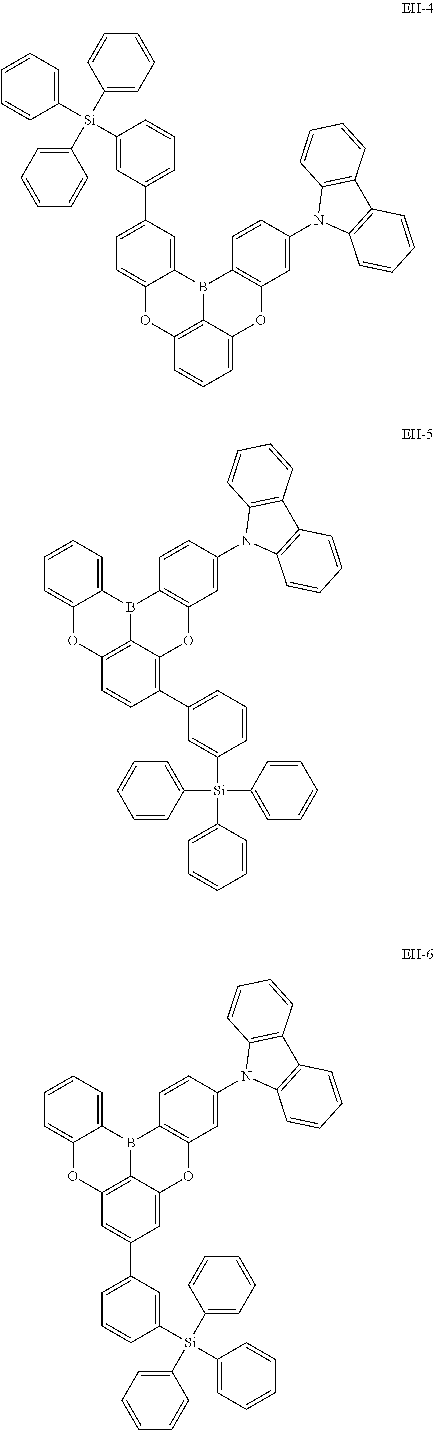 [SMILES: c1ccc([Si](c2ccccc2)(c2ccccc2)c2cccc(-c3ccc4c(c3)B3c5ccc(-n6c7ccccc7c7ccccc76)cc5Oc5cccc(c53)O4)c2)cc1 ; c1ccc([Si](c2ccccc2)(c2ccccc2)c2cccc(-c3ccc4c5c3Oc3cc(-n6c7ccccc7c7ccccc76)ccc3B5c3ccccc3O4)c2)cc1 ; c1ccc([Si](c2ccccc2)(c2ccccc2)c2cccc(-c3cc4c5c(c3)Oc3cc(-n6c7ccccc7c7ccccc76)ccc3B5c3ccccc3O4)c2)cc1]

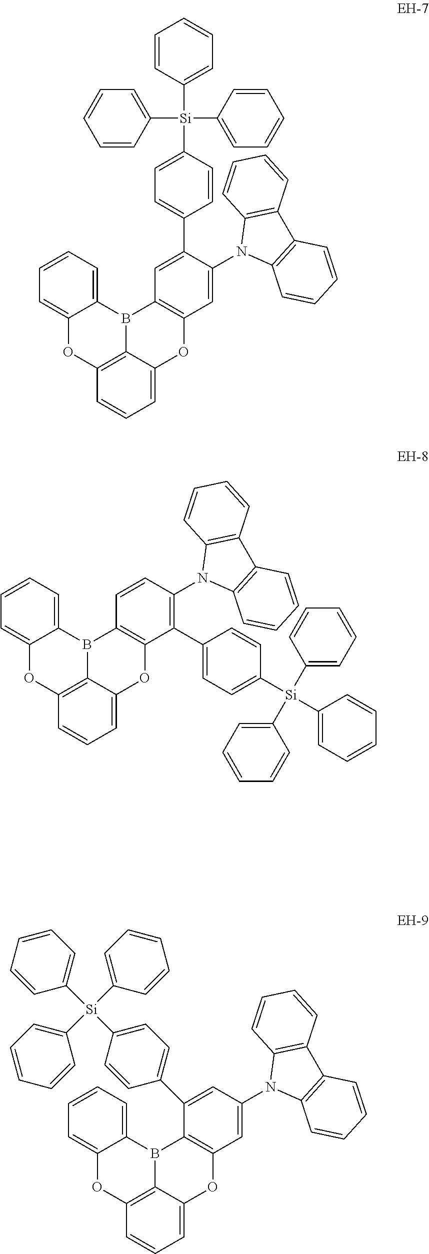 [SMILES: c1ccc([Si](c2ccccc2)(c2ccccc2)c2ccc(-c3cc4c(cc3-n3c5ccccc5c5ccccc53)Oc3cccc5c3B4c3ccccc3O5)cc2)cc1 ; c1ccc([Si](c2ccccc2)(c2ccccc2)c2ccc(-c3c(-n4c5ccccc5c5ccccc54)ccc4c3Oc3cccc5c3B4c3ccccc3O5)cc2)cc1 ; c1ccc([Si](c2ccccc2)(c2ccccc2)c2ccc(-c3cc(-n4c5ccccc5c5ccccc54)cc4c3B3c5ccccc5Oc5cccc(c53)O4)cc2)cc1]

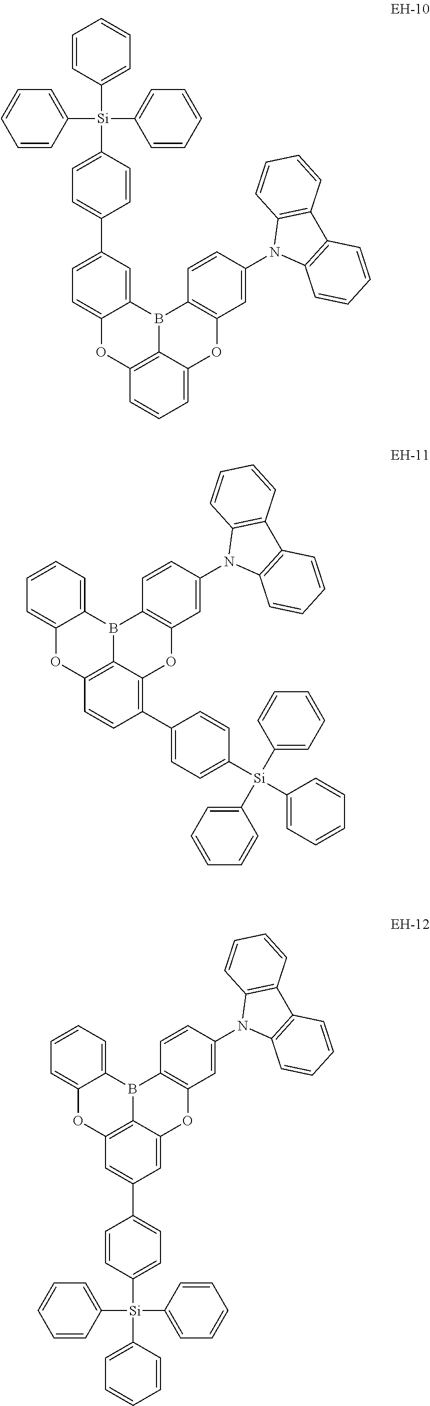 [SMILES: c1ccc([Si](c2ccccc2)(c2ccccc2)c2ccc(-c3ccc4c(c3)B3c5ccc(-n6c7ccccc7c7ccccc76)cc5Oc5cccc(c53)O4)cc2)cc1 ; c1ccc([Si](c2ccccc2)(c2ccccc2)c2ccc(-c3ccc4c5c3Oc3cc(-n6c7ccccc7c7ccccc76)ccc3B5c3ccccc3O4)cc2)cc1 ; c1ccc([Si](c2ccccc2)(c2ccccc2)c2ccc(-c3cc4c5c(c3)Oc3cc(-n6c7ccccc7c7ccccc76)ccc3B5c3ccccc3O4)cc2)cc1]

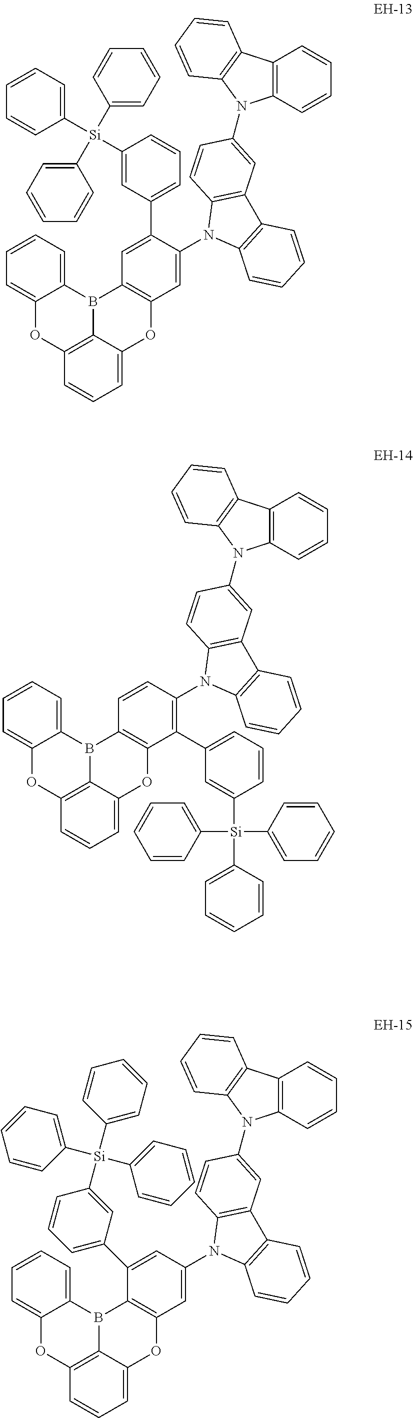 [SMILES: c1ccc([Si](c2ccccc2)(c2ccccc2)c2cccc(-c3cc4c(cc3-n3c5ccccc5c5cc(-n6c7ccccc7c7ccccc76)ccc53)Oc3cccc5c3B4c3ccccc3O5)c2)cc1 ; c1ccc([Si](c2ccccc2)(c2ccccc2)c2cccc(-c3c(-n4c5ccccc5c5cc(-n6c7ccccc7c7ccccc76)ccc54)ccc4c3Oc3cccc5c3B4c3ccccc3O5)c2)cc1 ; c1ccc([Si](c2ccccc2)(c2ccccc2)c2cccc(-c3cc(-n4c5ccccc5c5cc(-n6c7ccccc7c7ccccc76)ccc54)cc4c3B3c5ccccc5Oc5cccc(c53)O4)c2)cc1]

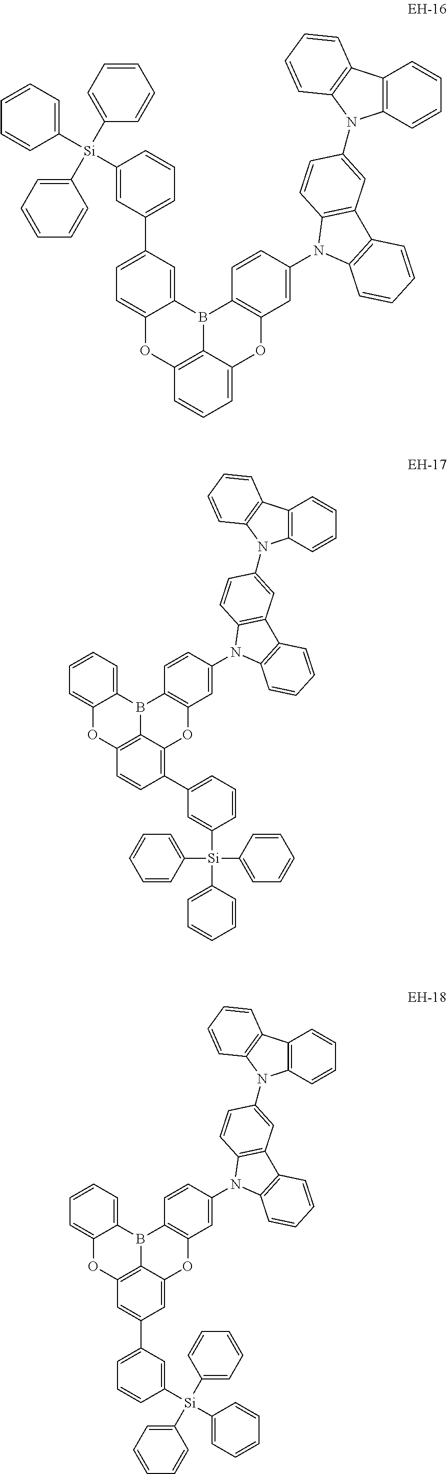 [SMILES: c1ccc([Si](c2ccccc2)(c2ccccc2)c2cccc(-c3ccc4c(c3)B3c5ccc(-n6c7ccccc7c7cc(-n8c9ccccc9c9ccccc98)ccc76)cc5Oc5cccc(c53)O4)c2)cc1 ; c1ccc([Si](c2ccccc2)(c2ccccc2)c2cccc(-c3ccc4c5c3Oc3cc(-n6c7ccccc7c7cc(-n8c9ccccc9c9ccccc98)ccc76)ccc3B5c3ccccc3O4)c2)cc1 ; c1ccc([Si](c2ccccc2)(c2ccccc2)c2cccc(-c3cc4c5c(c3)Oc3cc(-n6c7ccccc7c7cc(-n8c9ccccc9c9ccccc98)ccc76)ccc3B5c3ccccc3O4)c2)cc1]

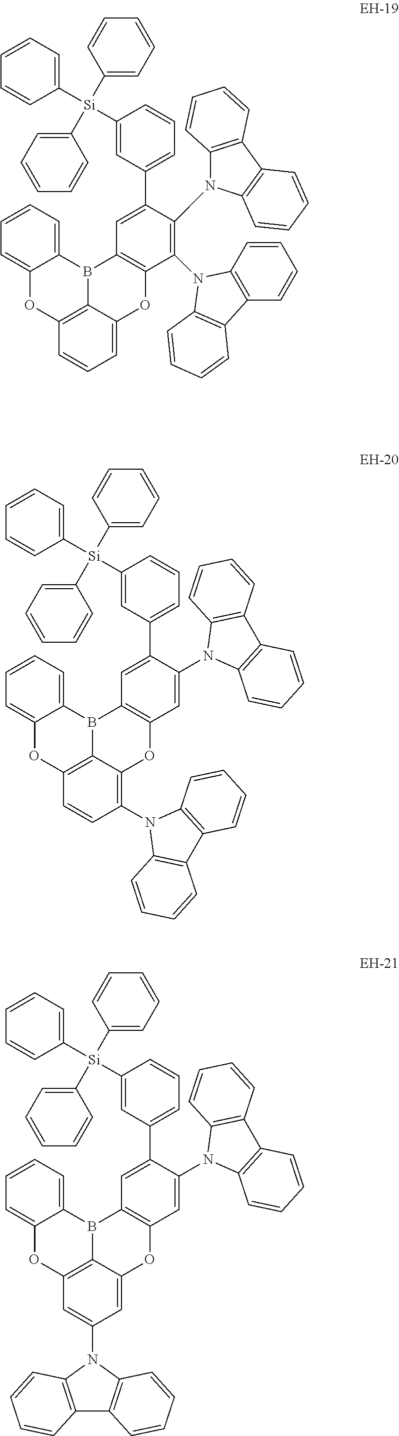 [SMILES: c1ccc([Si](c2ccccc2)(c2ccccc2)c2cccc(-c3cc4c(c(-n5c6ccccc6c6ccccc65)c3-n3c5ccccc5c5ccccc53)Oc3cccc5c3B4c3ccccc3O5)c2)cc1 ; c1ccc([Si](c2ccccc2)(c2ccccc2)c2cccc(-c3cc4c(cc3-n3c5ccccc5c5ccccc53)Oc3c(-n5c6ccccc6c6ccccc65)ccc5c3B4c3ccccc3O5)c2)cc1 ; c1ccc([Si](c2ccccc2)(c2ccccc2)c2cccc(-c3cc4c(cc3-n3c5ccccc5c5ccccc53)Oc3cc(-n5c6ccccc6c6ccccc65)cc5c3B4c3ccccc3O5)c2)cc1]

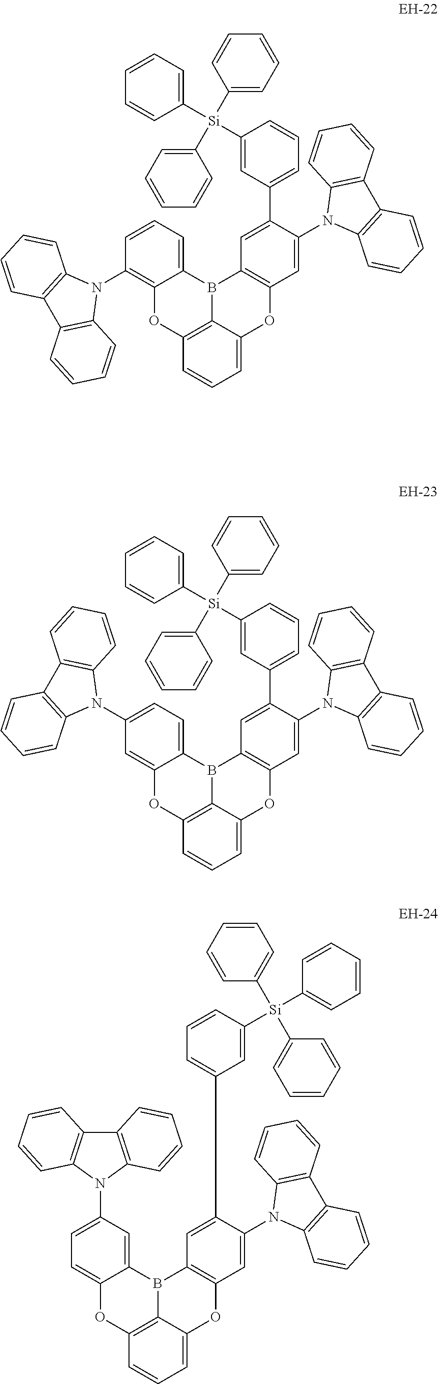 [SMILES: c1ccc([Si](c2ccccc2)(c2ccccc2)c2cccc(-c3cc4c(cc3-n3c5ccccc5c5ccccc53)Oc3cccc5c3B4c3cccc(-n4c6ccccc6c6ccccc64)c3O5)c2)cc1 ; c1ccc([Si](c2ccccc2)(c2ccccc2)c2cccc(-c3cc4c(cc3-n3c5ccccc5c5ccccc53)Oc3cccc5c3B4c3ccc(-n4c6ccccc6c6ccccc64)cc3O5)c2)cc1 ; c1ccc([Si](c2ccccc2)(c2ccccc2)c2cccc(-c3cc4c(cc3-n3c5ccccc5c5ccccc53)Oc3cccc5c3B4c3cc(-n4c6ccccc6c6ccccc64)ccc3O5)c2)cc1]

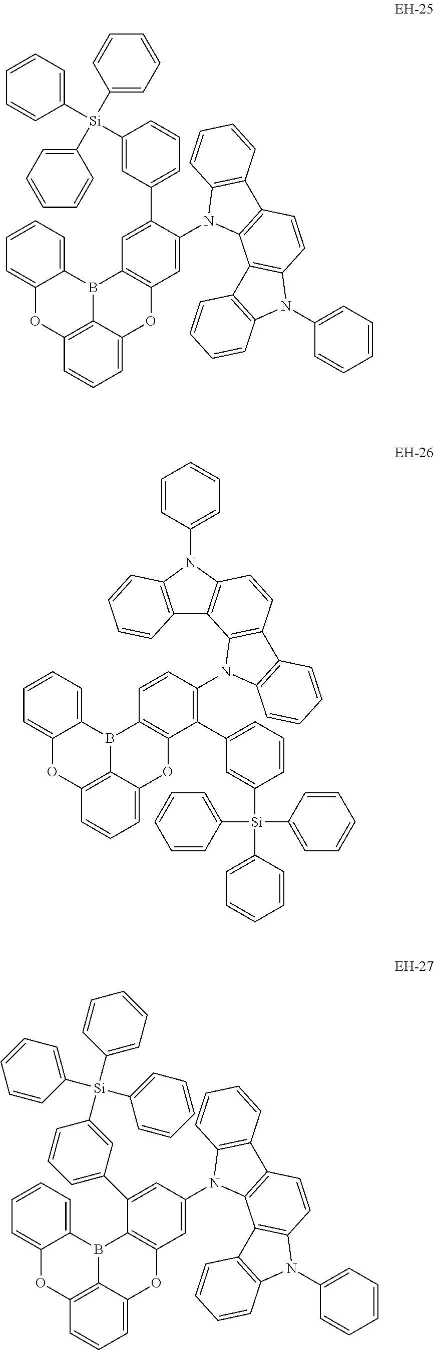 [SMILES: c1ccc(-n2c3ccccc3c3c2ccc2c4ccccc4n(-c4cc5c(cc4-c4cccc([Si](c6ccccc6)(c6ccccc6)c6ccccc6)c4)B4c6ccccc6Oc6cccc(c64)O5)c23)cc1 ; c1ccc(-n2c3ccccc3c3c2ccc2c4ccccc4n(-c4ccc5c(c4-c4cccc([Si](c6ccccc6)(c6ccccc6)c6ccccc6)c4)Oc4cccc6c4B5c4ccccc4O6)c23)cc1 ; c1ccc(-n2c3ccccc3c3c2ccc2c4ccccc4n(-c4cc5c(c(-c6cccc([Si](c7ccccc7)(c7ccccc7)c7ccccc7)c6)c4)B4c6ccccc6Oc6cccc(c64)O5)c23)cc1]

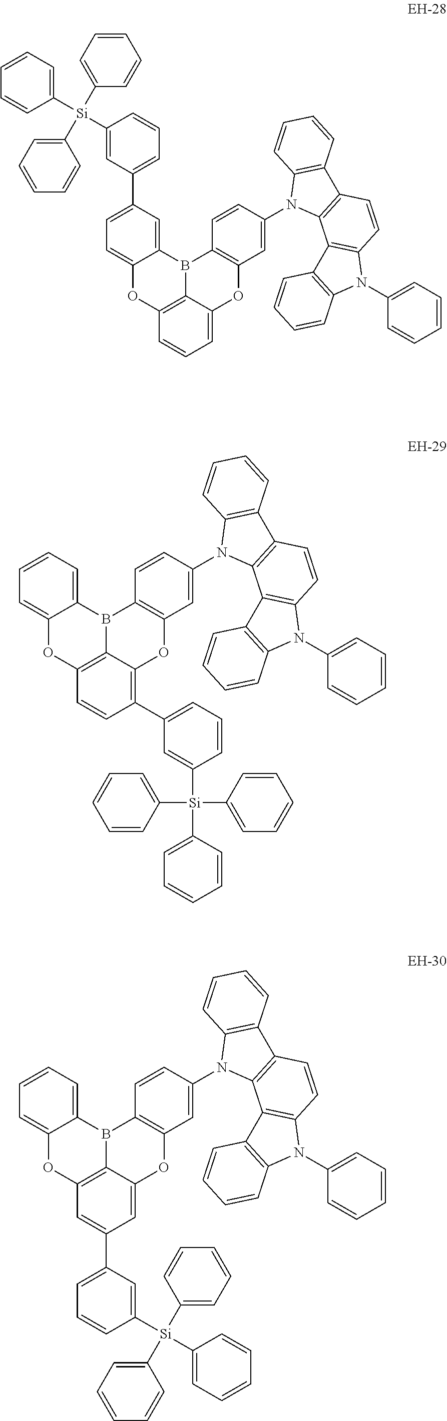 [SMILES: c1ccc(-n2c3ccccc3c3c2ccc2c4ccccc4n(-c4ccc5c(c4)Oc4cccc6c4B5c4cc(-c5cccc([Si](c7ccccc7)(c7ccccc7)c7ccccc7)c5)ccc4O6)c23)cc1 ; c1ccc(-n2c3ccccc3c3c2ccc2c4ccccc4n(-c4ccc5c(c4)Oc4c(-c6cccc([Si](c7ccccc7)(c7ccccc7)c7ccccc7)c6)ccc6c4B5c4ccccc4O6)c23)cc1 ; c1ccc(-n2c3ccccc3c3c2ccc2c4ccccc4n(-c4ccc5c(c4)Oc4cc(-c6cccc([Si](c7ccccc7)(c7ccccc7)c7ccccc7)c6)cc6c4B5c4ccccc4O6)c23)cc1]

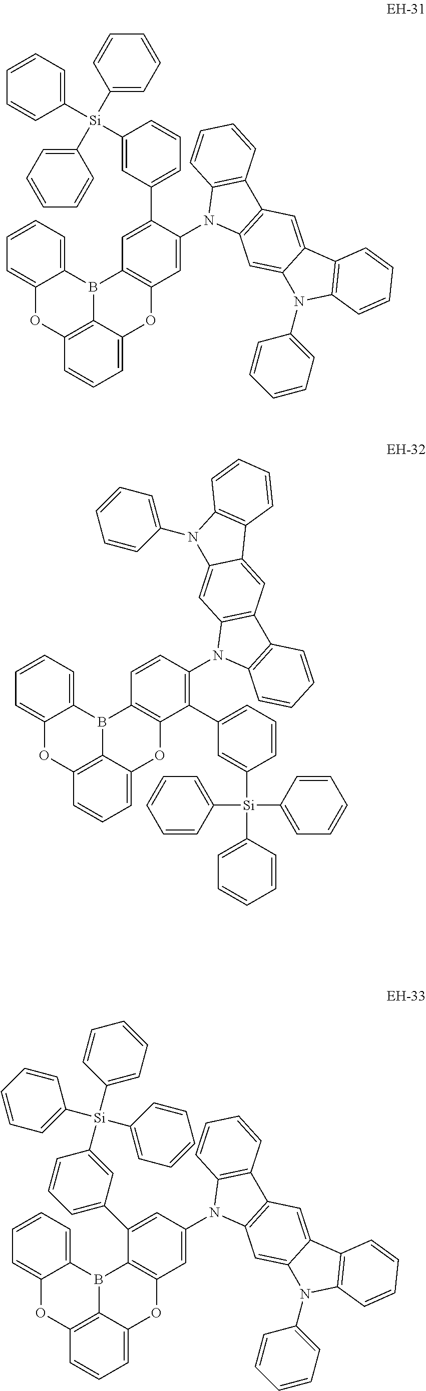 [SMILES: c1ccc(-n2c3ccccc3c3cc4c5ccccc5n(-c5cc6c(cc5-c5cccc([Si](c7ccccc7)(c7ccccc7)c7ccccc7)c5)B5c7ccccc7Oc7cccc(c75)O6)c4cc32)cc1 ; c1ccc(-n2c3ccccc3c3cc4c5ccccc5n(-c5ccc6c(c5-c5cccc([Si](c7ccccc7)(c7ccccc7)c7ccccc7)c5)Oc5cccc7c5B6c5ccccc5O7)c4cc32)cc1 ; c1ccc(-n2c3ccccc3c3cc4c5ccccc5n(-c5cc6c(c(-c7cccc([Si](c8ccccc8)(c8ccccc8)c8ccccc8)c7)c5)B5c7ccccc7Oc7cccc(c75)O6)c4cc32)cc1]

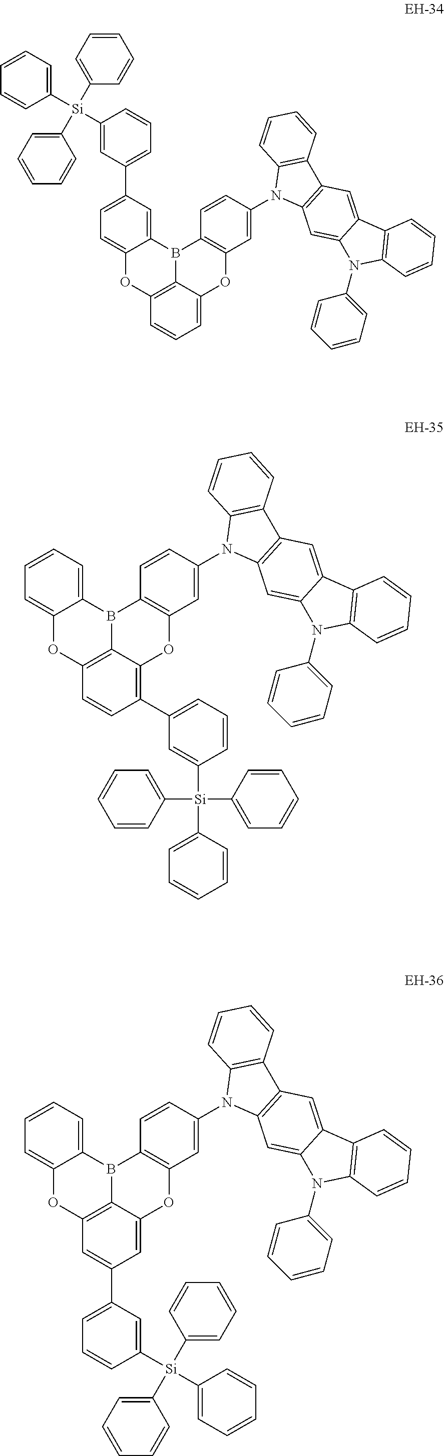 [SMILES: c1ccc(-n2c3ccccc3c3cc4c5ccccc5n(-c5ccc6c(c5)Oc5cccc7c5B6c5cc(-c6cccc([Si](c8ccccc8)(c8ccccc8)c8ccccc8)c6)ccc5O7)c4cc32)cc1 ; c1ccc(-n2c3ccccc3c3cc4c5ccccc5n(-c5ccc6c(c5)Oc5c(-c7cccc([Si](c8ccccc8)(c8ccccc8)c8ccccc8)c7)ccc7c5B6c5ccccc5O7)c4cc32)cc1 ; c1ccc(-n2c3ccccc3c3cc4c5ccccc5n(-c5ccc6c(c5)Oc5cc(-c7cccc([Si](c8ccccc8)(c8ccccc8)c8ccccc8)c7)cc7c5B6c5ccccc5O7)c4cc32)cc1]

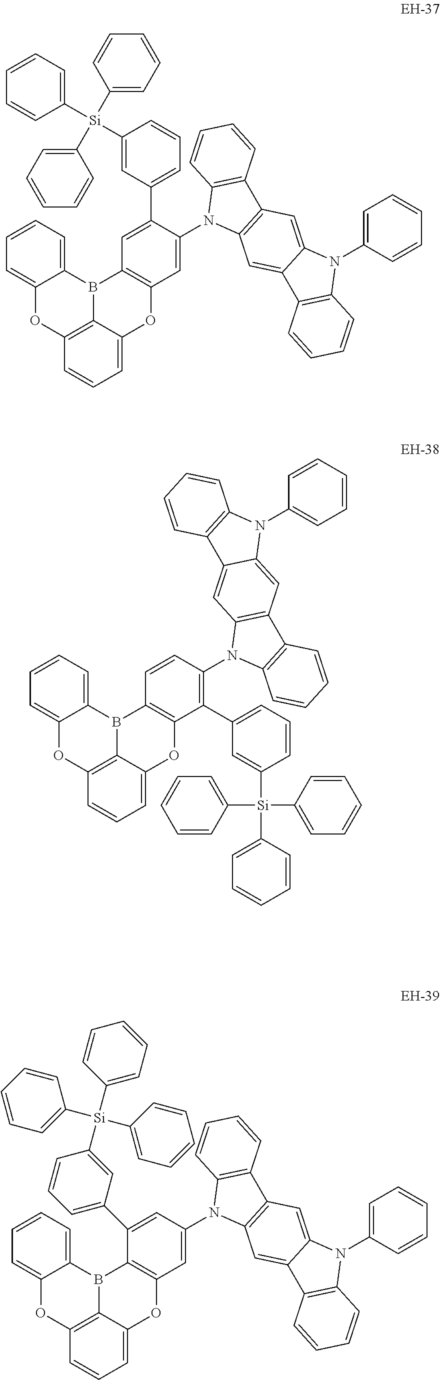 [SMILES: c1ccc(-n2c3ccccc3c3cc4c(cc32)c2ccccc2n4-c2cc3c(cc2-c2cccc([Si](c4ccccc4)(c4ccccc4)c4ccccc4)c2)B2c4ccccc4Oc4cccc(c42)O3)cc1 ; c1ccc(-n2c3ccccc3c3cc4c(cc32)c2ccccc2n4-c2ccc3c(c2-c2cccc([Si](c4ccccc4)(c4ccccc4)c4ccccc4)c2)Oc2cccc4c2B3c2ccccc2O4)cc1 ; c1ccc(-n2c3ccccc3c3cc4c(cc32)c2ccccc2n4-c2cc3c(c(-c4cccc([Si](c5ccccc5)(c5ccccc5)c5ccccc5)c4)c2)B2c4ccccc4Oc4cccc(c42)O3)cc1]

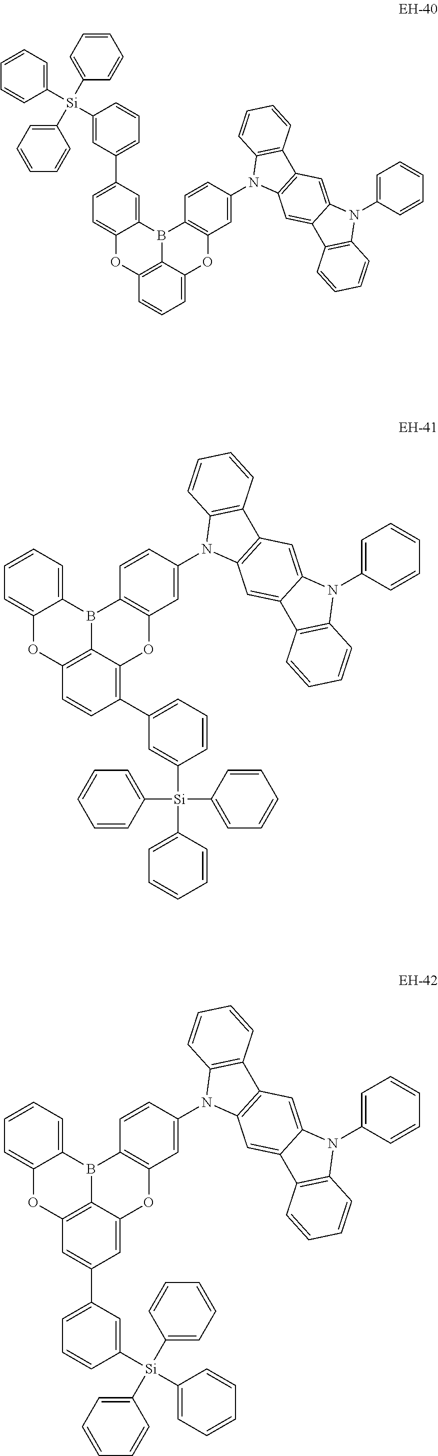 [SMILES: c1ccc(-n2c3ccccc3c3cc4c(cc32)c2ccccc2n4-c2ccc3c(c2)Oc2cccc4c2B3c2cc(-c3cccc([Si](c5ccccc5)(c5ccccc5)c5ccccc5)c3)ccc2O4)cc1 ; c1ccc(-n2c3ccccc3c3cc4c(cc32)c2ccccc2n4-c2ccc3c(c2)Oc2c(-c4cccc([Si](c5ccccc5)(c5ccccc5)c5ccccc5)c4)ccc4c2B3c2ccccc2O4)cc1 ; c1ccc(-n2c3ccccc3c3cc4c(cc32)c2ccccc2n4-c2ccc3c(c2)Oc2cc(-c4cccc([Si](c5ccccc5)(c5ccccc5)c5ccccc5)c4)cc4c2B3c2ccccc2O4)cc1]

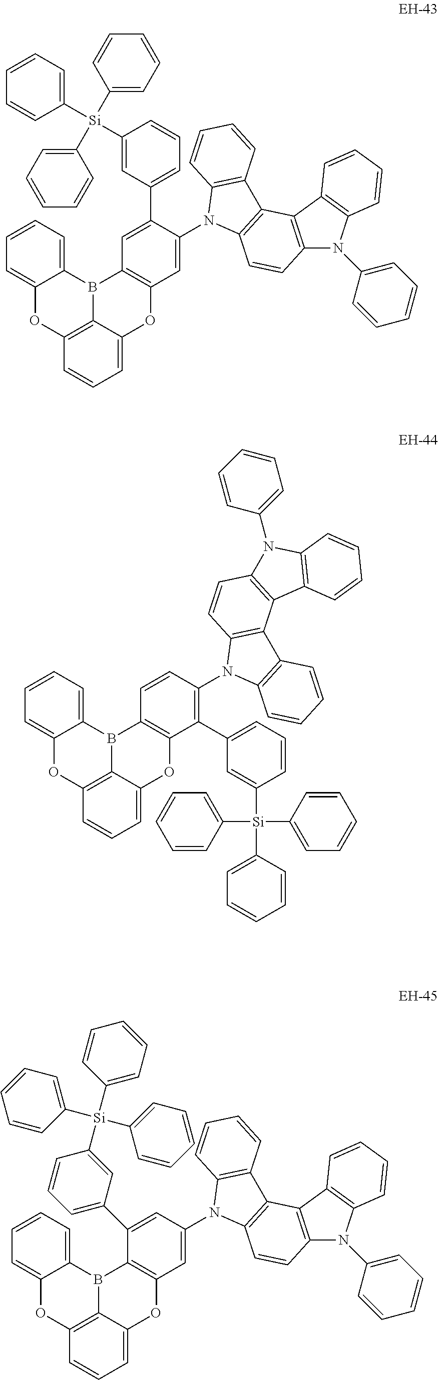 [SMILES: c1ccc(-n2c3ccccc3c3c4c5ccccc5n(-c5cc6c(cc5-c5cccc([Si](c7ccccc7)(c7ccccc7)c7ccccc7)c5)B5c7ccccc7Oc7cccc(c75)O6)c4ccc32)cc1 ; c1ccc(-n2c3ccccc3c3c4c5ccccc5n(-c5ccc6c(c5-c5cccc([Si](c7ccccc7)(c7ccccc7)c7ccccc7)c5)Oc5cccc7c5B6c5ccccc5O7)c4ccc32)cc1 ; c1ccc(-n2c3ccccc3c3c4c5ccccc5n(-c5cc6c(c(-c7cccc([Si](c8ccccc8)(c8ccccc8)c8ccccc8)c7)c5)B5c7ccccc7Oc7cccc(c75)O6)c4ccc32)cc1]

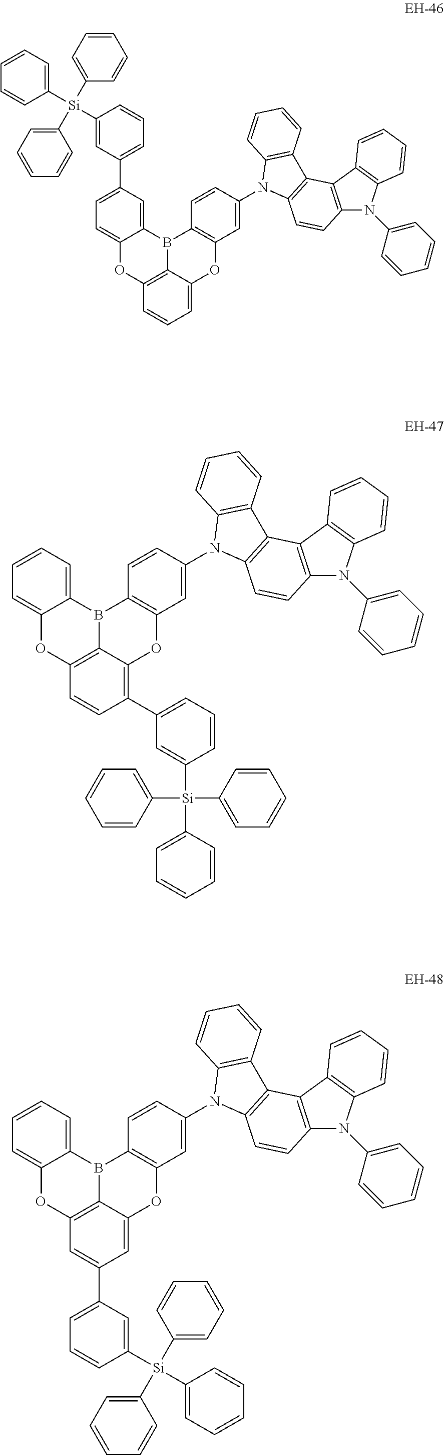 [SMILES: c1ccc(-n2c3ccccc3c3c4c5ccccc5n(-c5ccc6c(c5)Oc5cccc7c5B6c5cc(-c6cccc([Si](c8ccccc8)(c8ccccc8)c8ccccc8)c6)ccc5O7)c4ccc32)cc1 ; c1ccc(-n2c3ccccc3c3c4c5ccccc5n(-c5ccc6c(c5)Oc5c(-c7cccc([Si](c8ccccc8)(c8ccccc8)c8ccccc8)c7)ccc7c5B6c5ccccc5O7)c4ccc32)cc1 ; c1ccc(-n2c3ccccc3c3c4c5ccccc5n(-c5ccc6c(c5)Oc5cc(-c7cccc([Si](c8ccccc8)(c8ccccc8)c8ccccc8)c7)cc7c5B6c5ccccc5O7)c4ccc32)cc1]

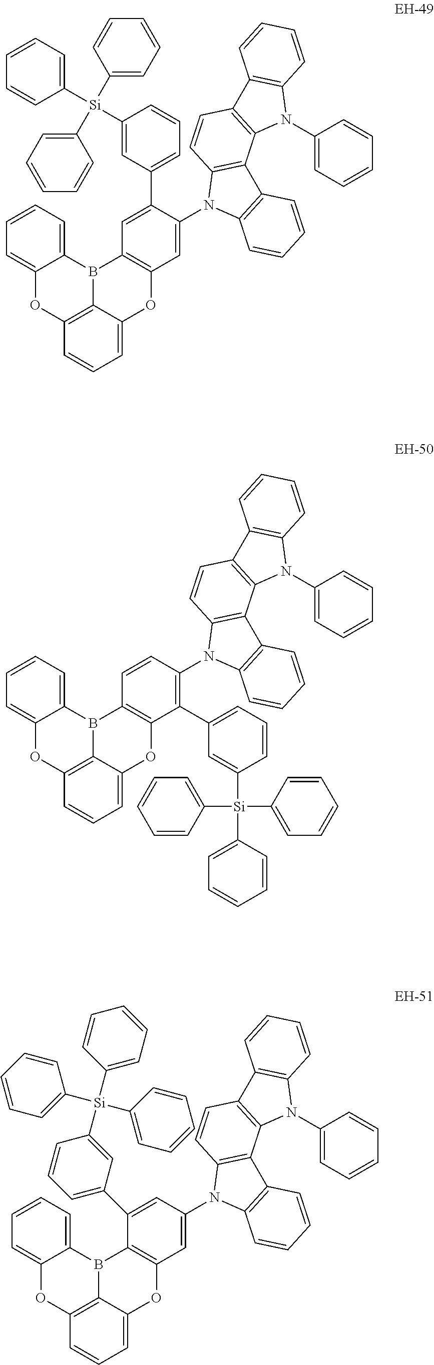 [SMILES: c1ccc(-n2c3ccccc3c3ccc4c(c5ccccc5n4-c4cc5c(cc4-c4cccc([Si](c6ccccc6)(c6ccccc6)c6ccccc6)c4)B4c6ccccc6Oc6cccc(c64)O5)c32)cc1 ; c1ccc(-n2c3ccccc3c3ccc4c(c5ccccc5n4-c4ccc5c(c4-c4cccc([Si](c6ccccc6)(c6ccccc6)c6ccccc6)c4)Oc4cccc6c4B5c4ccccc4O6)c32)cc1 ; c1ccc(-n2c3ccccc3c3ccc4c(c5ccccc5n4-c4cc5c(c(-c6cccc([Si](c7ccccc7)(c7ccccc7)c7ccccc7)c6)c4)B4c6ccccc6Oc6cccc(c64)O5)c32)cc1]

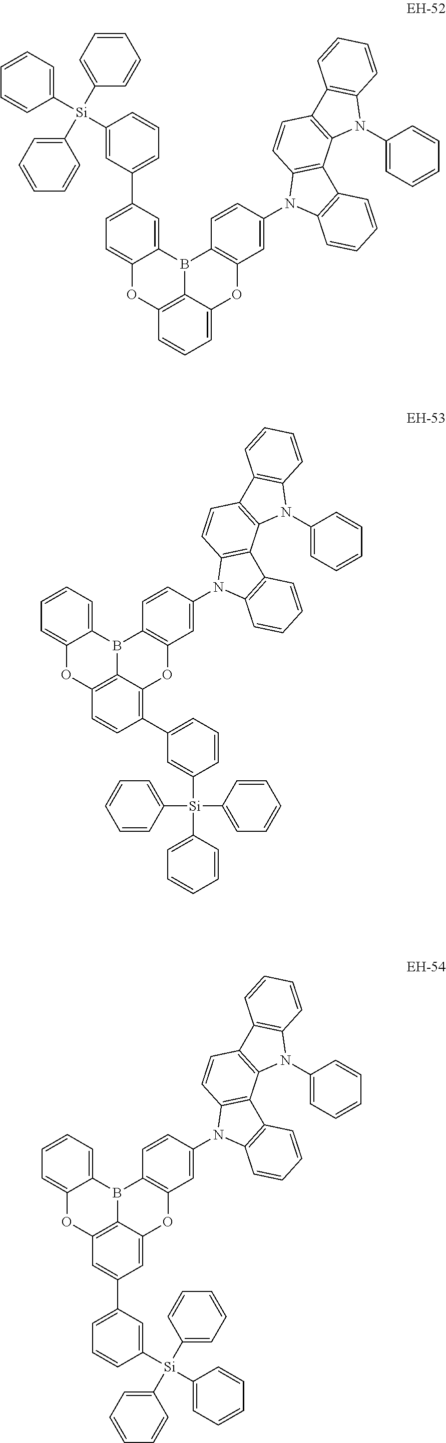 [SMILES: c1ccc(-n2c3ccccc3c3ccc4c(c5ccccc5n4-c4ccc5c(c4)Oc4cccc6c4B5c4cc(-c5cccc([Si](c7ccccc7)(c7ccccc7)c7ccccc7)c5)ccc4O6)c32)cc1 ; c1ccc(-n2c3ccccc3c3ccc4c(c5ccccc5n4-c4ccc5c(c4)Oc4c(-c6cccc([Si](c7ccccc7)(c7ccccc7)c7ccccc7)c6)ccc6c4B5c4ccccc4O6)c32)cc1 ; c1ccc(-n2c3ccccc3c3ccc4c(c5ccccc5n4-c4ccc5c(c4)Oc4cc(-c6cccc([Si](c7ccccc7)(c7ccccc7)c7ccccc7)c6)cc6c4B5c4ccccc4O6)c32)cc1]

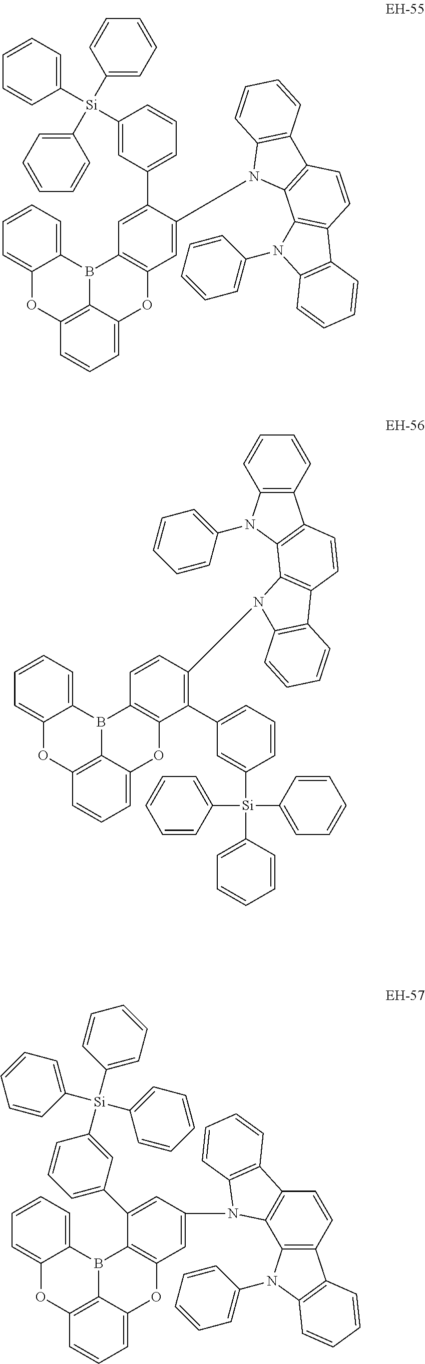 [SMILES: c1ccc(-n2c3ccccc3c3ccc4c5ccccc5n(-c5cc6c(cc5-c5cccc([Si](c7ccccc7)(c7ccccc7)c7ccccc7)c5)B5c7ccccc7Oc7cccc(c75)O6)c4c32)cc1 ; c1ccc(-n2c3ccccc3c3ccc4c5ccccc5n(-c5ccc6c(c5-c5cccc([Si](c7ccccc7)(c7ccccc7)c7ccccc7)c5)Oc5cccc7c5B6c5ccccc5O7)c4c32)cc1 ; c1ccc(-n2c3ccccc3c3ccc4c5ccccc5n(-c5cc6c(c(-c7cccc([Si](c8ccccc8)(c8ccccc8)c8ccccc8)c7)c5)B5c7ccccc7Oc7cccc(c75)O6)c4c32)cc1]

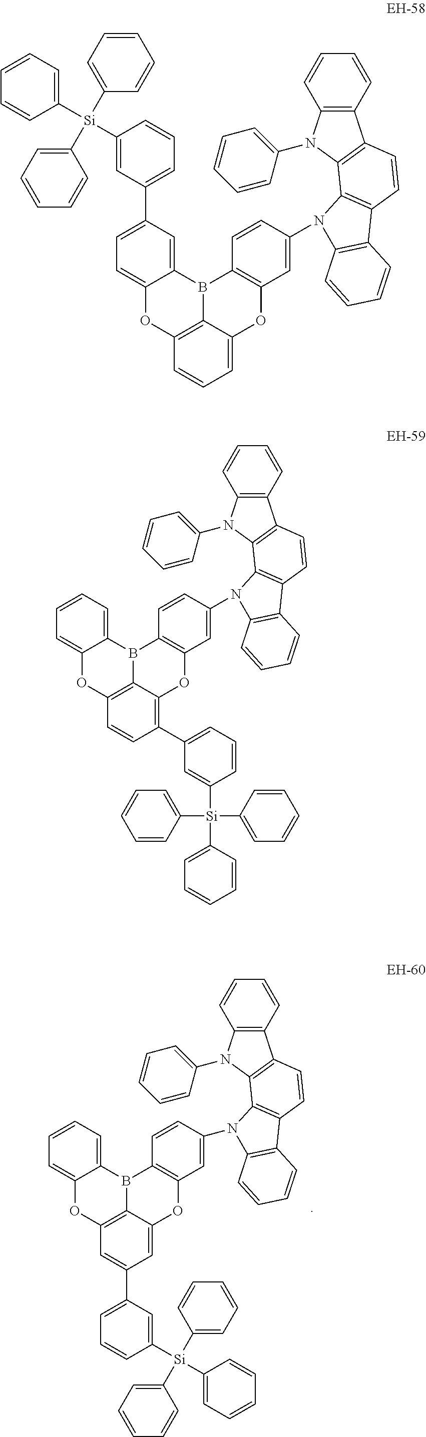 [SMILES: c1ccc(-n2c3ccccc3c3ccc4c5ccccc5n(-c5ccc6c(c5)Oc5cccc7c5B6c5cc(-c6cccc([Si](c8ccccc8)(c8ccccc8)c8ccccc8)c6)ccc5O7)c4c32)cc1 ; c1ccc(-n2c3ccccc3c3ccc4c5ccccc5n(-c5ccc6c(c5)Oc5c(-c7cccc([Si](c8ccccc8)(c8ccccc8)c8ccccc8)c7)ccc7c5B6c5ccccc5O7)c4c32)cc1 ; c1ccc(-n2c3ccccc3c3ccc4c5ccccc5n(-c5ccc6c(c5)Oc5cc(-c7cccc([Si](c8ccccc8)(c8ccccc8)c8ccccc8)c7)cc7c5B6c5ccccc5O7)c4c32)cc1]

4. The organic light emitting diode according to claim 1, wherein the second compound is be represented by Formula 3-1 or Formula 3-2: 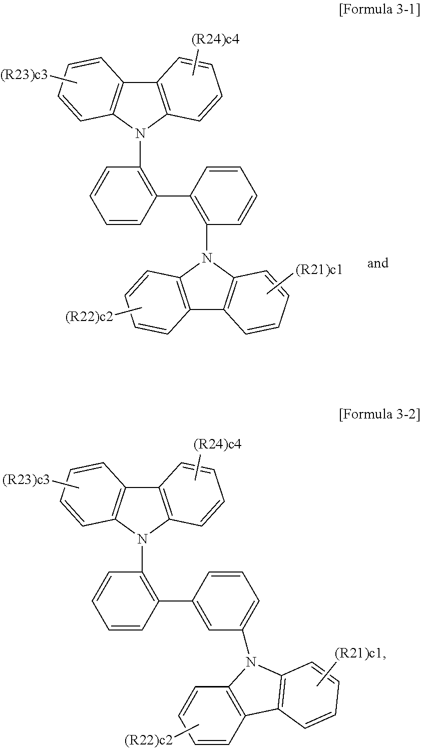
wherein in each of the Formulas 3-1 and 3-2,
each of c1, c2, c3 and c4 is independently an integer of 0 to 4, and
each of R21, R22, R23 and R24 is independently selected from the group consisting of deuterium, halogen, cyano, a substituted or unsubstituted C1 to C20 alkyl group, a substituted or unsubstituted C1 to C20 alkoxy group, a substituted or unsubstituted C1 to C20 alkylamino group, a substituted or unsubstituted C6 to C30 arylamino group, a substituted or unsubstituted C6 to C30 arylsilyl group, a substituted or unsubstituted C6 to C30 aryl group and a substituted or unsubstituted C3 to C30 heteroaryl group.

5. The organic light emitting diode according to claim 4, wherein the second compound is one of compounds in Formula 4:

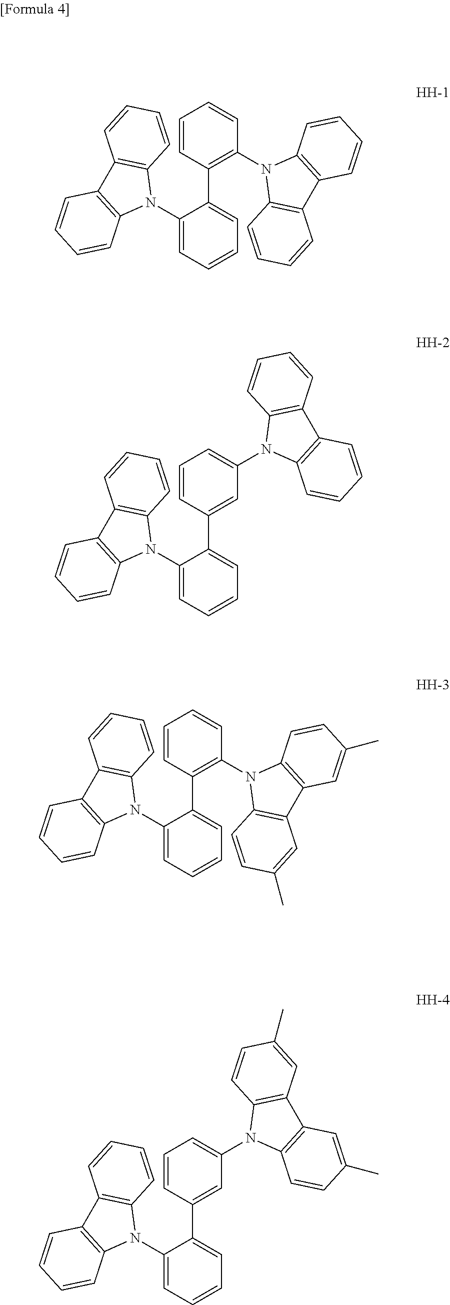 [SMILES: c1ccc(-n2c3ccccc3c3ccccc32)c(-c2ccccc2-n2c3ccccc3c3ccccc32)c1 ; c1cc(-c2ccccc2-n2c3ccccc3c3ccccc32)cc(-n2c3ccccc3c3ccccc32)c1 ; Cc1ccc2c(c1)c1cc(C)ccc1n2-c1ccccc1-c1ccccc1-n1c2ccccc2c2ccccc21 ; Cc1ccc2c(c1)c1cc(C)ccc1n2-c1cccc(-c2ccccc2-n2c3ccccc3c3ccccc32)c1]

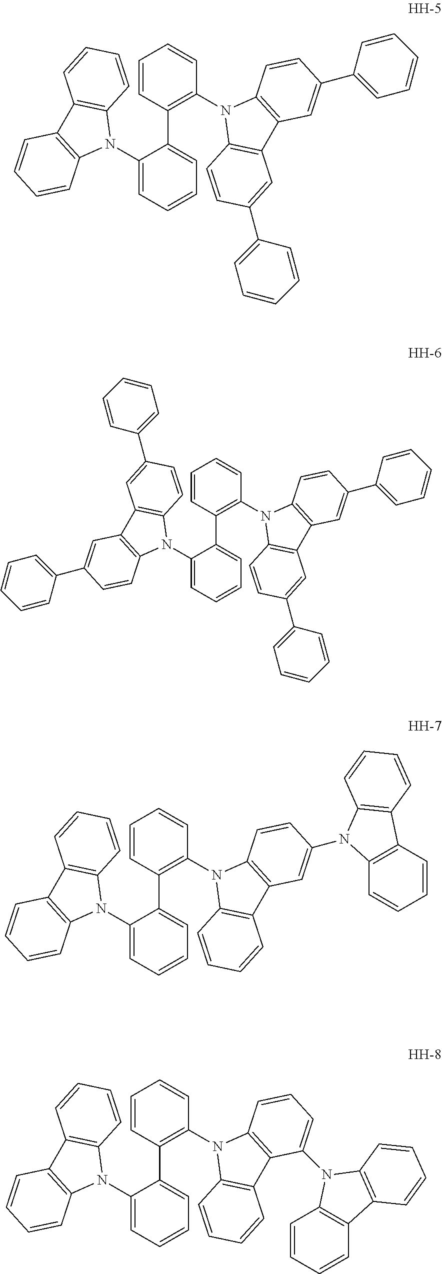 [SMILES: c1ccc(-c2ccc3c(c2)c2cc(-c4ccccc4)ccc2n3-c2ccccc2-c2ccccc2-n2c3ccccc3c3ccccc32)cc1 ; c1ccc(-c2ccc3c(c2)c2cc(-c4ccccc4)ccc2n3-c2ccccc2-c2ccccc2-n2c3ccc(-c4ccccc4)cc3c3cc(-c4ccccc4)ccc32)cc1 ; c1ccc(-n2c3ccccc3c3ccccc32)c(-c2ccccc2-n2c3ccccc3c3cc(-n4c5ccccc5c5ccccc54)ccc32)c1 ; c1ccc(-n2c3ccccc3c3ccccc32)c(-c2ccccc2-n2c3ccccc3c3c(-n4c5ccccc5c5ccccc54)cccc32)c1]

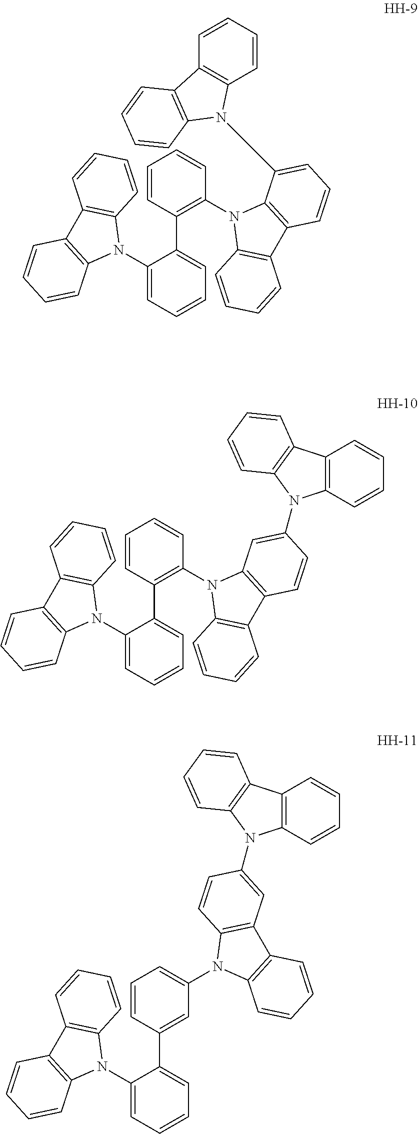 [SMILES: c1ccc(-n2c3ccccc3c3ccccc32)c(-c2ccccc2-n2c3ccccc3c3cccc(-n4c5ccccc5c5ccccc54)c32)c1 ; c1ccc(-n2c3ccccc3c3ccccc32)c(-c2ccccc2-n2c3ccccc3c3ccc(-n4c5ccccc5c5ccccc54)cc32)c1 ; c1cc(-c2ccccc2-n2c3ccccc3c3ccccc32)cc(-n2c3ccccc3c3cc(-n4c5ccccc5c5ccccc54)ccc32)c1]

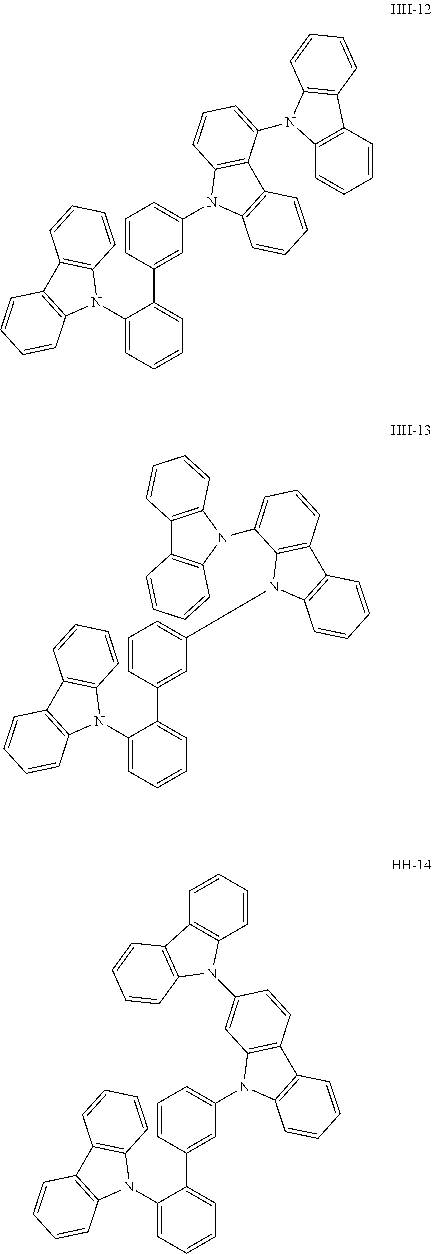 [SMILES: c1cc(-c2ccccc2-n2c3ccccc3c3ccccc32)cc(-n2c3ccccc3c3c(-n4c5ccccc5c5ccccc54)cccc32)c1 ; c1cc(-c2ccccc2-n2c3ccccc3c3ccccc32)cc(-n2c3ccccc3c3cccc(-n4c5ccccc5c5ccccc54)c32)c1 ; c1cc(-c2ccccc2-n2c3ccccc3c3ccccc32)cc(-n2c3ccccc3c3ccc(-n4c5ccccc5c5ccccc54)cc32)c1]

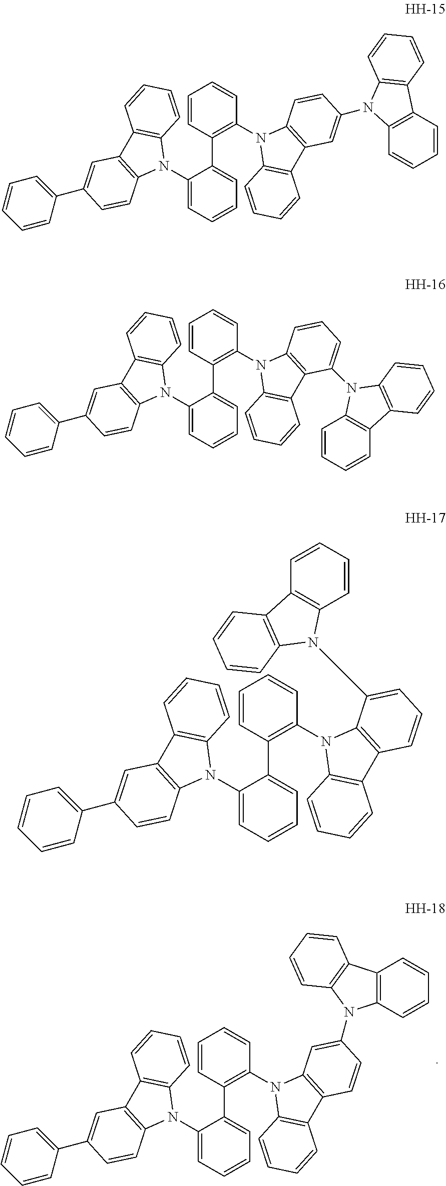 [SMILES: c1ccc(-c2ccc3c(c2)c2ccccc2n3-c2ccccc2-c2ccccc2-n2c3ccccc3c3cc(-n4c5ccccc5c5ccccc54)ccc32)cc1 ; c1ccc(-c2ccc3c(c2)c2ccccc2n3-c2ccccc2-c2ccccc2-n2c3ccccc3c3c(-n4c5ccccc5c5ccccc54)cccc32)cc1 ; c1ccc(-c2ccc3c(c2)c2ccccc2n3-c2ccccc2-c2ccccc2-n2c3ccccc3c3cccc(-n4c5ccccc5c5ccccc54)c32)cc1 ; c1ccc(-c2ccc3c(c2)c2ccccc2n3-c2ccccc2-c2ccccc2-n2c3ccccc3c3ccc(-n4c5ccccc5c5ccccc54)cc32)cc1]

6. The organic light emitting diode according to claim 1, wherein the third compound is one of compounds in Formula 6:

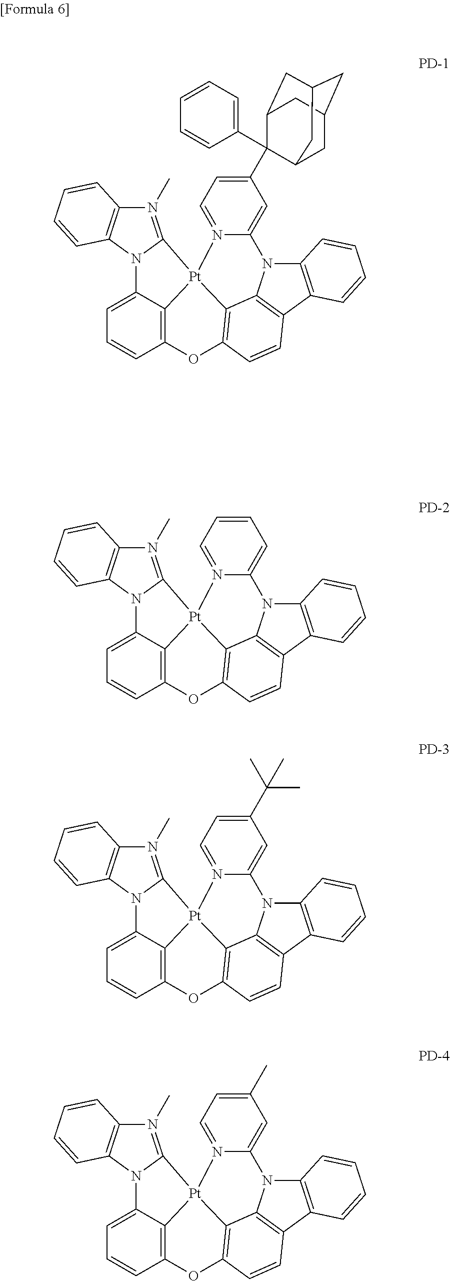

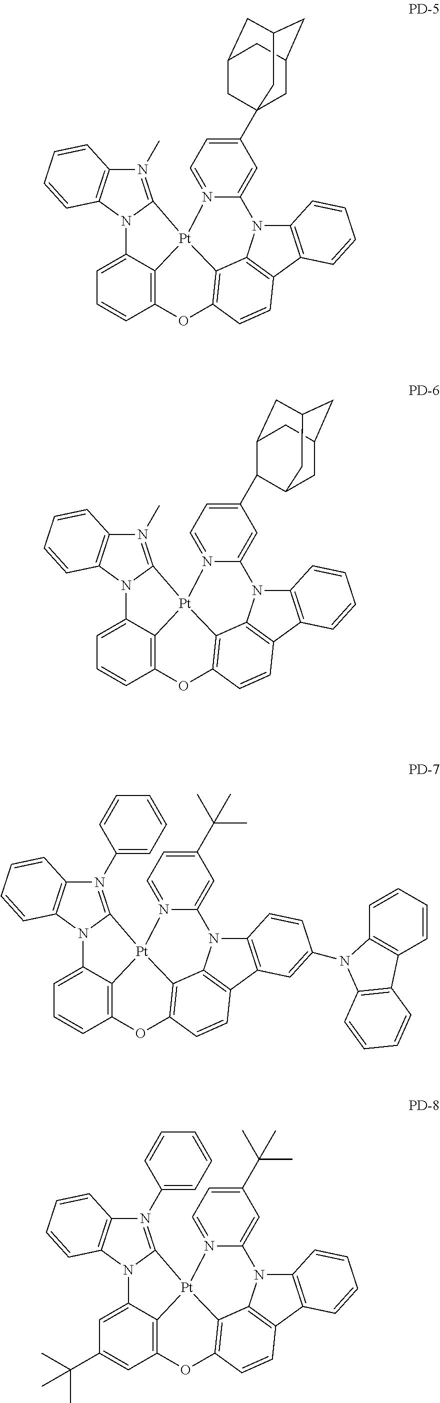

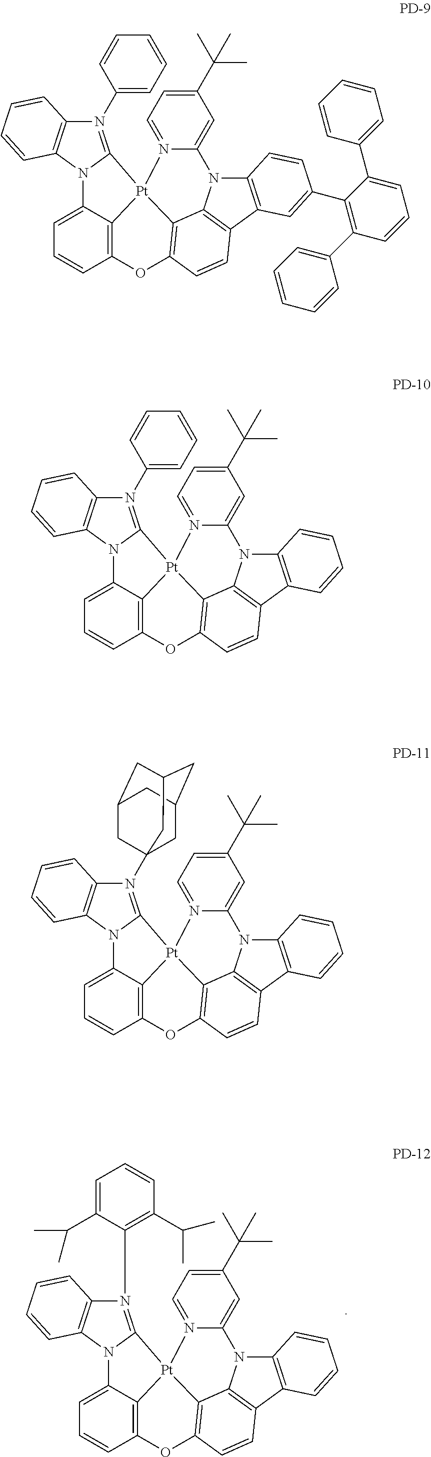

7. The organic light emitting diode according to claim 1, wherein a LUMO energy level of the first compound is higher than a LUMO energy level of the third compound.

8. The organic light emitting diode according to claim 7, wherein the LUMO energy level of the first compound is lower than a LUMO energy level of the second compound.

9. The organic light emitting diode according to claim 1, further comprising:
a second blue emitting material layer between the first blue emitting material layer and the second electrode,
wherein the second blue emitting material layer includes a host and a fluorescent dopant.

10. The organic light emitting diode according to claim 9, further comprising:
an emitting material layer positioned between the first and second blue emitting material layers and including one or more of a red emitting material layer, a yellow-green emitting material layer and a green emitting material layer.

11. The organic light emitting diode according to claim 1, further comprising:
a second blue emitting material layer between the first blue emitting material layer and the second electrode,
wherein the second blue emitting material layer includes a fourth compound represented by the Formula 1, a fifth compound represented by the Formula 3 and a sixth compound represented by the Formula 5.

12. The organic light emitting diode according to claim 11, wherein in the second blue emitting material layer, a summation of a weight % of the fourth compound, a weight % of the fifth compound and a weight % of the sixth compound is 100%.

13. The organic light emitting diode according to claim 12, wherein the weight % of each of the fourth compound and the fifth compound is greater than the weight % of the sixth compound.

14. The organic light emitting diode according to claim 11, wherein a LUMO energy level of the fourth compound is higher than a LUMO energy level of the sixth compound, and the LUMO energy level of the fourth compound is lower than a LUMO energy level of the fifth compound.

15. An organic light emitting device, comprising:
a substrate;
an organic light emitting diode of claim 1 disposed over the substrate; and
an encapsulation layer covering the organic light emitting diode.

16. The organic light emitting device according to claim 15, wherein the substrate includes a red pixel region, a green pixel region and a blue pixel region, and the organic light emitting diode corresponds to the red, green and blue pixel regions, and
wherein the organic light emitting device further comprises a color conversion layer corresponding to the red, green and blue pixel regions.

17. The organic light emitting device according to claim 15, wherein the substrate includes a red pixel region, a green pixel region and a blue pixel region, and the organic light emitting diode corresponds to the red, green and blue pixel regions, and
wherein the organic light emitting device further comprises a color filter layer corresponding to the red, green and blue pixel regions.

18. The organic light emitting device according to claim 15, wherein the first compound is one of compounds in Formula 2:

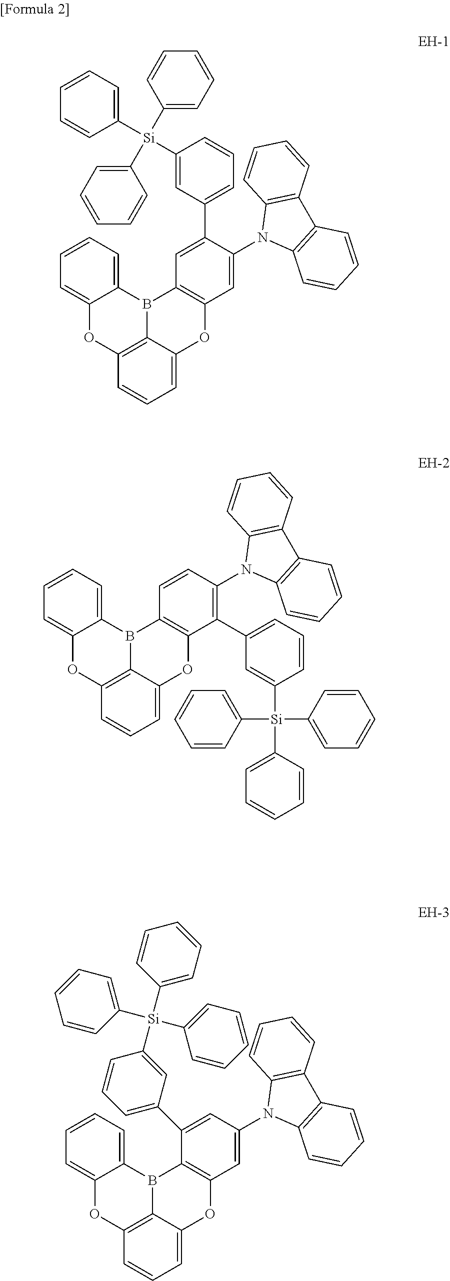 [SMILES: c1ccc([Si](c2ccccc2)(c2ccccc2)c2cccc(-c3cc4c(cc3-n3c5ccccc5c5ccccc53)Oc3cccc5c3B4c3ccccc3O5)c2)cc1 ; c1ccc([Si](c2ccccc2)(c2ccccc2)c2cccc(-c3c(-n4c5ccccc5c5ccccc54)ccc4c3Oc3cccc5c3B4c3ccccc3O5)c2)cc1 ; c1ccc([Si](c2ccccc2)(c2ccccc2)c2cccc(-c3cc(-n4c5ccccc5c5ccccc54)cc4c3B3c5ccccc5Oc5cccc(c53)O4)c2)cc1]

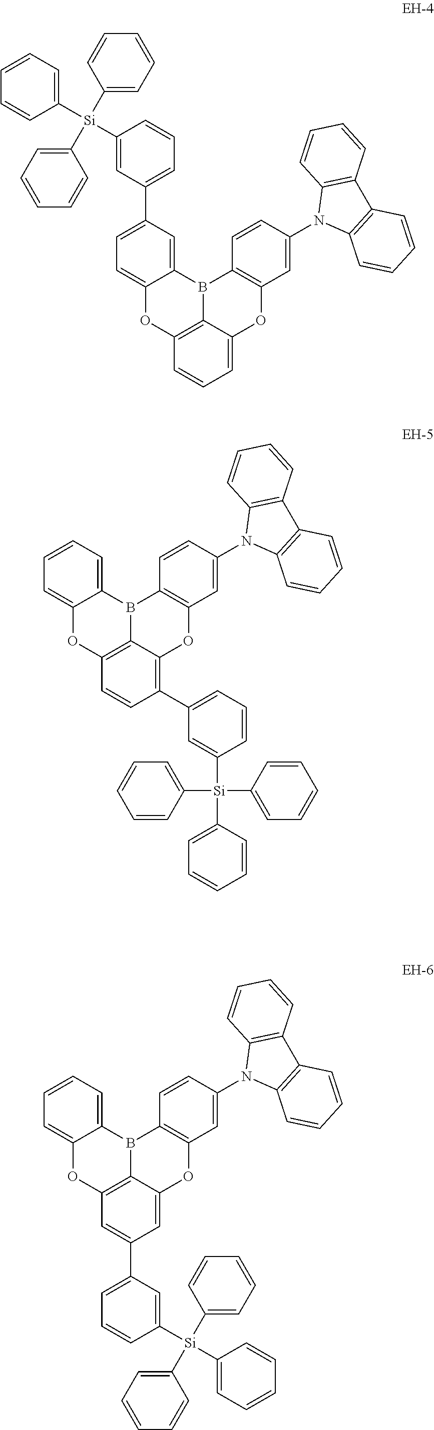 [SMILES: c1ccc([Si](c2ccccc2)(c2ccccc2)c2cccc(-c3ccc4c(c3)B3c5ccc(-n6c7ccccc7c7ccccc76)cc5Oc5cccc(c53)O4)c2)cc1 ; c1ccc([Si](c2ccccc2)(c2ccccc2)c2cccc(-c3ccc4c5c3Oc3cc(-n6c7ccccc7c7ccccc76)ccc3B5c3ccccc3O4)c2)cc1 ; c1ccc([Si](c2ccccc2)(c2ccccc2)c2cccc(-c3cc4c5c(c3)Oc3cc(-n6c7ccccc7c7ccccc76)ccc3B5c3ccccc3O4)c2)cc1]

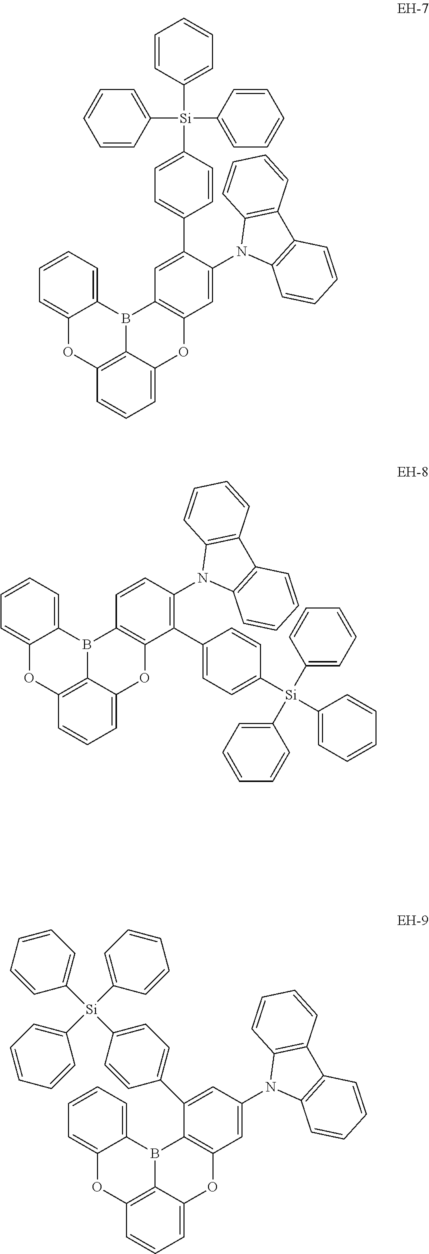 [SMILES: c1ccc([Si](c2ccccc2)(c2ccccc2)c2ccc(-c3cc4c(cc3-n3c5ccccc5c5ccccc53)Oc3cccc5c3B4c3ccccc3O5)cc2)cc1 ; c1ccc([Si](c2ccccc2)(c2ccccc2)c2ccc(-c3c(-n4c5ccccc5c5ccccc54)ccc4c3Oc3cccc5c3B4c3ccccc3O5)cc2)cc1 ; c1ccc([Si](c2ccccc2)(c2ccccc2)c2ccc(-c3cc(-n4c5ccccc5c5ccccc54)cc4c3B3c5ccccc5Oc5cccc(c53)O4)cc2)cc1]

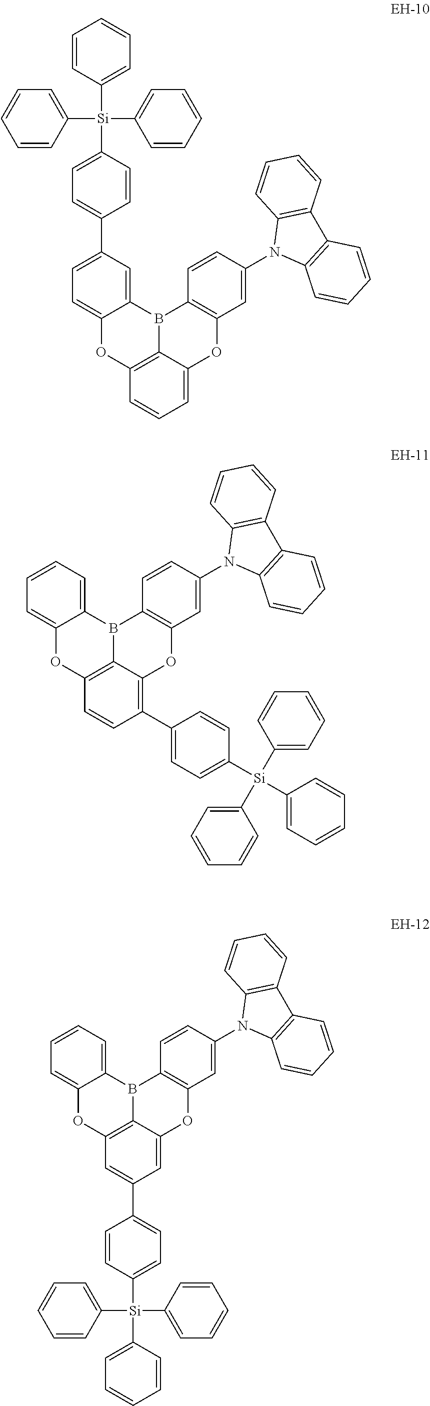 [SMILES: c1ccc([Si](c2ccccc2)(c2ccccc2)c2ccc(-c3ccc4c(c3)B3c5ccc(-n6c7ccccc7c7ccccc76)cc5Oc5cccc(c53)O4)cc2)cc1 ; c1ccc([Si](c2ccccc2)(c2ccccc2)c2ccc(-c3ccc4c5c3Oc3cc(-n6c7ccccc7c7ccccc76)ccc3B5c3ccccc3O4)cc2)cc1 ; c1ccc([Si](c2ccccc2)(c2ccccc2)c2ccc(-c3cc4c5c(c3)Oc3cc(-n6c7ccccc7c7ccccc76)ccc3B5c3ccccc3O4)cc2)cc1]

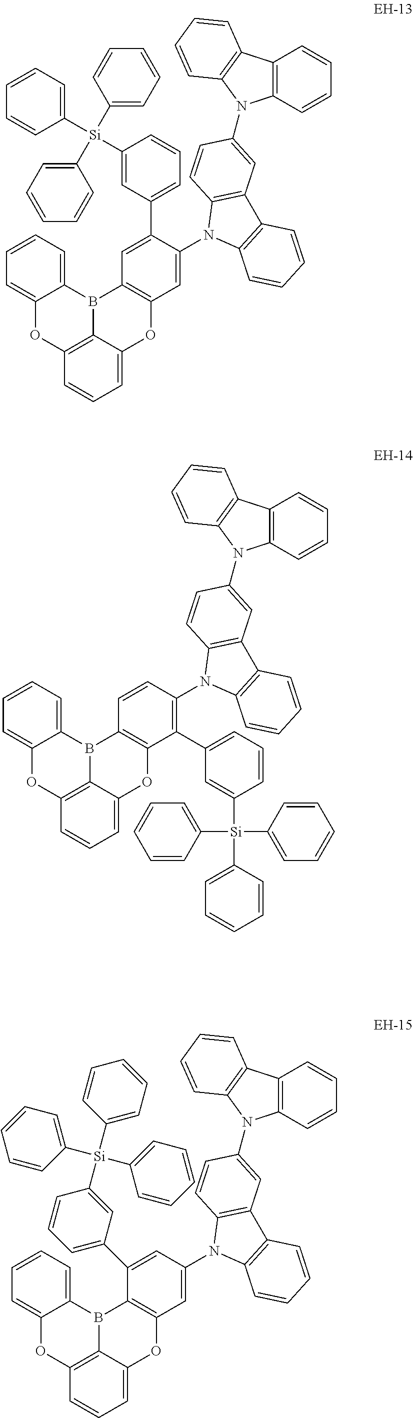 [SMILES: c1ccc([Si](c2ccccc2)(c2ccccc2)c2cccc(-c3cc4c(cc3-n3c5ccccc5c5cc(-n6c7ccccc7c7ccccc76)ccc53)Oc3cccc5c3B4c3ccccc3O5)c2)cc1 ; c1ccc([Si](c2ccccc2)(c2ccccc2)c2cccc(-c3c(-n4c5ccccc5c5cc(-n6c7ccccc7c7ccccc76)ccc54)ccc4c3Oc3cccc5c3B4c3ccccc3O5)c2)cc1 ; c1ccc([Si](c2ccccc2)(c2ccccc2)c2cccc(-c3cc(-n4c5ccccc5c5cc(-n6c7ccccc7c7ccccc76)ccc54)cc4c3B3c5ccccc5Oc5cccc(c53)O4)c2)cc1]

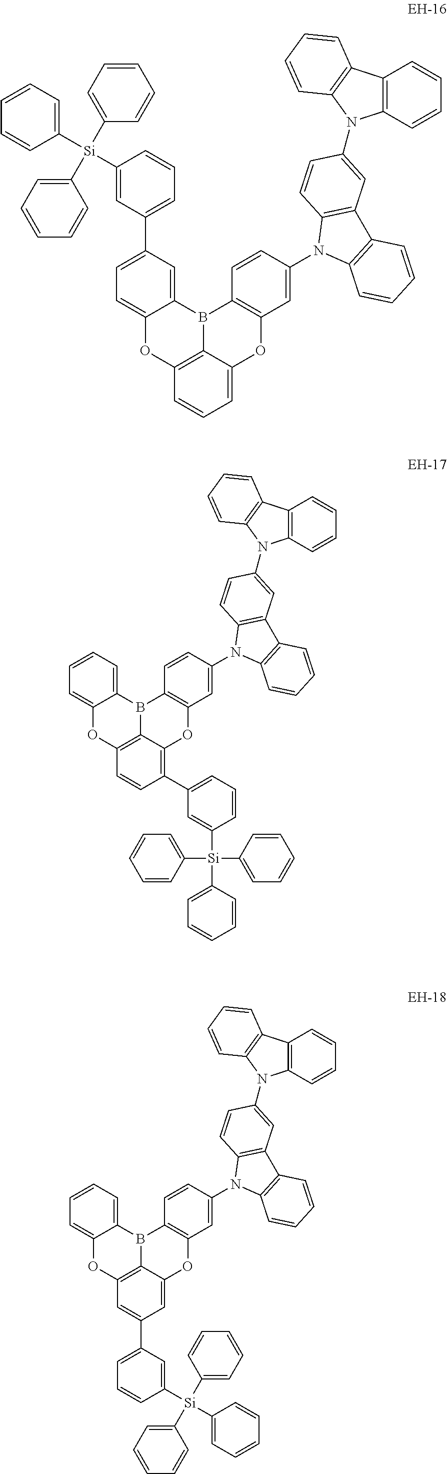 [SMILES: c1ccc([Si](c2ccccc2)(c2ccccc2)c2cccc(-c3ccc4c(c3)B3c5ccc(-n6c7ccccc7c7cc(-n8c9ccccc9c9ccccc98)ccc76)cc5Oc5cccc(c53)O4)c2)cc1 ; c1ccc([Si](c2ccccc2)(c2ccccc2)c2cccc(-c3ccc4c5c3Oc3cc(-n6c7ccccc7c7cc(-n8c9ccccc9c9ccccc98)ccc76)ccc3B5c3ccccc3O4)c2)cc1 ; c1ccc([Si](c2ccccc2)(c2ccccc2)c2cccc(-c3cc4c5c(c3)Oc3cc(-n6c7ccccc7c7cc(-n8c9ccccc9c9ccccc98)ccc76)ccc3B5c3ccccc3O4)c2)cc1]

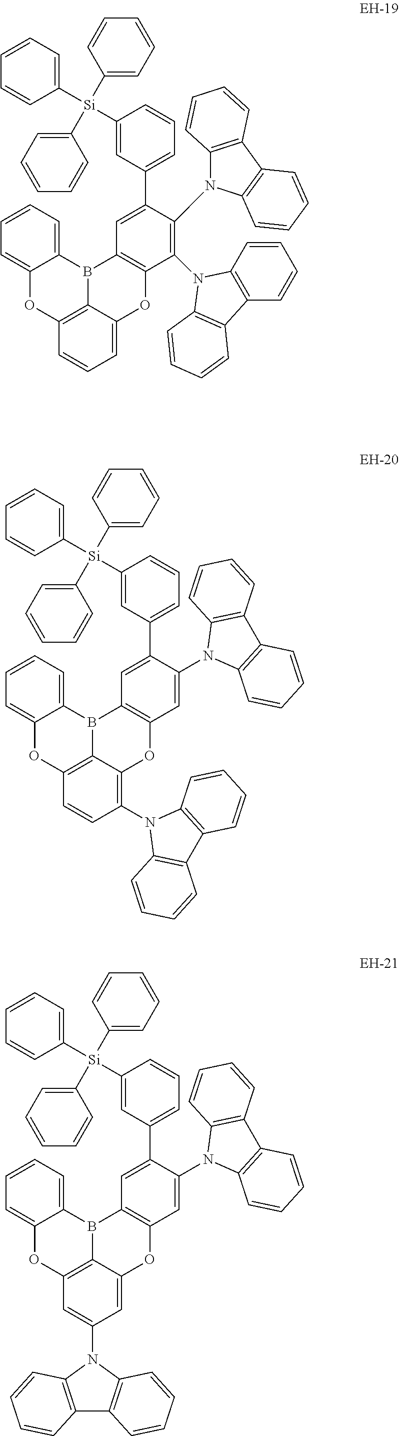 [SMILES: c1ccc([Si](c2ccccc2)(c2ccccc2)c2cccc(-c3cc4c(c(-n5c6ccccc6c6ccccc65)c3-n3c5ccccc5c5ccccc53)Oc3cccc5c3B4c3ccccc3O5)c2)cc1 ; c1ccc([Si](c2ccccc2)(c2ccccc2)c2cccc(-c3cc4c(cc3-n3c5ccccc5c5ccccc53)Oc3c(-n5c6ccccc6c6ccccc65)ccc5c3B4c3ccccc3O5)c2)cc1 ; c1ccc([Si](c2ccccc2)(c2ccccc2)c2cccc(-c3cc4c(cc3-n3c5ccccc5c5ccccc53)Oc3cc(-n5c6ccccc6c6ccccc65)cc5c3B4c3ccccc3O5)c2)cc1]

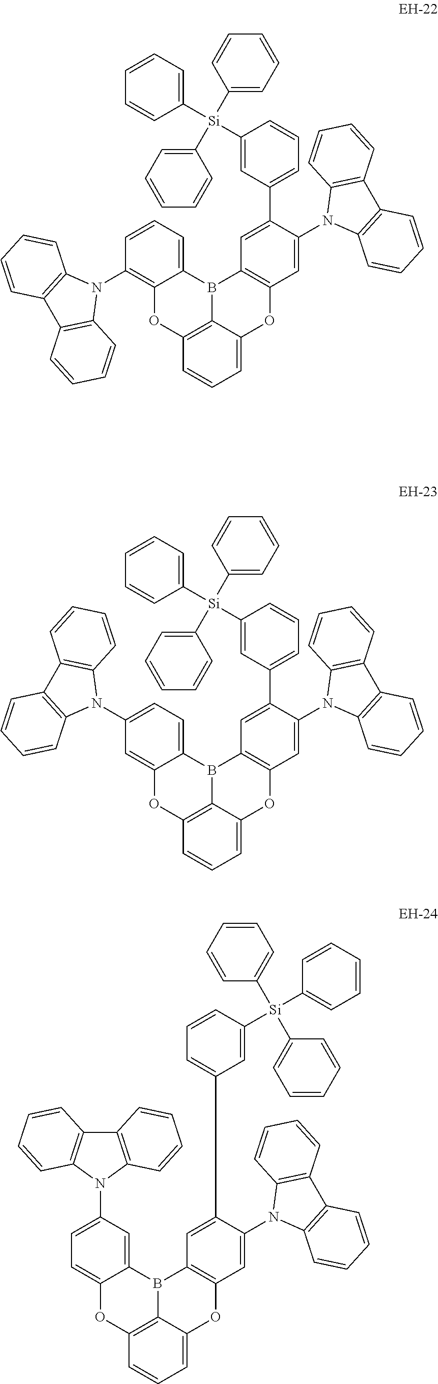 [SMILES: c1ccc([Si](c2ccccc2)(c2ccccc2)c2cccc(-c3cc4c(cc3-n3c5ccccc5c5ccccc53)Oc3cccc5c3B4c3cccc(-n4c6ccccc6c6ccccc64)c3O5)c2)cc1 ; c1ccc([Si](c2ccccc2)(c2ccccc2)c2cccc(-c3cc4c(cc3-n3c5ccccc5c5ccccc53)Oc3cccc5c3B4c3ccc(-n4c6ccccc6c6ccccc64)cc3O5)c2)cc1 ; c1ccc([Si](c2ccccc2)(c2ccccc2)c2cccc(-c3cc4c(cc3-n3c5ccccc5c5ccccc53)Oc3cccc5c3B4c3cc(-n4c6ccccc6c6ccccc64)ccc3O5)c2)cc1]

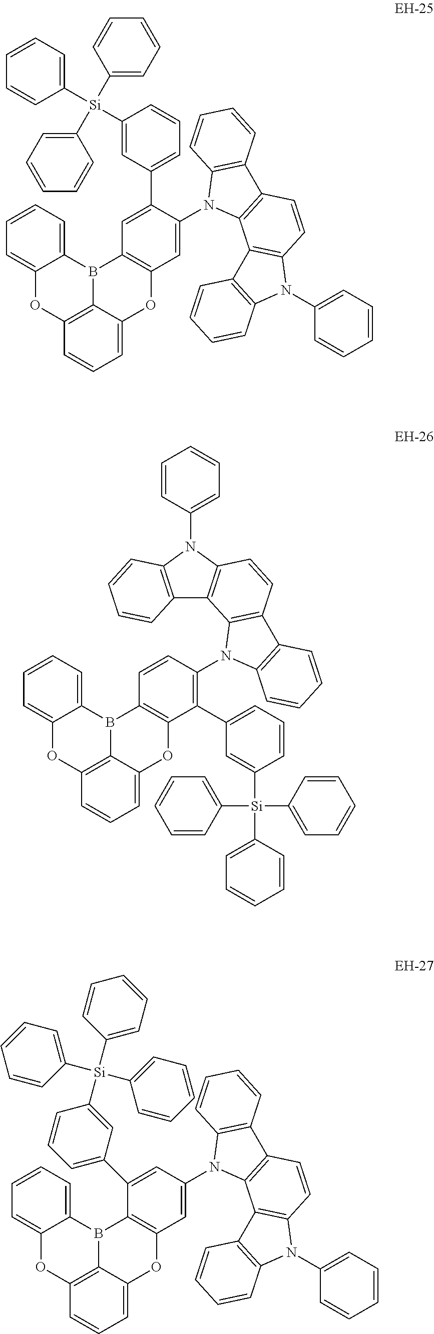 [SMILES: c1ccc(-n2c3ccccc3c3c2ccc2c4ccccc4n(-c4cc5c(cc4-c4cccc([Si](c6ccccc6)(c6ccccc6)c6ccccc6)c4)B4c6ccccc6Oc6cccc(c64)O5)c23)cc1 ; c1ccc(-n2c3ccccc3c3c2ccc2c4ccccc4n(-c4ccc5c(c4-c4cccc([Si](c6ccccc6)(c6ccccc6)c6ccccc6)c4)Oc4cccc6c4B5c4ccccc4O6)c23)cc1 ; c1ccc(-n2c3ccccc3c3c2ccc2c4ccccc4n(-c4cc5c(c(-c6cccc([Si](c7ccccc7)(c7ccccc7)c7ccccc7)c6)c4)B4c6ccccc6Oc6cccc(c64)O5)c23)cc1]

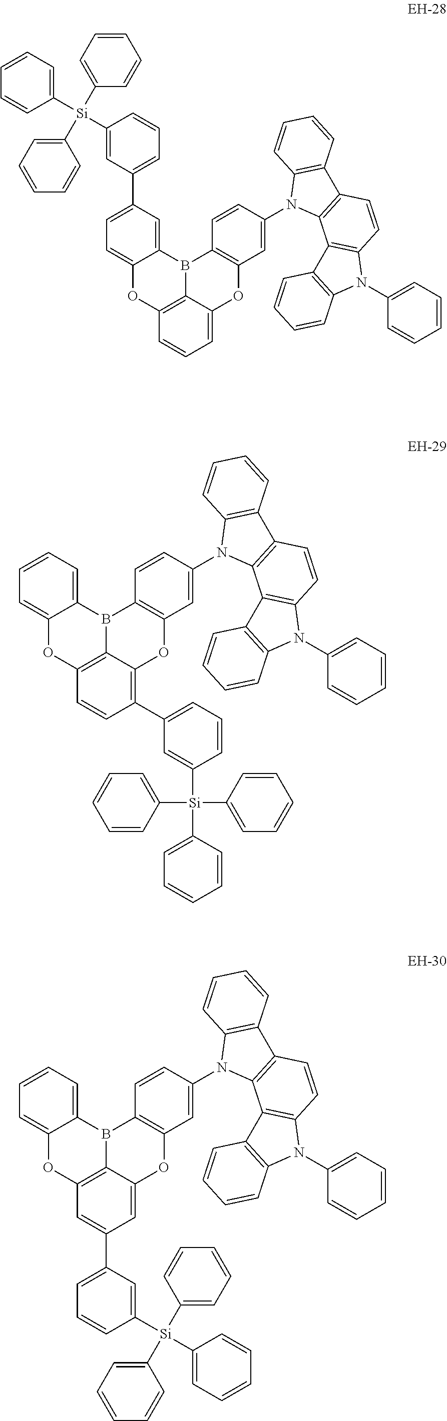 [SMILES: c1ccc(-n2c3ccccc3c3c2ccc2c4ccccc4n(-c4ccc5c(c4)Oc4cccc6c4B5c4cc(-c5cccc([Si](c7ccccc7)(c7ccccc7)c7ccccc7)c5)ccc4O6)c23)cc1 ; c1ccc(-n2c3ccccc3c3c2ccc2c4ccccc4n(-c4ccc5c(c4)Oc4c(-c6cccc([Si](c7ccccc7)(c7ccccc7)c7ccccc7)c6)ccc6c4B5c4ccccc4O6)c23)cc1 ; c1ccc(-n2c3ccccc3c3c2ccc2c4ccccc4n(-c4ccc5c(c4)Oc4cc(-c6cccc([Si](c7ccccc7)(c7ccccc7)c7ccccc7)c6)cc6c4B5c4ccccc4O6)c23)cc1]

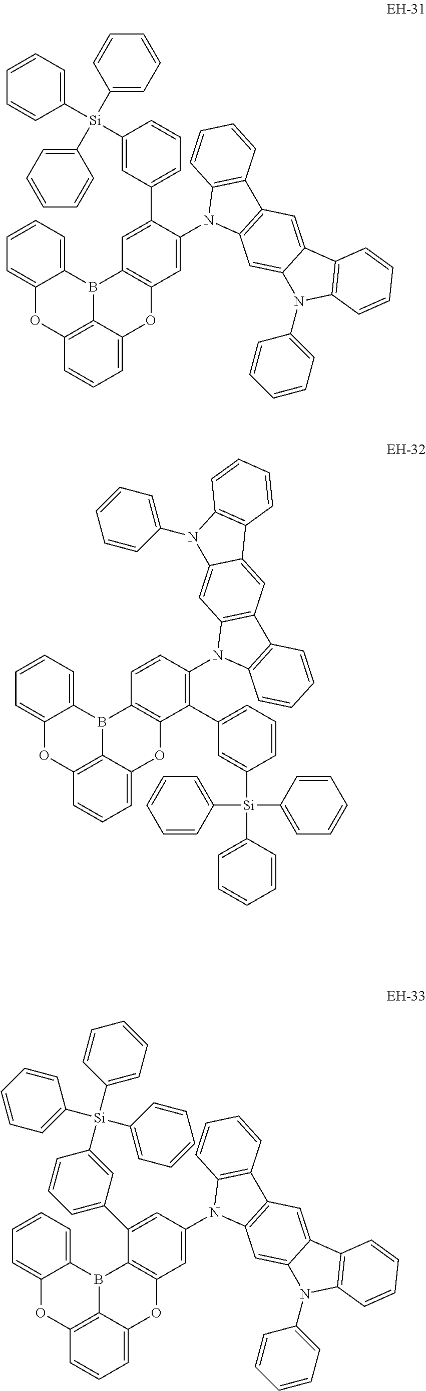 [SMILES: c1ccc(-n2c3ccccc3c3cc4c5ccccc5n(-c5cc6c(cc5-c5cccc([Si](c7ccccc7)(c7ccccc7)c7ccccc7)c5)B5c7ccccc7Oc7cccc(c75)O6)c4cc32)cc1 ; c1ccc(-n2c3ccccc3c3cc4c5ccccc5n(-c5ccc6c(c5-c5cccc([Si](c7ccccc7)(c7ccccc7)c7ccccc7)c5)Oc5cccc7c5B6c5ccccc5O7)c4cc32)cc1 ; c1ccc(-n2c3ccccc3c3cc4c5ccccc5n(-c5cc6c(c(-c7cccc([Si](c8ccccc8)(c8ccccc8)c8ccccc8)c7)c5)B5c7ccccc7Oc7cccc(c75)O6)c4cc32)cc1]

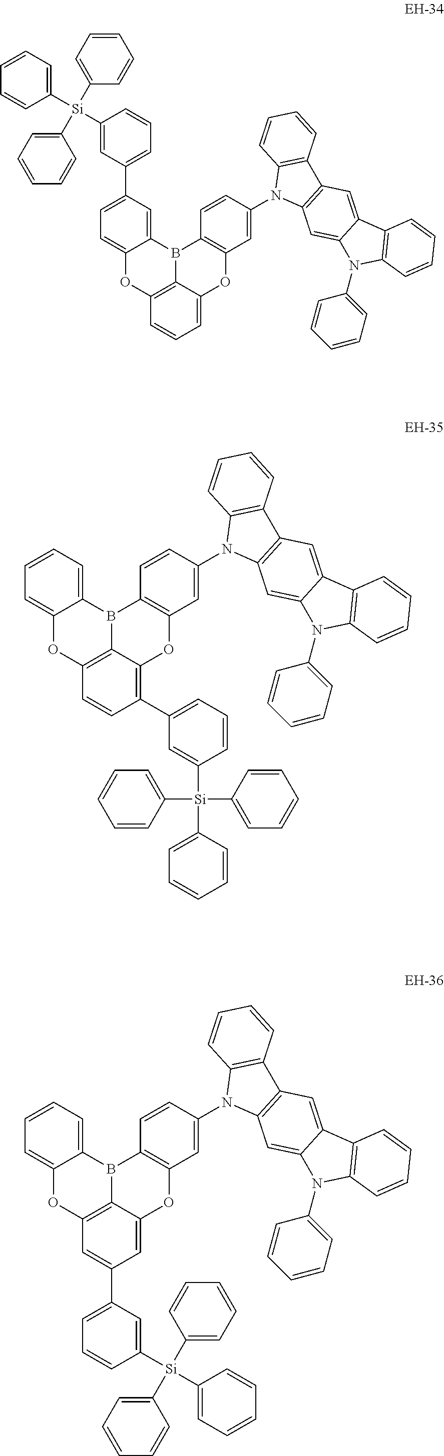 [SMILES: c1ccc(-n2c3ccccc3c3cc4c5ccccc5n(-c5ccc6c(c5)Oc5cccc7c5B6c5cc(-c6cccc([Si](c8ccccc8)(c8ccccc8)c8ccccc8)c6)ccc5O7)c4cc32)cc1 ; c1ccc(-n2c3ccccc3c3cc4c5ccccc5n(-c5ccc6c(c5)Oc5c(-c7cccc([Si](c8ccccc8)(c8ccccc8)c8ccccc8)c7)ccc7c5B6c5ccccc5O7)c4cc32)cc1 ; c1ccc(-n2c3ccccc3c3cc4c5ccccc5n(-c5ccc6c(c5)Oc5cc(-c7cccc([Si](c8ccccc8)(c8ccccc8)c8ccccc8)c7)cc7c5B6c5ccccc5O7)c4cc32)cc1]

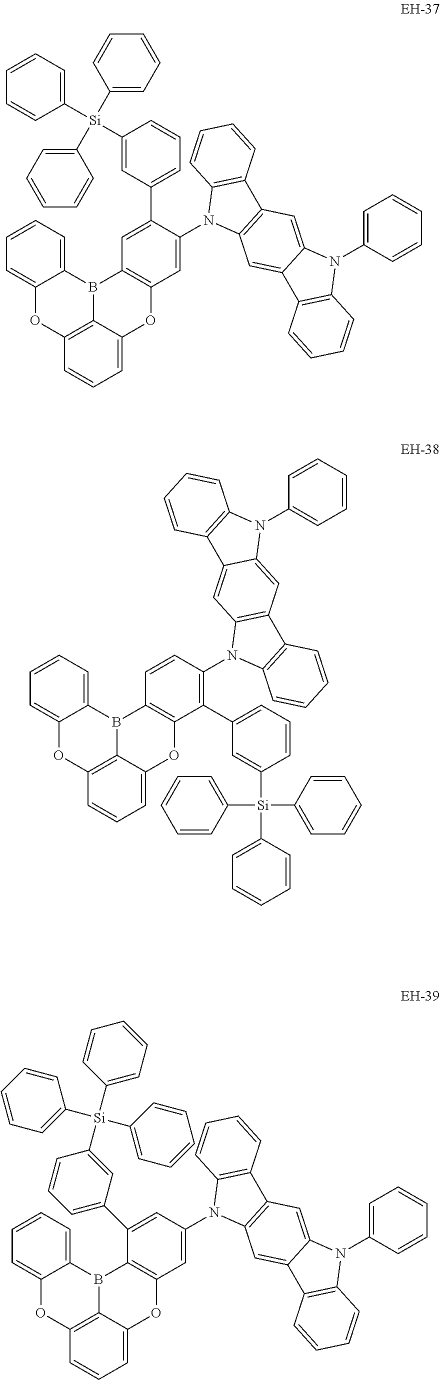 [SMILES: c1ccc(-n2c3ccccc3c3cc4c(cc32)c2ccccc2n4-c2cc3c(cc2-c2cccc([Si](c4ccccc4)(c4ccccc4)c4ccccc4)c2)B2c4ccccc4Oc4cccc(c42)O3)cc1 ; c1ccc(-n2c3ccccc3c3cc4c(cc32)c2ccccc2n4-c2ccc3c(c2-c2cccc([Si](c4ccccc4)(c4ccccc4)c4ccccc4)c2)Oc2cccc4c2B3c2ccccc2O4)cc1 ; c1ccc(-n2c3ccccc3c3cc4c(cc32)c2ccccc2n4-c2cc3c(c(-c4cccc([Si](c5ccccc5)(c5ccccc5)c5ccccc5)c4)c2)B2c4ccccc4Oc4cccc(c42)O3)cc1]

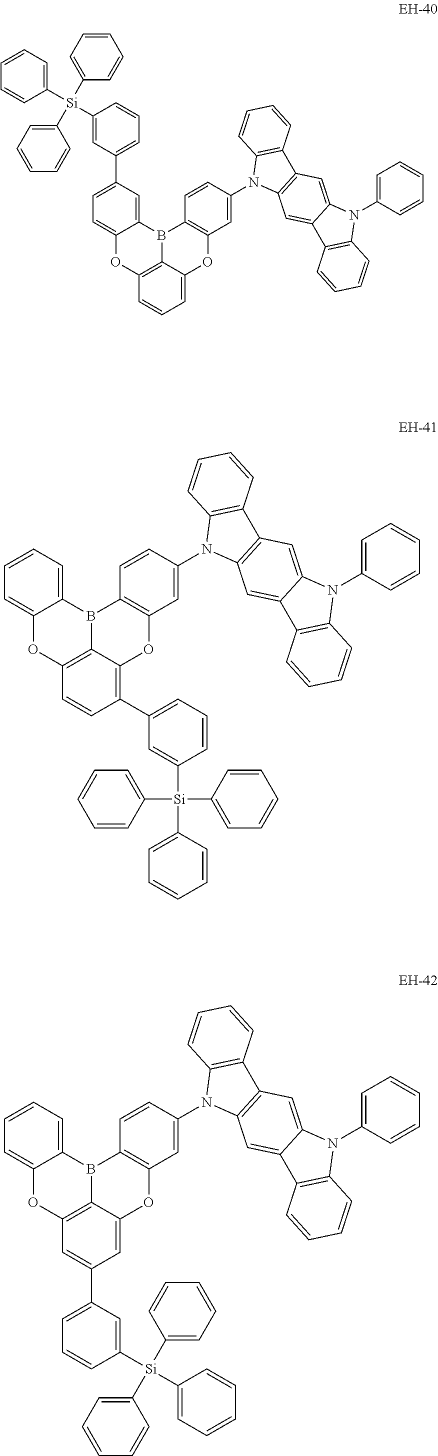 [SMILES: c1ccc(-n2c3ccccc3c3cc4c(cc32)c2ccccc2n4-c2ccc3c(c2)Oc2cccc4c2B3c2cc(-c3cccc([Si](c5ccccc5)(c5ccccc5)c5ccccc5)c3)ccc2O4)cc1 ; c1ccc(-n2c3ccccc3c3cc4c(cc32)c2ccccc2n4-c2ccc3c(c2)Oc2c(-c4cccc([Si](c5ccccc5)(c5ccccc5)c5ccccc5)c4)ccc4c2B3c2ccccc2O4)cc1 ; c1ccc(-n2c3ccccc3c3cc4c(cc32)c2ccccc2n4-c2ccc3c(c2)Oc2cc(-c4cccc([Si](c5ccccc5)(c5ccccc5)c5ccccc5)c4)cc4c2B3c2ccccc2O4)cc1]

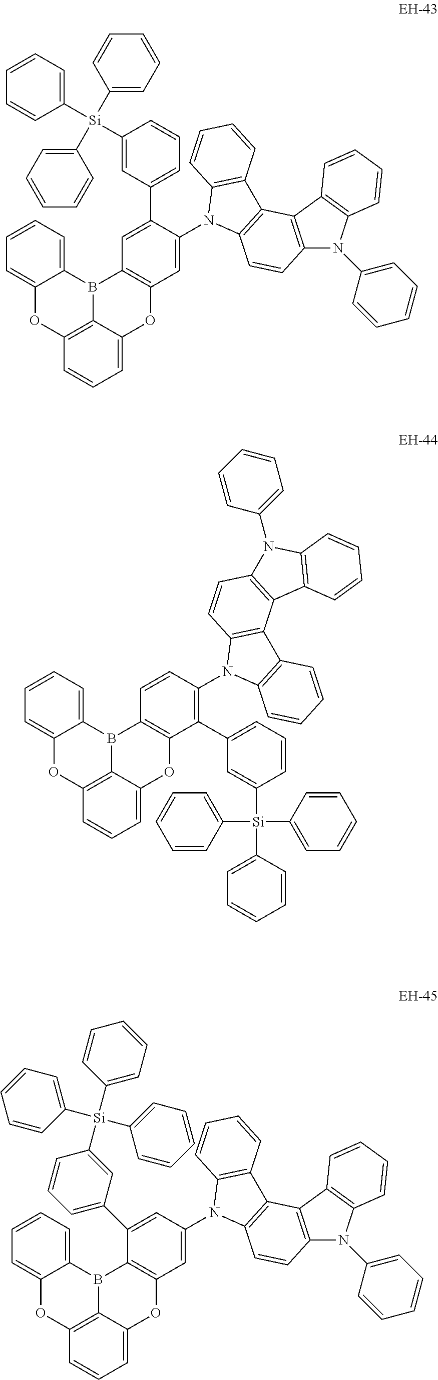 [SMILES: c1ccc(-n2c3ccccc3c3c4c5ccccc5n(-c5cc6c(cc5-c5cccc([Si](c7ccccc7)(c7ccccc7)c7ccccc7)c5)B5c7ccccc7Oc7cccc(c75)O6)c4ccc32)cc1 ; c1ccc(-n2c3ccccc3c3c4c5ccccc5n(-c5ccc6c(c5-c5cccc([Si](c7ccccc7)(c7ccccc7)c7ccccc7)c5)Oc5cccc7c5B6c5ccccc5O7)c4ccc32)cc1 ; c1ccc(-n2c3ccccc3c3c4c5ccccc5n(-c5cc6c(c(-c7cccc([Si](c8ccccc8)(c8ccccc8)c8ccccc8)c7)c5)B5c7ccccc7Oc7cccc(c75)O6)c4ccc32)cc1]

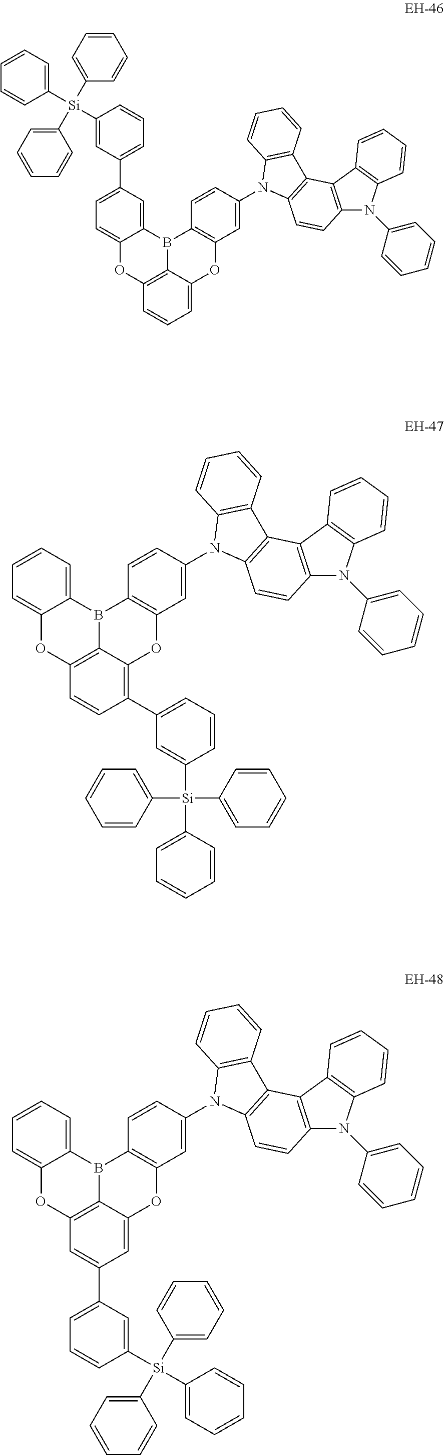 [SMILES: c1ccc(-n2c3ccccc3c3c4c5ccccc5n(-c5ccc6c(c5)Oc5cccc7c5B6c5cc(-c6cccc([Si](c8ccccc8)(c8ccccc8)c8ccccc8)c6)ccc5O7)c4ccc32)cc1 ; c1ccc(-n2c3ccccc3c3c4c5ccccc5n(-c5ccc6c(c5)Oc5c(-c7cccc([Si](c8ccccc8)(c8ccccc8)c8ccccc8)c7)ccc7c5B6c5ccccc5O7)c4ccc32)cc1 ; c1ccc(-n2c3ccccc3c3c4c5ccccc5n(-c5ccc6c(c5)Oc5cc(-c7cccc([Si](c8ccccc8)(c8ccccc8)c8ccccc8)c7)cc7c5B6c5ccccc5O7)c4ccc32)cc1]

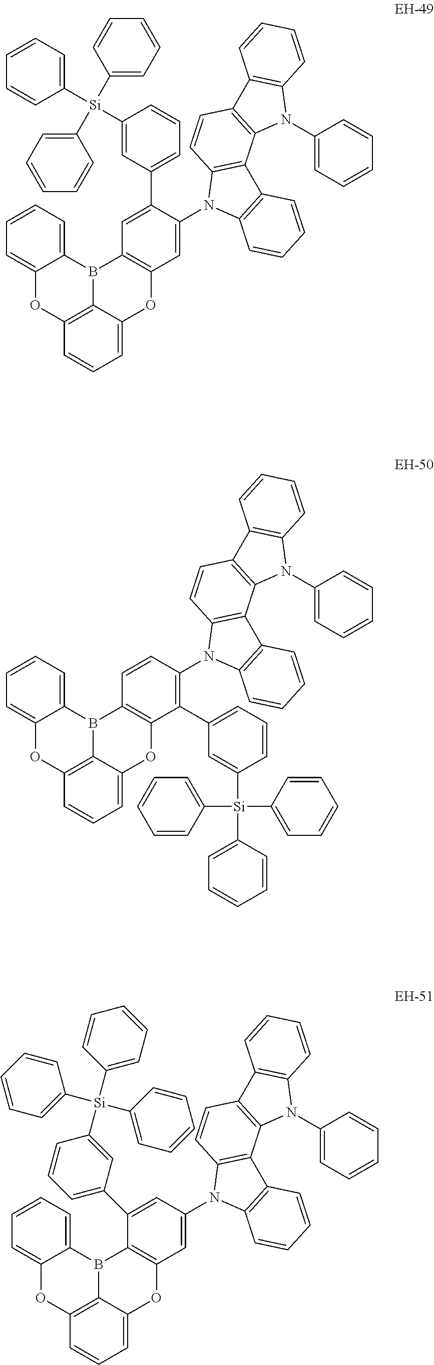 [SMILES: c1ccc(-n2c3ccccc3c3ccc4c(c5ccccc5n4-c4cc5c(cc4-c4cccc([Si](c6ccccc6)(c6ccccc6)c6ccccc6)c4)B4c6ccccc6Oc6cccc(c64)O5)c32)cc1 ; c1ccc(-n2c3ccccc3c3ccc4c(c5ccccc5n4-c4ccc5c(c4-c4cccc([Si](c6ccccc6)(c6ccccc6)c6ccccc6)c4)Oc4cccc6c4B5c4ccccc4O6)c32)cc1 ; c1ccc(-n2c3ccccc3c3ccc4c(c5ccccc5n4-c4cc5c(c(-c6cccc([Si](c7ccccc7)(c7ccccc7)c7ccccc7)c6)c4)B4c6ccccc6Oc6cccc(c64)O5)c32)cc1]

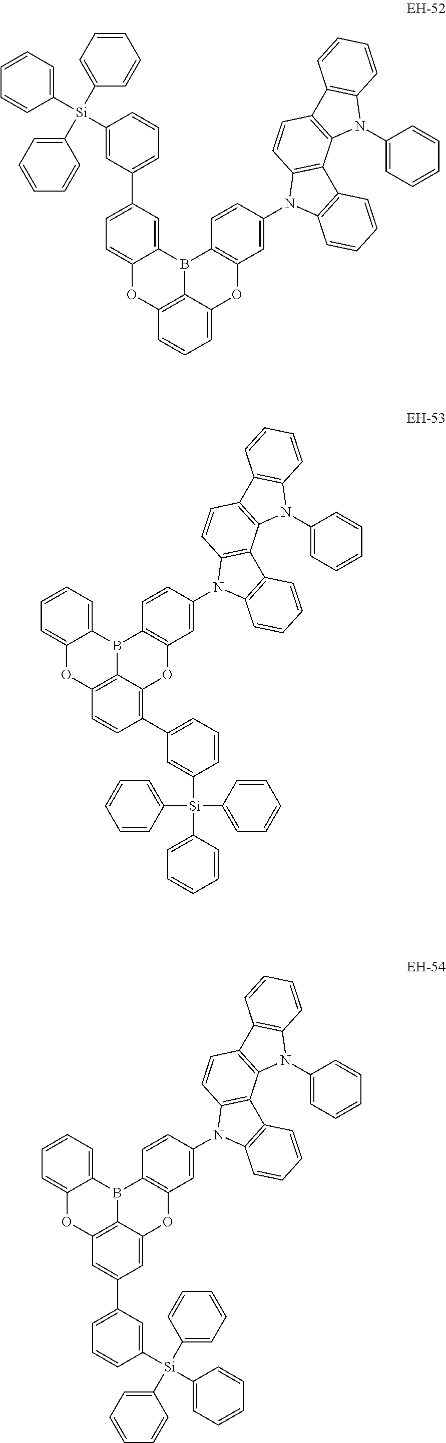 [SMILES: c1ccc(-n2c3ccccc3c3ccc4c(c5ccccc5n4-c4ccc5c(c4)Oc4cccc6c4B5c4cc(-c5cccc([Si](c7ccccc7)(c7ccccc7)c7ccccc7)c5)ccc4O6)c32)cc1 ; c1ccc(-n2c3ccccc3c3ccc4c(c5ccccc5n4-c4ccc5c(c4)Oc4c(-c6cccc([Si](c7ccccc7)(c7ccccc7)c7ccccc7)c6)ccc6c4B5c4ccccc4O6)c32)cc1 ; c1ccc(-n2c3ccccc3c3ccc4c(c5ccccc5n4-c4ccc5c(c4)Oc4cc(-c6cccc([Si](c7ccccc7)(c7ccccc7)c7ccccc7)c6)cc6c4B5c4ccccc4O6)c32)cc1]

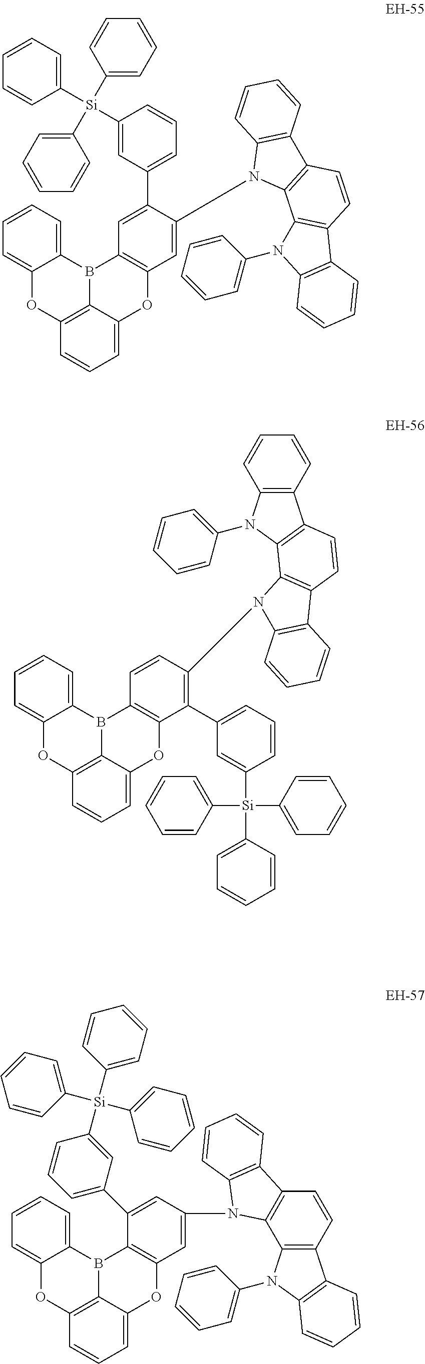 [SMILES: c1ccc(-n2c3ccccc3c3ccc4c5ccccc5n(-c5cc6c(cc5-c5cccc([Si](c7ccccc7)(c7ccccc7)c7ccccc7)c5)B5c7ccccc7Oc7cccc(c75)O6)c4c32)cc1 ; c1ccc(-n2c3ccccc3c3ccc4c5ccccc5n(-c5ccc6c(c5-c5cccc([Si](c7ccccc7)(c7ccccc7)c7ccccc7)c5)Oc5cccc7c5B6c5ccccc5O7)c4c32)cc1 ; c1ccc(-n2c3ccccc3c3ccc4c5ccccc5n(-c5cc6c(c(-c7cccc([Si](c8ccccc8)(c8ccccc8)c8ccccc8)c7)c5)B5c7ccccc7Oc7cccc(c75)O6)c4c32)cc1]

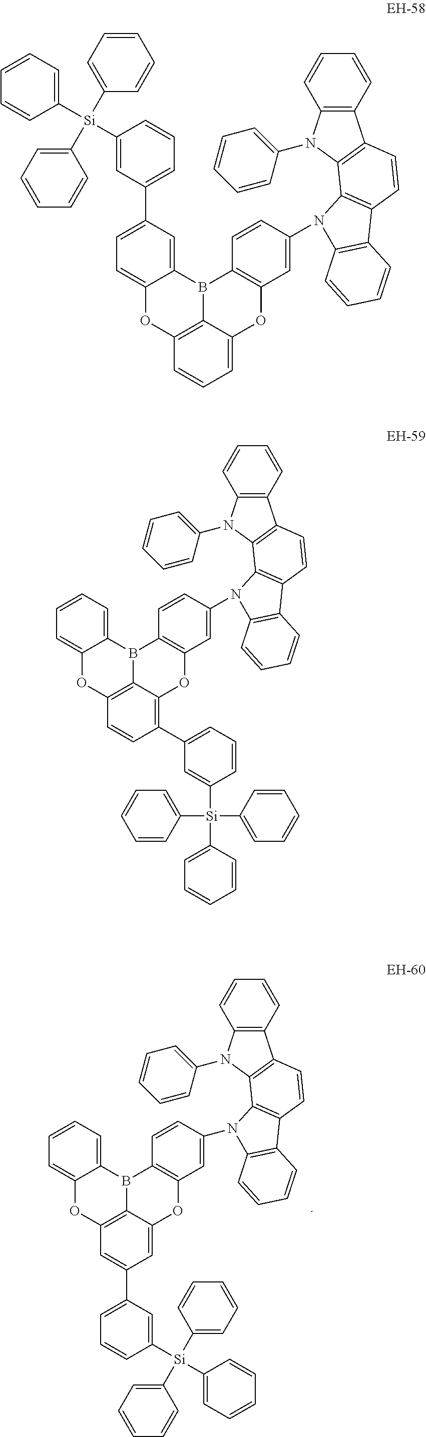 [SMILES: c1ccc(-n2c3ccccc3c3ccc4c5ccccc5n(-c5ccc6c(c5)Oc5cccc7c5B6c5cc(-c6cccc([Si](c8ccccc8)(c8ccccc8)c8ccccc8)c6)ccc5O7)c4c32)cc1 ; c1ccc(-n2c3ccccc3c3ccc4c5ccccc5n(-c5ccc6c(c5)Oc5c(-c7cccc([Si](c8ccccc8)(c8ccccc8)c8ccccc8)c7)ccc7c5B6c5ccccc5O7)c4c32)cc1 ; c1ccc(-n2c3ccccc3c3ccc4c5ccccc5n(-c5ccc6c(c5)Oc5cc(-c7cccc([Si](c8ccccc8)(c8ccccc8)c8ccccc8)c7)cc7c5B6c5ccccc5O7)c4c32)cc1]

19. The organic light emitting device according to claim 15, wherein the second compound is one of compounds in Formula 4:

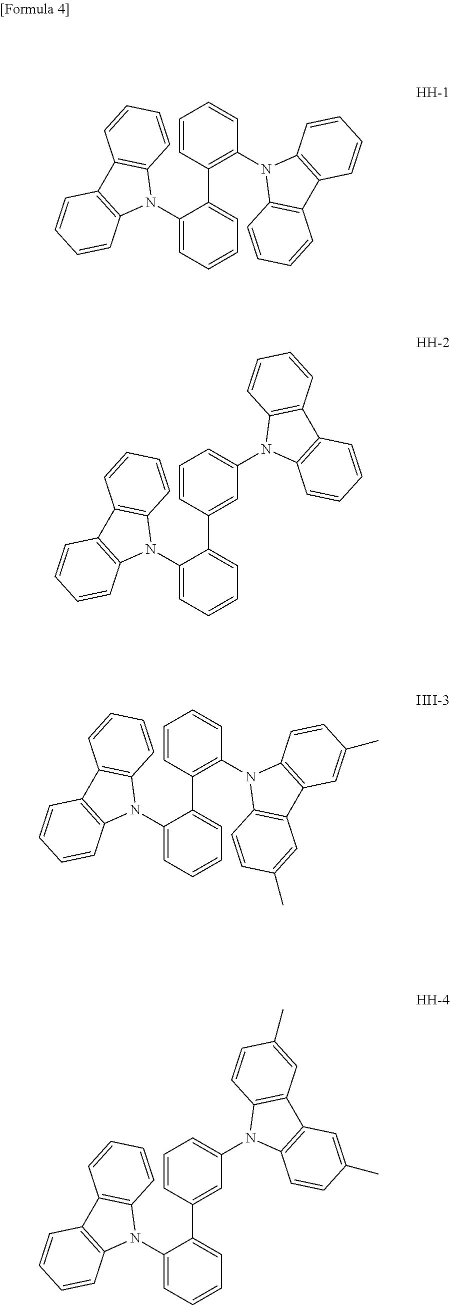 [SMILES: c1ccc(-n2c3ccccc3c3ccccc32)c(-c2ccccc2-n2c3ccccc3c3ccccc32)c1 ; c1cc(-c2ccccc2-n2c3ccccc3c3ccccc32)cc(-n2c3ccccc3c3ccccc32)c1 ; Cc1ccc2c(c1)c1cc(C)ccc1n2-c1ccccc1-c1ccccc1-n1c2ccccc2c2ccccc21 ; Cc1ccc2c(c1)c1cc(C)ccc1n2-c1cccc(-c2ccccc2-n2c3ccccc3c3ccccc32)c1]

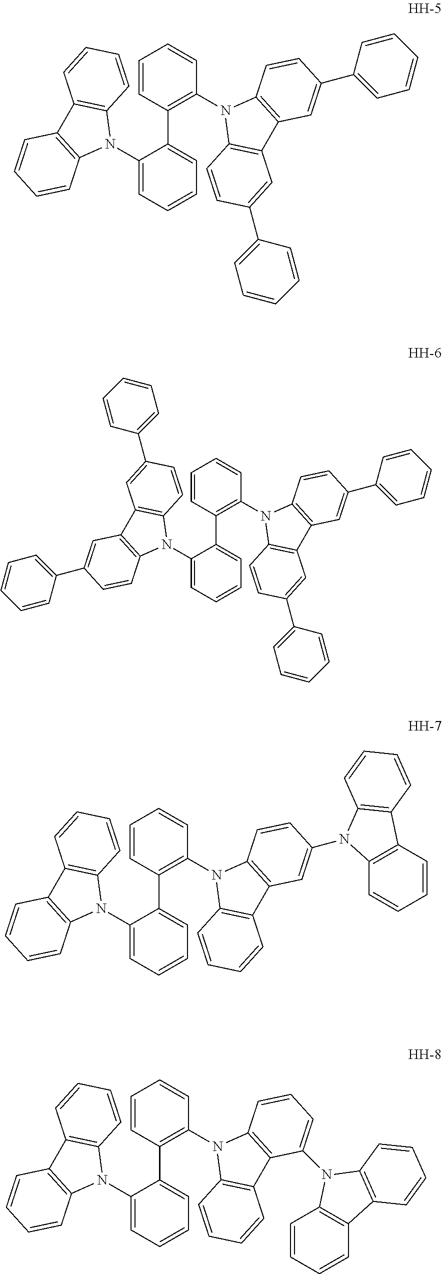 [SMILES: c1ccc(-c2ccc3c(c2)c2cc(-c4ccccc4)ccc2n3-c2ccccc2-c2ccccc2-n2c3ccccc3c3ccccc32)cc1 ; c1ccc(-c2ccc3c(c2)c2cc(-c4ccccc4)ccc2n3-c2ccccc2-c2ccccc2-n2c3ccc(-c4ccccc4)cc3c3cc(-c4ccccc4)ccc32)cc1 ; c1ccc(-n2c3ccccc3c3ccccc32)c(-c2ccccc2-n2c3ccccc3c3cc(-n4c5ccccc5c5ccccc54)ccc32)c1 ; c1ccc(-n2c3ccccc3c3ccccc32)c(-c2ccccc2-n2c3ccccc3c3c(-n4c5ccccc5c5ccccc54)cccc32)c1]

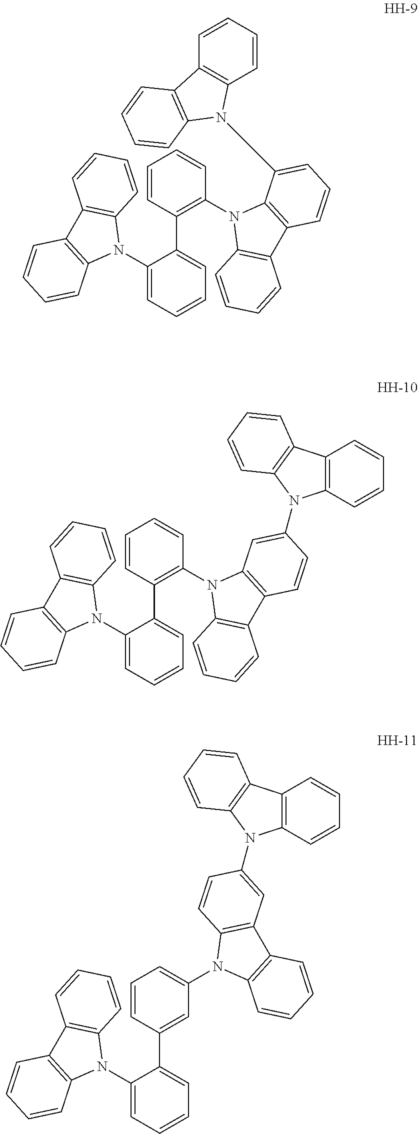 [SMILES: c1ccc(-n2c3ccccc3c3ccccc32)c(-c2ccccc2-n2c3ccccc3c3cccc(-n4c5ccccc5c5ccccc54)c32)c1 ; c1ccc(-n2c3ccccc3c3ccccc32)c(-c2ccccc2-n2c3ccccc3c3ccc(-n4c5ccccc5c5ccccc54)cc32)c1 ; c1cc(-c2ccccc2-n2c3ccccc3c3ccccc32)cc(-n2c3ccccc3c3cc(-n4c5ccccc5c5ccccc54)ccc32)c1]

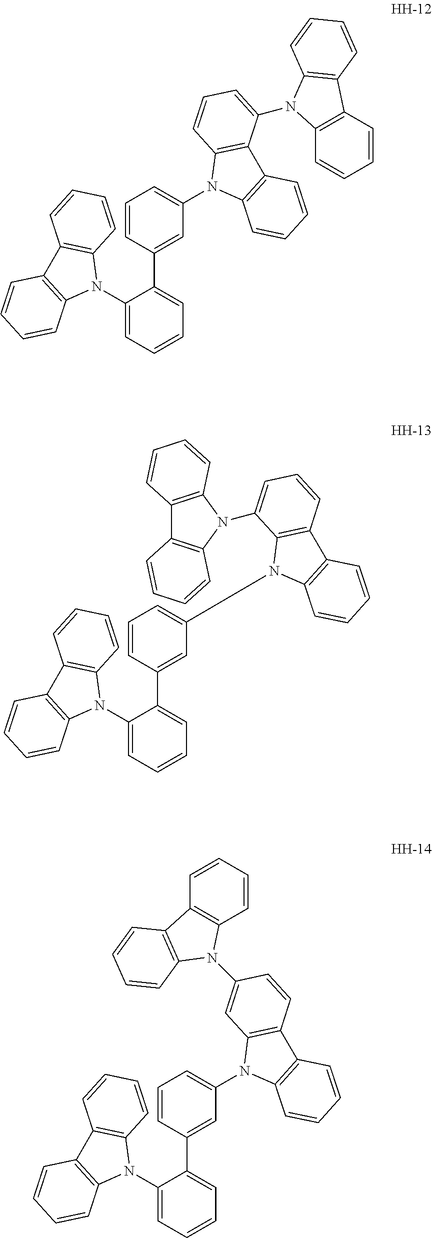 [SMILES: c1cc(-c2ccccc2-n2c3ccccc3c3ccccc32)cc(-n2c3ccccc3c3c(-n4c5ccccc5c5ccccc54)cccc32)c1 ; c1cc(-c2ccccc2-n2c3ccccc3c3ccccc32)cc(-n2c3ccccc3c3cccc(-n4c5ccccc5c5ccccc54)c32)c1 ; c1cc(-c2ccccc2-n2c3ccccc3c3ccccc32)cc(-n2c3ccccc3c3ccc(-n4c5ccccc5c5ccccc54)cc32)c1]

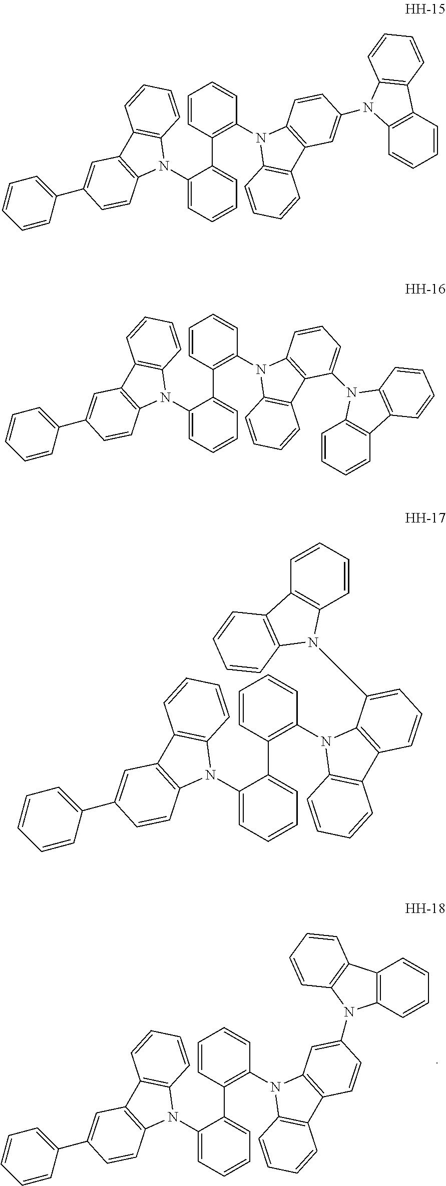 [SMILES: c1ccc(-c2ccc3c(c2)c2ccccc2n3-c2ccccc2-c2ccccc2-n2c3ccccc3c3cc(-n4c5ccccc5c5ccccc54)ccc32)cc1 ; c1ccc(-c2ccc3c(c2)c2ccccc2n3-c2ccccc2-c2ccccc2-n2c3ccccc3c3c(-n4c5ccccc5c5ccccc54)cccc32)cc1 ; c1ccc(-c2ccc3c(c2)c2ccccc2n3-c2ccccc2-c2ccccc2-n2c3ccccc3c3cccc(-n4c5ccccc5c5ccccc54)c32)cc1 ; c1ccc(-c2ccc3c(c2)c2ccccc2n3-c2ccccc2-c2ccccc2-n2c3ccccc3c3ccc(-n4c5ccccc5c5ccccc54)cc32)cc1]

20. The organic light emitting device according to claim 15, wherein the third compound is one of compounds in Formula 6: 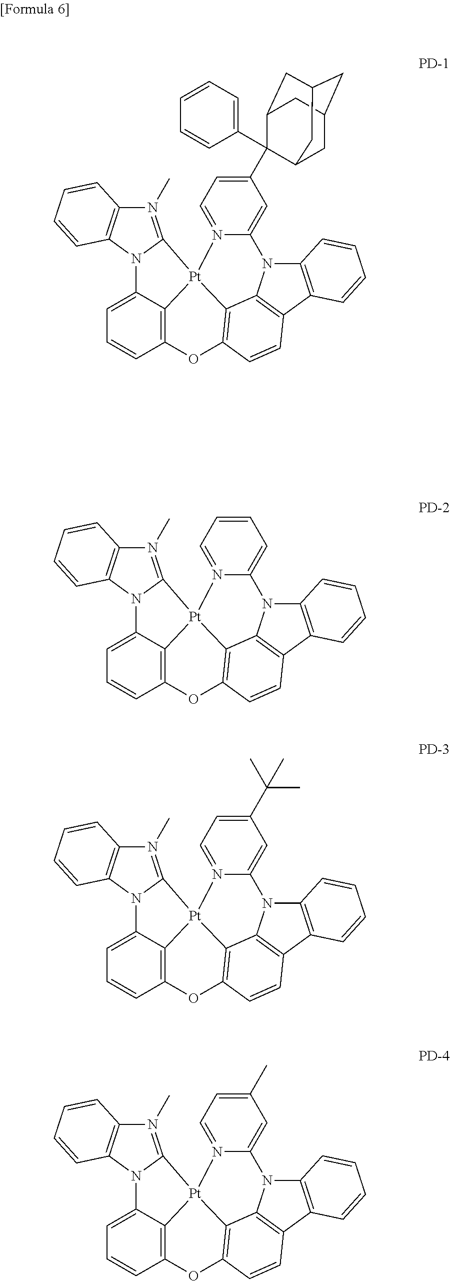 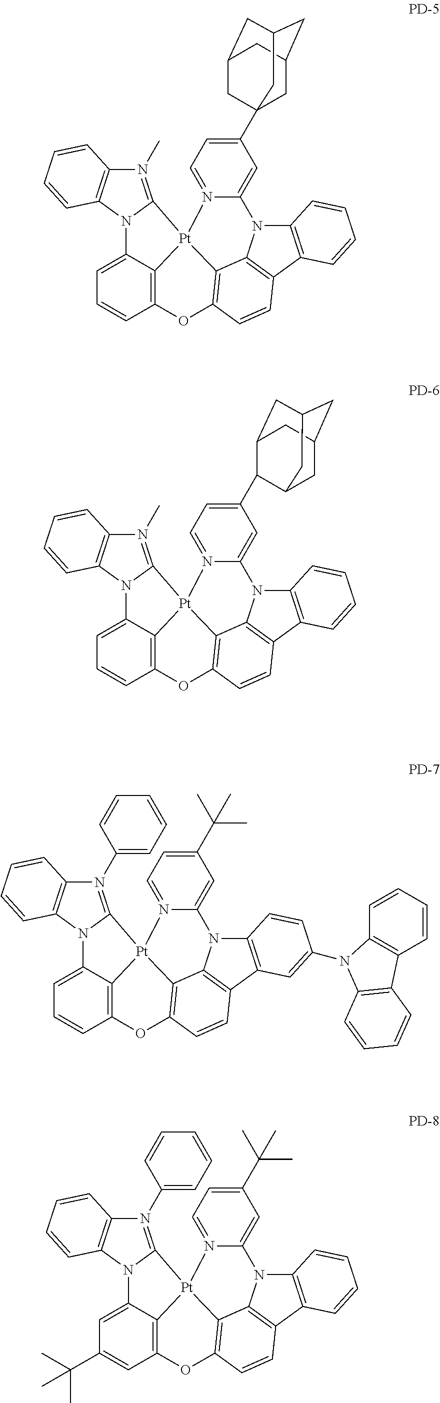 [chemical structure]
